(19) United States
(12) Patent Application Publication
(10) Pub. No.: US 2026/0088255 A1
(43) Pub. Date: Mar. 26, 2026

(54) SHOWERHEAD FACEPLATES

(71) Applicant: Lam Research Corporation, Fremont, CA (US)

(72) Inventors: Zubin Huang, Santa Clara, CA (US); Jeremy Todd Tucker, Redwood City, CA (US); Conor Le Gear, Amsterdam (NL); Ujjwal Aashray Trakroo, Bangalore (IN)

(21) Appl. No.: 19/111,319

(22) PCT Filed: Sep. 14, 2023
(86) PCT No.: PCT/US2023/074154

§ 371 Date: Mar. 13, 2025

Related U.S. Application Data
(60) Provisional application No. 63/375,740, filed on Sep. 15, 2022.
(60) Provisional application No. 63/503,424, filed on May 19, 2023.
(60) Provisional application No. 63/509,225, filed on Jun. 20, 2023.
(60) Provisional application No. 63/526,944, filed on Jul. 14, 2023.

(51) Int. Cl. H01J 37/32; B05B 1/18

(52) U.S. Cl. CPC H01J 37/3244; B05B 1/18

(57) ABSTRACT

Semiconductor processing tool showerhead designs suitable for multi-gas delivery and for being made through additive manufacturing are provided. Such showerhead designs may feature either internal spiral passages or internal plenums with a plurality of pillars spanning between upper and lower surfaces thereof distributed throughout.

### RELATED APPLICATIONS

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Semiconductor processing tools frequently utilize gas distribution systems, often referred to as showerheads, to distribute process gas or gases across a semiconductor wafer being processed. Such showerheads typically have a plurality of gas distribution holes distributed across, or arranged on, a bottom surface thereof so as to allow process gases from an internal plenum or plenums of such a showerhead to be flowed onto the semiconductor wafer from above. In some instances, a showerhead may be a single, integrated structure, e.g., made in multiple pieces that are then welded together, while in other instances, a showerhead may be a multi-piece structure that is able to be disassembled, e.g., consisting of multiple pieces that are fastened together, e.g., using screws.

### SUMMARY

In some implementations, an apparatus may be provided that includes a main body having a first side and a second side on an opposite side of the main body from the first side. The apparatus may also include N spiral passages located within the main body, each spiral passage following a corresponding spiral path, the N spiral passages including at least: a first spiral passage located within the main body, wherein at least a portion of the first spiral passage follows a first spiral path and has a first cross-sectional profile along at least a portion of the first spiral path, and a second spiral passage located within the main body, wherein at least a portion of the second spiral passage follows a second spiral path and has a second cross-sectional profile along at least a portion of the second spiral path. The apparatus may also include a plurality of first gas distribution holes extending from the second side to the first spiral passage, a plurality of second gas distribution holes extending from the second side to the second spiral passage, one or more first inlet ports, each first inlet port extending from a corresponding location on the exterior of the main body to the first spiral passage, and one or more second inlet ports, each second inlet port extending from a corresponding location on the exterior of the main body to the second spiral passage. In such an implementation, the first gas distribution holes may be arranged along the first spiral path, and the second gas distribution holes may be arranged along the second spiral path.

In some implementations, the first cross-sectional profile may have a first segment proximate to the first side, a second segment positioned such that the first segment is between the second segment and the first side, and opposing first side segments, each first side segment spanning between the first segment and the second segment. In such implementations, the second cross-sectional profile may have a third segment proximate to the first side, a fourth segment positioned such that the third segment is between the fourth segment and the first side, and opposing second side segments, each second side segment spanning between the third segment and the fourth segment. The first segment may include corresponding first rounded transition regions, the third segment may include corresponding second rounded transition regions, each first rounded transition region may connect with a corresponding one of the first side segments, and each second rounded transition region may connect with a corresponding one of the second side segments.

In some implementations, each first rounded transition region may be tangent to the first side segment to which it connects, and each second rounded transition region may be tangent to the second side segment to which it connects.

In some implementations, the first rounded transition regions connected with the first side segments may connect with each other such that the first segment has a circular or parabolic profile in cross-section.

In some implementations, the second rounded transition regions connected with the second side segments may connect with each other such that the third segment has a circular or parabolic profile in cross-section.

In some implementations, the first rounded transition regions connected with the first side segments may connect with each other such that the first segment has a circular or parabolic profile in cross-section, and the second rounded transition regions connected with the second side segments may connect with each other such that the third segment has a circular or parabolic profile in cross-section.

In some implementations, the second segment may include corresponding third rounded transition regions, the fourth segment may include corresponding fourth rounded transition regions, each third rounded transition region may connect with a corresponding one of the first side segments, and each fourth rounded transition region may connect with a corresponding one of the second side segments.

In some implementations, the third rounded transition regions may be smaller in cross-sectional profile than the first rounded transition regions, and the fourth rounded transition regions may be smaller in cross-sectional profile than the second rounded transition regions.

In some implementations, the third segment may include a first linear portion located between the third rounded transition regions, the fourth segment may include a second linear portion located between the fourth rounded transition regions, and the first linear portion and the second linear portion may be parallel to a first plane defined by the first side.

In some implementations, the first gas distribution holes may connect with the first spiral passage at cross-sectional locations within the first linear portion, and the second gas distribution holes may connect with the second spiral passage at cross-sectional locations within the second linear portion.

In some implementations, the spiral paths followed by the N spiral passages may all be coaxial with one another, the spiral paths may all be at different angular orientations with respect to a center axis of the spiral paths, and each spiral path may be 360°/N out of phase with each neighboring spiral path.

In some implementations, N=2 or N=3.

In some implementations, the apparatus may further include N spiral walls, each spiral wall separating one spiral passage from an adjacent spiral passage and following a corresponding spiral wall path, and a plurality of zeroth gas distribution holes, each zeroth gas distribution hole extending from the first side of the main body to the second side of the main body, wherein the zeroth gas distribution holes are distributed along the corresponding spiral wall path for at least one of the spiral walls.

In some implementations, the zeroth gas distribution holes may be distributed along the corresponding spiral wall paths of the spiral walls.

In some implementations, the apparatus may further include a plurality of zeroth gas distribution holes arranged along a zeroth spiral path. Each zeroth gas distribution hole may extend from the first side of the main body to the second side of the main body, and the spiral paths, including the spiral paths followed by the N spiral passages and the zeroth spiral path, may be coaxial with one another, at different angular orientations with respect to a center axis of the spiral paths, and each 360°/(N+1) out of phase with each neighboring spiral path.

In some implementations, the first cross-sectional profile may be at a different distance from the second side in a direction perpendicular to a plane defined by the second side than the second cross-sectional profile.

In some implementations, the first spiral path and the second spiral path may have the same pitch and the same number of revolutions.

In some implementations, the first spiral path may have between 5 and 15 revolutions.

In some implementations, the one or more first inlet ports may connect with the first spiral passage at a location or locations that are proximate to an end of the first spiral passage that is furthest from a center of the first spiral path, and the one or more second inlet ports may connect with the second spiral passage at a location or locations that are proximate to an end of the second spiral passage that is furthest from a center of the second spiral path.

In some such implementations, the one or more first inlet ports and the one or more second inlet ports may be positioned at a common azimuthal location relative to the first spiral path and the second spiral path.

In some implementations, the first spiral path may have an outer diameter of at least 300 mm.

In some implementations, the main body and spiral passages may be formed through additive manufacturing.

In some implementations, the main body and spiral passages may be formed from a material exhibiting an anisotropic micrograin structure.

In some implementations, the material may be a metal, e.g., Hastelloy C-22 alloy

In some implementations, the first gas distribution holes and the second gas distribution holes may be drilled or electrical discharge machined holes.

In some implementations, the apparatus may further include a plurality of outlet ports. Each spiral passage may be fluidically interposed between two of the outlet ports, and at least one of the outlet ports between which each spiral passage may be fluidically interposed is sealed off to prevent fluid flow therethrough.

In some implementations, at least one of the inlet ports may also serve as one of the outlet ports.

In some implementations, the outlet ports may be used to flow a polishing compound through the spiral passages.

In some implementations, a method for manufacturing one of the above apparatuses may be provided, the method including manufacturing the main body and, concurrently with manufacturing the main body, the spiral passages using additive manufacturing, and drilling the first gas distribution holes and the second gas distribution holes after manufacturing the main body.

In some implementations, the drilling may be performed using a mechanical drill or using electric discharge drilling.

In some implementations, the method may further include flowing a polishing compound through the spiral passages.

In some implementations, an apparatus may be provided that includes a main body having a first side and a second side on an opposite side of the main body from the first side, a first internal plenum volume located within the main body, the first internal plenum volume located between a first surface and a second surface, the first surface between the first side and the second surface, and the second surface between the first surface and the second side, and a plurality of pillars, the plurality of pillars including first pillars distributed throughout a first region of the first internal plenum volume. Each first pillar in a set of the first pillars may span between the first surface and the second surface, each first pillar in the set of first pillars may include a corresponding first gas distribution hole that extends between the first side and the second side, each first pillar in the set of first pillars may have one or more exterior side walls, and the one or more exterior side walls of each first pillar in the set of first pillars may connect with the first surface via a corresponding first rounded transition region. The apparatus may also include a plurality of second gas distribution holes distributed throughout the first region of the first internal plenum volume, each second gas distribution hole spanning between the second side and the second surface.

In some implementations, the apparatus may include a second internal plenum volume located within the main body, the second internal plenum volume located between a third surface and a fourth surface, the third surface between the first side and the fourth surface, the fourth surface between the third surface and the second side, and the third and fourth surfaces between the first side and the first surface. Each first pillar in the set of first pillars may be interposed between two corresponding second pillars of the plurality of pillars, the two corresponding second pillars for each first pillar in the set of first pillars may be the two closest pillars in the first internal plenum volume to that first pillar, each first pillar in the set of first pillars and the corresponding second pillars for that first pillar may be arranged along a corresponding first axis parallel to a first direction, the plurality of pillars may further include third pillars located within the second internal plenum volume, each third pillar corresponding in location to one of the first pillars in the set of first pillars and having the corresponding first gas distribution hole for that first pillar extending therethrough, and the corresponding second pillars for each first pillar in the set of first pillars may each include a corresponding third gas distribution hole that spans between the second side and the fourth surface.

In some implementations, each first pillar in the set of first pillars may be interposed between two of the second gas distribution holes that are closest to that first pillar, each first pillar in the set of first pillars and the two second gas distribution holes closest thereto may be arranged along a corresponding second axis parallel to a second direction, and the second direction may be transverse to the first direction.

In some implementations, a center of each first pillar in the set of first pillars may be equidistantly spaced from centers of the two second pillars that are closest to that first pillar and from centers of the two second gas distribution holes that are closest to that first pillar.

In some implementations, the first direction may be perpendicular to the second direction.

In some implementations, the first pillars in the set of first pillars may be arranged in a square array.

In some implementations, the square array may have array axes that are at 45° to the first direction.

In some implementations, the apparatus may further include a second internal plenum volume located within the main body, the second internal plenum volume located between a third surface and a fourth surface, the third surface between the first side and the fourth surface, the fourth surface between the third surface and the second side, and the third and fourth surfaces between the first side and the first surface. The plurality of pillars may also include second pillars located within the first internal plenum volume and third pillars located within the second internal plenum volume, for each first pillar in the set of first pillars, the three pillars closest thereto within the first internal plenum volume may each be second pillars, equidistantly spaced from that first pillar, and equidistantly spaced from one another, each third pillar may correspond in location to one of the first pillars in the set of first pillars and has the corresponding first gas distribution hole for that first pillar extending therethrough, and the second pillars may each include a corresponding third gas distribution hole that spans between the second side and the fourth surface.

In some implementations, for each first pillar in the set of first pillars, the three second gas distribution holes closest thereto may each be equidistantly spaced from that first pillar and equidistantly spaced from one another.

In some implementations, each second gas distribution hole in a set of the second gas distribution holes may be at the center of a hexagonal pattern of three first pillars and three second pillars

In some implementations, the second surface may define a first reference plane, each of the pillars in a set of the pillars in the first internal plenum volume may be associated with a corresponding contour region of the first surface, a corresponding portion of the first surface may be bounded by the corresponding contour region for each pillar in the set of pillars, and a first distance between the first reference plane and the corresponding portion of the first surface for each pillar in the set of pillars in the first internal plenum volume may increase as a function of a second distance from a center axis of that pillar.

In some implementations, for each pillar in a set of pillars in the first internal plenum volume, the first distances for that pillar may be determined according to a scalar function having axial symmetry about a center axis of that pillar.

In some implementations, cross-sectional profiles of the corresponding portion of the first surface for each pillar in a set of pillars in the first internal plenum volume may, at a boundary of the corresponding contour region for that pillar, be tangent to a second reference plane that is parallel to the first reference plane and may, at that pillar, be tangent to a third reference plane that is parallel to the second reference plane.

In some implementations, for each pillar in the set of pillars in the first internal plenum volume, a difference between minimum and maximum values of the first distance within the corresponding contour region for that pillar may be between 20% and 30% of a maximum distance between the center axis of that pillar and a boundary of the corresponding contour region.

In some implementations, the corresponding contour region for each pillar in a set of pillars in the first internal plenum volume may have boundary edges that are perpendicular to, and bisect, reference lines extending between that pillar and adjacent pillars within the first internal plenum volume.

In some implementations, the corresponding contour region for each pillar in a set of pillars in the first internal plenum volume may be bounded by a corresponding plurality of bounding reference planes, and for each of the pillars in the set of pillars in the first internal plenum volume, each reference plane in the corresponding plurality of bounding reference planes for that pillar may be positioned midway between that pillar and another pillar in the first internal plenum volume and may be perpendicular to a corresponding reference axis that is parallel to the first reference plane and that passes through the center of that pillar and the other pillar.

In some implementations, the one or more exterior side walls of each first pillar in the set of first pillars may connect with the second surface via a corresponding second rounded transition region, and the second rounded transition regions may be smaller than the first rounded transition regions.

In some implementations, the first rounded transition region of each first pillar in the set of first pillars may meet the first rounded transition region of at least one other first pillar of the first pillars.

In some implementations, the first surface may be offset from the second surface in a direction perpendicular to the first surface and by a first amount, and the first amount may be less than or equal to 120% of a radius of the first rounded transition regions.

In some implementations, each first pillar in the set of first pillars may have a centerline that is within 240% of a radius of the first rounded transition regions of the centerlines of any immediately neighboring first pillars of that first pillar.

In some implementations, the first region may be a circular region of at least 300 mm in diameter.

In some implementations, the main body and the first pillars may be formed through additive manufacturing.

In some implementations, the main body and first pillars may be formed from a material exhibiting an anisotropic micrograin structure.

In some implementations, the material may be a metal, e.g., Hastelloy C-22 alloy

In some implementations, the first gas distribution holes and the second gas distribution holes may be drilled or electrical discharge machined holes.

### BRIEF DESCRIPTION OF THE DRAWINGS

FIG. 1 shows representational grain boundaries taken in a vertical plane and horizontal plane in an example component made using an example DMLM process.

FIG. 2 is a top view of an example showerhead configured to separately deliver two process gases using internal spiral passages.

FIG. 3 is a section view of the example showerhead of FIG. 2 taken along the indicated section line.

FIG. 4 is a section view of the example showerhead of FIG. 2 taken along the section line indicated in FIG. 3.

FIG. 4′ is a detail section view of a pair of radially adjacent spiral passages of the example showerhead of FIG. 2.

FIG. 5 depicts a cross-sectional view of a showerhead similar to that of FIG. 2, but with inlet ports located near the periphery of the showerhead.

FIG. 6 depicts analysis results showing the relative molar concentration of a reactant flowed through a showerhead such as the showerhead of FIG. 2.

FIG. 7 depicts analysis results showing the relative molar concentration of a reactant flowed through a showerhead such as the showerhead of FIG. 5.

FIG. 8 depicts a cross-sectional view of a showerhead having two spiral passages with azimuthally collocated inlet ports.

FIG. 9 depicts analysis results showing the relative molar concentration of a reactant flowed through a showerhead such as the showerhead of FIG. 8.

FIG. 10 depicts an isometric cutaway view of an example showerhead having dual-level spiral passages.

FIG. 11 depicts an isometric top section view of the showerhead of FIG. 10.

FIG. 12 depicts a second isometric top section view of the showerhead of FIG. 10.

FIG. 13 depicts analysis results showing the relative molar concentration of a reactant flowed through a showerhead similar to the showerhead of FIG. 10.

FIG. 14 depicts a top view and side section view of an example showerhead that includes spiral passages and spoke passages.

FIG. 15 depicts a side view and top section view of the example showerhead of FIG. 14.

FIG. 16 depicts the side view and another top section view of the example showerhead of FIG. 14.

FIG. 17 depicts analysis results showing the relative molar concentration of a reactant flowed through a showerhead similar to the showerhead of FIG. 14.

FIG. 18 is a section view of an example showerhead similar to the example showerhead of FIG. 2, but configured to separately deliver three process gases using internal spiral passages.

FIG. 19 is a side view of another example showerhead similar to that of FIG. 2, but having the capability of separately delivering three process gases-two via internal spiral passages and one via gas distribution holes that extend from one side of the showerhead to the other.

FIG. 20 is a top view of the example showerhead of FIG. 19.

FIG. 21 is a section view of the example showerhead of FIG. 19 taken along the section view of FIG. 19.

FIG. 22 is an isometric section view of the example showerhead of FIG. 19 taken along the section line in FIG. 20.

FIG. 23 is a top view of another example showerhead that is configured to separately deliver three different process gases in a manner similar to how the example showerhead of FIG. 19 delivers process gases.

FIG. 24 is a side section view of the example showerhead of FIG. 23 taken along the section line of FIG. 23.

FIGS. 25 and 26 are section views of the example showerhead of FIG. 23 taken along the corresponding section lines at different elevations in FIG. 24.

FIG. 27 is a bottom view of the example showerhead of FIG. 23.

FIG. 28 is a top cutaway view of an example showerhead featuring two nested dual-level spiral passages.

FIG. 29 is a section view of the example showerhead of FIG. 28 along the dash-dot-dash line in FIG. 28.

FIG. 30 is a detail view of the portion of the section view of the example showerhead of FIG. 28 within the rectangular dash-dot-dash rectangle.

FIG. 31 depicts a side view of an example showerhead featuring four nested, dual-level spiral passages.

FIG. 32 depicts a top cutaway view of the example showerhead of FIG. 31 along the dash-dot-dash line in FIG. 31.

FIG. 33 depicts a top cutaway section view of another example showerhead similar to that of FIG. 31 but having six nested, dual-level spiral passages.

FIG. 34 depicts a side view of an example showerhead having nested dual-level, reversed spiral passages.

FIG. 35 depicts an isometric exploded section view of the example showerhead of FIG. 34.

FIG. 36 depicts a diagram showing crossover points between nested spiral passages in a dual-level reversed spiral passage showerhead.

FIG. 37 is a side view of an example showerhead featuring an internal plenum volume having a plurality of pillars extending between upper and lower surfaces thereof.

FIGS. 38 and 39 are isometric section views of the example showerhead of FIG. 37 taken along the corresponding section lines of FIG. 37.

FIG. 40 depicts a partial cutaway view of a portion of the showerhead of FIG. 37 in which several pillars are visible.

FIG. 41 depicts a side section view of a representative pillar highlighting various features thereof.

FIG. 42 is a side view of another example showerhead featuring an internal plenum volume having a plurality of pillars extending between upper and lower surfaces thereof.

FIGS. 43 and 44 are isometric section views of the example showerhead of FIG. 42 taken along the corresponding section lines of FIG. 42.

FIG. 45 is an isometric section view of the example showerhead of FIG. 42 taken along the corresponding section line of FIG. 42.

FIG. 46 is a perspective view of a portion of an example showerhead.

FIGS. 47 through 50 are perspective cutaway views of the example showerhead of FIG. 46.

FIG. 51 is a plan view of an interior portion of the example showerhead of FIG. 46.

FIGS. 52 and 53 are plan view cutaway views of the portion of the example showerhead of FIG. 46.

FIG. 54 is a diagram showing various cross-sections of a portion of the showerhead of FIG. 46.

FIG. 55 is a plan view of an interior portion of another example showerhead.

FIGS. 56 through 58 are perspective views of a portion of the example showerhead of FIG. 55, with FIGS. 57 and 58 being cutaway views thereof.

FIG. 59 depicts a top view of an example showerhead having two edge-fed internal plenums with pillars spanning between upper and lower surfaces of each plenum.

FIG. 60 depicts a side view of the example showerhead of FIG. 59.

FIG. 61 depicts an isometric exploded section view of the example showerhead of FIG. 59.

FIG. 62 is a detail view of the portion of the example showerhead of FIG. 61 within the rectangular dash-dot-dash rectangle at left in FIG. 61.

FIG. 63 is a detail view of the portion of the example showerhead of FIG. 61 within the rectangular dash-dot-dash rectangle at right in FIG. 61.

FIG. 64 depicts an isometric exploded section view of an example showerhead similar to that shown in FIGS. 59 through 63, except that one of the internal plenums is center-fed and does not have pillars spanning between top and bottom surfaces thereof.

FIG. 65 depicts an example of a showerhead that is manufactured using traditional machining techniques.

FIG. 66 depicts a schematic of a chamber.

### DETAILED DESCRIPTION

A showerhead, in the context of this disclosure, refers to a structure that typically features a main body that houses within it one or more passages or internal volumes that form one or more internal plenum volumes. Showerheads also include a plurality of gas distribution holes that are each fluidically connected with the internal plenum volume or with one of the internal plenum volumes (if multiple such internal plenum volumes exist). The gas distribution holes are typically distributed across the underside of the main body and positioned so as to deliver process gas supplied thereby across the upper surface of a wafer being processed (or across the underside of the wafer if backside deposition or etching is being performed).

A showerhead faceplate, in the context of this disclosure, is a showerhead that is designed to be interfaced with another component, e.g., a back plate, in order to provide an additional plenum volume for delivering gas. For example, a showerhead will have one or more internal cavities or passages within it that form one or more plenum volumes within the showerhead that may be used to distribute gas to gas distribution holes in the showerhead that are each fluidically connected with one of the plenum volumes (or with the plenum volume if there is only one plenum volume within the showerhead). In some cases, however, the showerhead may have additional gas distribution holes that do not fluidically connect with a plenum volume internal to the showerhead but instead pass completely through the showerhead. When that showerhead is then interfaced with one or more other components in order to form another plenum volume that is bounded on one side by an exterior surface of the showerhead, this allows another gas to be delivered to that newly created plenum volume and then flowed through the gas distribution holes that pass completely through the showerhead. Such a showerhead may be referred to as a showerhead faceplate.

Disclosed herein are various showerhead or showerhead faceplate designs that are specially designed so as to be able to be manufactured using additive manufacturing techniques such as selective laser melting (SLM) (which may be used to produce ceramic or silicon versions of such showerheads) or direct metal laser melting (DMLM) (which may be used to produce metal versions thereof). In particular, the showerhead designs discussed herein may be particularly suitable for being manufactured using laser powder-bed fusion (LPBF) additive manufacturing techniques, which may include manufacturing processes such as SLM, DMLM, SLS (selective laser sintering), and DMLS (direct metal laser sintering), all of which may be used to create metal-based components (and some of which, like SLS and SLM, may be used to create ceramic-based components).

In most additive manufacturing processes, a part is manufactured by adding material to the part one horizontal layer at a time; such layers may be extremely thin, e.g., 0.02 mm at a time is possible for DMLM parts. In DMLM, for example, a platen supporting a part is gradually lowered relative to a reference plane. The platen forms the “floor” of a cavity that is used to contain the part being manufactured. Each time the platen is lowered, powdered material is added to the cavity and then leveled so as to be level with the reference plane. A laser then scans across the reference plane and applies heat to the uppermost layer of powdered material in the regions where structure is desired, melting the powder granules to each other and to any underlying, previously fused structure. Once a particular layer is done, the platen may be lowered slightly, a new layer of powdered material may be applied, and the laser melting process repeated. This process is repeated until the part is complete, at which point the cavity of the DMLM device will be filled with unmelted powdered material having buried within it the additively manufactured component.

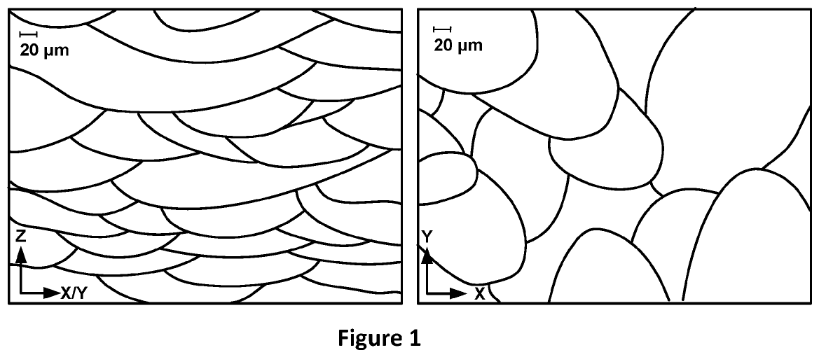

Such additively manufactured components typically have a very fine grain microstructure as compared with bulk-manufactured components (e.g., such as components made by casting in which molten material is formed into the desired component in generally a single operation as opposed to a small number of grains being fused together at a time over the course of many sequential operations as is done in SLM or DMLM)), i.e., a structure that is formed through the fusion of small grains of solid material through the selective application of heat provided by a laser. Such additively manufactured components also, in many cases, tend to have a microstructure that is noticeably directional, with micrograins having profiles in the XY plane that are more rounded and larger than the profiles of such micrograins in a plane parallel to the Z direction (with the XY plane corresponding to the horizontal plane, and the Z direction corresponding to the vertical direction, relative to the component as positioned during the additive manufacturing process). FIG. 1, for example, shows representational grain boundaries taken in a vertical plane (left side) and horizontal plane (right side) in an example component made using one example DMLM process; as can be seen, the size of the grains in the vertical plane exhibit a high degree of asymmetry with respect to their size in the Z-direction compared to their size in either the X or Y directions. The micrograins tend to be much longer in the X and/or Y directions than they are thick in the Z direction. This micrograin structure may be referred to herein as being an anisotropic micrograin structure, which should be understood to differentiate it from micrograin structures in which the micrograins, while exhibiting variation in size and shape, do not generally exhibit dimensional variance that is tied to a particular axis. It will be understood that at least some of the additively manufactured showerheads discussed herein may exhibit such anisotropic micrograin structure.

The use of such additive manufacturing techniques permits the adoption of showerhead geometries that would be extremely difficult or impossible to achieve using only conventional machining (subtractive machining) techniques such as milling, drilling, or turning. Such showerhead geometries may allow, for example, showerheads to have smaller interior volumes (thus decreasing the amount of gas needed to provide a desired gas flow through the showerhead and reducing the amount of time needed before the showerhead reaches steady state flow) and, in some cases, an increased number of different fluidically isolated flow paths within the showerhead (or at least a higher density of such flow paths).

The showerhead and showerhead faceplate designs discussed herein are designed to permit flow or delivery of two or more different gases used during semiconductor processing operations (including, for example, precursors, reactants, or inert or non-reactive purge gases) from or through a common showerhead while segregating those gas flows from one another within the showerhead.

Such showerhead and showerhead faceplate (for ease of reference, the term “showerhead” may be used to collectively refer to either or both of a showerhead and showerhead faceplate in the following discussions) designs may have characteristics that lend themselves to being made using additive manufacturing techniques while avoiding potential particulate-generating geometries. For example, such showerheads may fall within two broad categories of design-showerheads with internal spiral passages and showerheads with a large open internal plenum volume having a large number of vertical pillars distributed therethroughout. In either case, such showerheads will have generally vertical surfaces located within the showerhead that either define the sidewalls of the spiral passages or the pillars. Each such sidewall may extend between two opposing internal surfaces of the showerhead that are generally parallel to the underside of the showerhead. To avoid particulate generation, however, the transitions from those sidewall surfaces to the opposing internal surfaces of the showerhead may be designed to be rounded transitions.

By avoiding sharp, interior corner edges within the showerhead main body, the potential for particulates to become trapped and then later released within such interior corners is reduced (a particle that flows into contact with a sharp corner edge may make contact with two surfaces simultaneously, thereby increasing the risk of it becoming stuck; a particle that flows into contact with a rounded interior edge, however, will generally only contact one surface at a time, thereby reducing the risk of the particle becoming stuck).

At the same time, the surface finish of additively manufactured parts is often rough and may require post-additive manufacturing processing in order to reduce the surface roughness on some surfaces. This is particularly the case in showerheads, as the surface finish in the internal volumes of the showerheads through which gas flows that results from the additive manufacturing process may be undesirably rough. For example, there may be granules of the material used in the additive manufacturing process that are only loosely fused in place and which may thus pose a risk of later being released from their anchor points by exposure to the gas flowing through those internal spaces. To reduce or eliminate the chance of this, a polishing compound or slurry may be pumped through the internal spaces post-additive manufacturing to abrade away such granules and polish or smooth out the internal passages. However, if there are sharp interior corners along the paths that such a polishing compound or slurry may flow, such sharp interior corners may act, in effect, as stagnation zones in which there is much less fluid flow than elsewhere in the internal spaces of the showerhead. Thus, the polishing compound or slurry may have a greatly reduced capability for removing particulates that may be present in such interior corners. This may result in increased chances of such particulates remaining after the polishing process is performed and then potentially being released or knocked free during operational use of the showerhead during semiconductor processing operations (thereby contaminating a semiconductor wafer being processed).

The chances of such particulate contamination occurring may be greatly reduced by rounding the intersections between the sidewalls and the top and bottom internal surfaces of the showerhead that the sidewalls span between.

Additive manufacturing processes for metals, e.g., such as may be used in making the above-referenced showerheads, may be used to make complex shapes that would be difficult or impossible to manufacture using traditional subtractive machining and/or casting processes. In particular additively manufacturing may be used to create, as a single piece, components having internal cavities or chambers that would normally require machining as two or more separate pieces that are then welded or bonded together. However, such capabilities are not without limitation. For example, internal cavities or passages having downward-facing, horizontal surfaces may be ill-suited for manufacture using such techniques since those downward-facing surfaces may sag during the additive manufacturing process due to a lack of support by any rigid structure. For example, the only support for such surfaces may be provided by unfused granular material directly underneath such surfaces, and such unfused material may compact or may, itself, fuse to some extent (thus becoming denser and reducing in volume) due to heat that bleeds through from the surface being fused.

Generally speaking, horizontal, downward-facing surfaces that are larger than 1 cm in width may be at risk of sagging during additive manufacturing processing. To reduce or eliminate the chance of such horizontal-surface sag, some showerheads such as are discussed herein may be designed such that the rounded transitions between the above-mentioned sidewalls and the upper internal surfaces of such showerheads have radii that are large enough that the rounded transitions for the sidewall surfaces and the upper internal surface(s) of the shower head may touch for neighboring sidewalls. For example, a spiral passage in such a showerhead may be designed so as to have an arcuate or parabolic “roof” that smoothly transitions to the sidewall surfaces but which has a horizontal element that is, in effect, infinitesimally thin. In another example, in some showerheads in which pillars are distributed throughout an internal plenum of the showerhead and span between the top and bottom internal surfaces thereof, each pillar may be spaced apart from the closest neighboring pillars by a distance that is equal to twice a radius of the rounded transitions between the pillar sidewall and the upper interior surface of the showerhead, thereby forming continuous and smooth arches between the pillar and adjacent pillars.

At the same time, the rounded transition regions where the sidewall surfaces meet the lower internal surface of the showerhead may be rounded to a much lesser extent than the upper rounded transition regions. This results in flat or horizontal surfaces being present between the sidewall surfaces of the passages or adjacent pillars. Such flat or horizontal surfaces may be designed to be at least several millimeters in width. Such an approach may help ensure that when gas distribution holes are drilled into the underside of the showerhead so as to intersect with the internal passages or volumes within the main body of the showerhead, such gas distribution holes will all generally be positioned such that each gas distribution hole is the same length (since such gas distribution holes may span between the lower horizontal surface of the showerhead and the horizontal portions of the lower internal surface of the showerhead). If the lower rounded regions were sized the same as the upper rounded regions, there would only be a relatively small area of the lower internal surface of the showerhead in which such gas distribution holes could be positioned and still all be the same length. Any inaccuracy in where such gas distribution holes are located in such a showerhead may result in such gas distribution holes having different lengths-for example, if a gas distribution hole happens to exit into the internal region of the showerhead in a location that is within a rounded region, the length of that gas distribution hole would be longer than if it were to exit into the internal region of the showerhead in a location that is within one of the horizontal, planar regions of the lower internal surface of the showerhead.

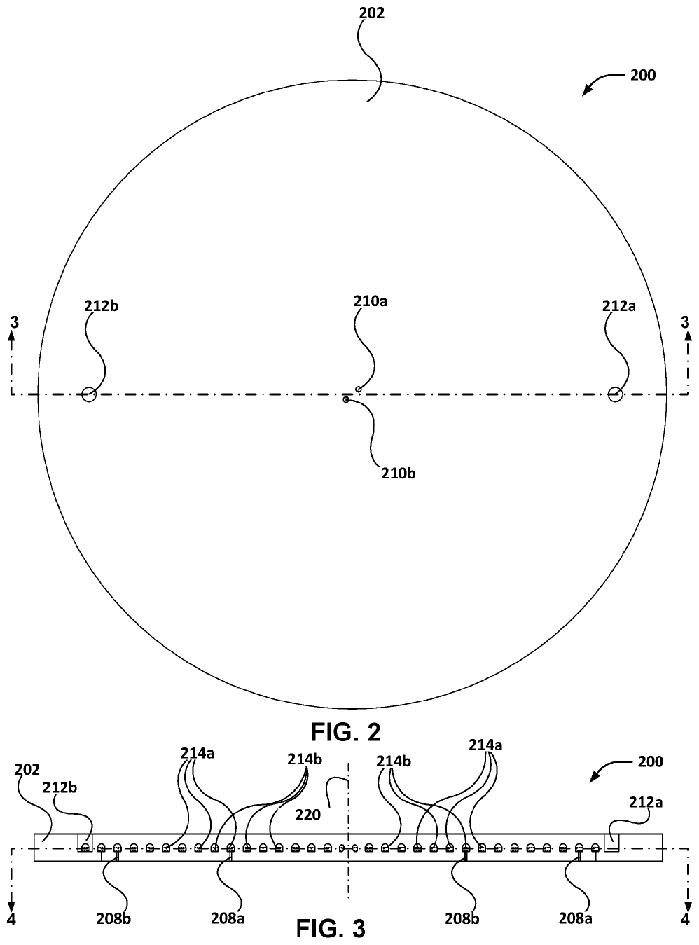

FIGS. 2 through 45 depict various examples of such showerhead designs.

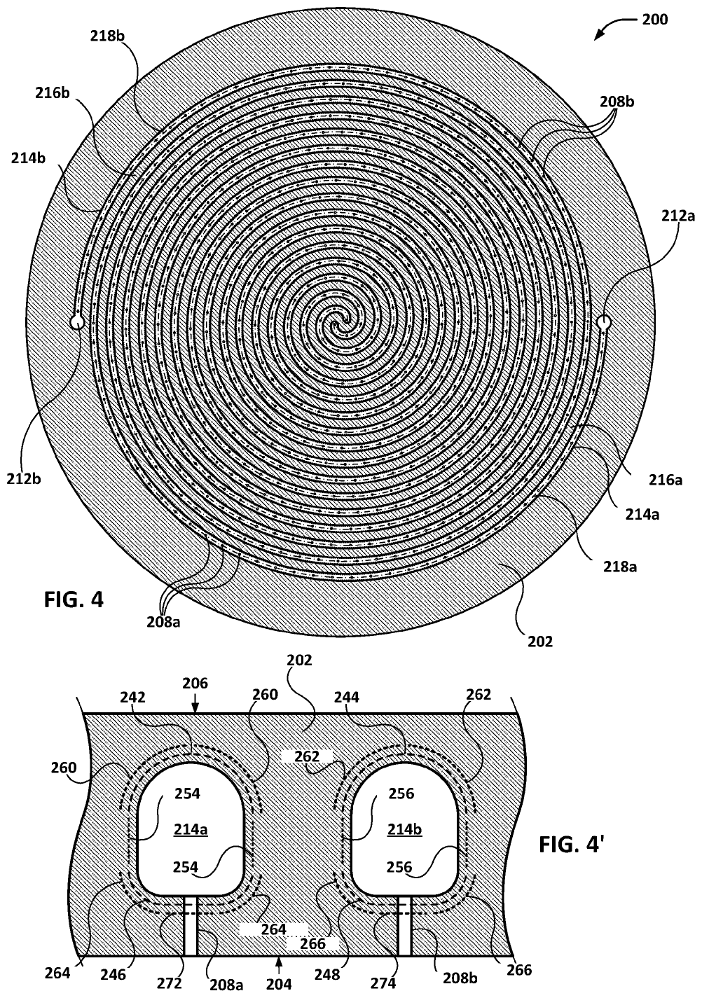

FIG. 2 is a top view of an example showerhead 200 configured to separately deliver two process gases using internal spiral passages. FIG. 3 is a section view of the example showerhead 200 of FIG. 2 taken along the indicated section line. FIG. 4 is a section view of the example showerhead 200 of FIG. 2 taken along the section line indicated in FIG. 3. FIG. 4′is a section detail view of a pair of radially adjacent spiral passages of the example showerhead 200 of FIG. 2.

As can be best seen in FIG. 4, the showerhead 200 includes a main body 202 with a pair of spiral passages 214a and 214b that follow spiral paths 218a and 218b, respectively, that are 180° out of phase with the other relative to a center axis 220 of the spiral paths 218a and 218b (although coaxial with one another; it will be understood that spiral paths that are coaxial with one another, in the context of this disclosure, refer to spiral paths that share a common spiral path center axis). The spiral passages 214 may be, for example, 6 mm to 25.5 mm in width in some implementations, and may be separated from one another by walls 216a and 216b for example. The spiral paths 218a and 218b are, in this example, spiral paths with the same pitch and number of revolutions, e.g., between 5 and 15 revolutions. Such dimensional ranges may provide a sufficient degree of uniformity in the distribution of gas across a portion of the underside of the showerhead that is approximately 330 mm to 360 mm in diameter. The spiral passages 214a and 214b each have a cross-section along most or all of their lengths as shown in FIG. 4′, which depicts a cross-sectional detail view of two adjacent portions of spiral passages 214a and 214b. As shown in FIG. 4′, the first spiral passage 214a and the second spiral passage 214b have cross-sectional profiles that include a first segment 242 and a second segment 244, respectively, that form the “ceiling” of those spiral passages 214 (assuming the showerhead 200 is oriented as shown in FIG. 4′. The cross-sectional profile, for clarity, is shown as a heavy, solid black line bounding the interiors of the spiral passages 214; the additional lines shown offset from the solid black lines and as dotted or dashed lines are intended to identify portions of the solid black line that correspond to those dotted or dashed lines. The cross-sectional profile of the first spiral passage 214a may further include a third segment 246 and a pair of first side segments 254, each of which may span between the first segment 242 and the third segment 246. Similarly, the cross-sectional profile of the second spiral passage 214b may further include a fourth segment 248 and a pair of second side segments 256, each of which may span between the second segment 244 and the fourth segment 248.

The first segment 242 may include first rounded transition regions 260 where the first segment 242 connects with the first side segments 254. The first rounded transition regions may, for example, smoothly blend with the first side segments 254 so as to avoid sharp interior edges along the length of the first spiral passage 214a Similarly, the second segment may include second rounded transition regions 262 where the second segment 244 connects with the second side segments 256.

Somewhat similarly, the third segment 246 may include third rounded transition regions 264 where the third segment 246 connects with the first side segments 254. The third rounded transition regions 264 may, for example, also smoothly blend with the first side segments 254 so as to avoid sharp interior edges along the length of the first spiral passage 214a Similarly, the fourth segment may include fourth rounded transition regions 266 where the fourth segment 248 connects with the second side segments 256.

As alluded to earlier, the first rounded transition regions 260 may be generally larger than the third rounded transition regions 264, while the second rounded transition regions 262 may be generally larger than the fourth rounded transition regions 266. For example, the third rounded transition regions 264 and the fourth rounded transition regions 266 may be filleted or rounded interior edges with a 0.01″ to 0.02″ radius, while the first rounded transition regions 260 and the second rounded transition regions 262 may be filleted or rounded interior edges with radii equal to approximately half the width of the spiral passages 214 (which may be on the order of a millimeter or more in width, e.g., 2 mm to 6 mm in width in some examples. Such an arrangement allows the first segment 242 and the second segment 244 to, in some instances, be in the shape of an arch (either a semicircular arch, as shown, or a parabolic arch). In such instances, the first segment 242 and the second segment 244 may be generally free of any horizontal portions, except for very small portions at the highest points of the first segment 242 and the second segment 244 (where the slope of the first segment 242 and the second segment 244 reverses through zero). Such cross-sectional profiles may be used to prevent issues during additive manufacturing of such showerheads 200. For example, by avoiding horizontal spans in the first segment 242 and the second segment 244, the potential for partial collapse of the spiral passages 214 during additive manufacturing may be reduced or eliminated. At the same time, the elimination of sharp interior corner edges in the cross-sectional profiles of the spiral passages 214 reduces the chances of particulates being trapped within the showerhead 200 and then later being dislodged and potentially contaminating a wafer being processed therewith.

As can be seen in FIG. 4, the spiral passages 214a and 214b each follow, respectively, spiral paths 218a and 218b. In some implementations, the spiral paths 218 may have outer diameters that are equal to at least a diameter of a wafer, e.g., 300 mm, to be processed using the showerhead 200 (the outer diameter of a spiral path being understood to be the diameter of a circle centered on the spiral center point and touching the outermost end of the spiral path). In some implementations, the spiral paths may have outer diameters that are at least 330 mm or 350 mm in diameter. The spiral paths 218a and 218b extend from points near the center of the showerhead 200 that coincide with inlet ports 210a and 210b, respectively, and then spiral radially outward to terminate at, for example, outlet ports 212a and 212b, respectively. A plurality of first gas distribution holes 208a, each extending from, and fluidically connecting, the second side 206 of the showerhead 200 to the first spiral passage 214a may be located along the first spiral path 218a, while a plurality of second gas distribution holes 208b, each extending from, and fluidically connecting, the second side 206 of the showerhead 200 to the second spiral passage 214b may be located along the second spiral path 218b. The first inlet port 210a may, for example, fluidically connect with the first spiral passage 214a and a location on the exterior surface of the showerhead 200 to allow one or more first gases to be delivered to the first spiral passage 214a for distribution via the first gas distribution holes 208a. Similarly, the second inlet port 210b may, for example, fluidically connect with the second spiral passage 214b and another location on the exterior surface of the showerhead 200 to allow one or more second gases to be delivered to the second spiral passage 214b for distribution via the second gas distribution holes 208b.

The outlet ports 212a and 212b are optional and may be used to allow a polishing slurry or other polishing fluid to be pumped/circulated through the spiral passages 214 after additive manufacturing of the showerhead 200 is complete. For example, such a polishing fluid may be pumped into the first spiral passage 214a via the first inlet port 210a and may then flow through the first spiral passage 214a before exiting the first spiral passage 214a via the first outlet port 212a. Similarly, the polishing fluid may also be pumped into the second spiral passage 214b via the second inlet port 210b and may then flow through the second spiral passage 214b before exiting the second spiral passage 214b via the second outlet port 212b. After such polishing is completed, the outlet ports 212a and 212b may be plugged, sealed, or otherwise capped off. In some implementations, the outlet ports 212a and 212b may be plugged, sealed, or otherwise capped off using removable plugs or caps such that, for example, fluid may be introduced into, or removed from, the spiral passages 214a and 214b via both or either of the outlet ports 212a and 212b and the inlet ports 210a and 210b. For example, a cleaning slurry or fluid may be circulated through the spiral passages 214a and 214b at an increased velocity by flowing the cleaning slurry or fluid into the spiral passages 214a and 214b via the inlet ports 210a and 210b, respectively, and out of the spiral passages 214a and 214b via the outlet ports 212a and 212b, respectively (as compared with the flow velocity that may be achieved by flowing such slurry or fluid from the spiral passages 214a and 214b via the gas distribution holes 208a and 208b).

In the depicted example, the first gas distribution holes 208a are all the same size and are equidistantly spaced along the first spiral path 218a and the second gas distribution holes 208b are also all the same size and are equidistantly spaced along the second spiral path 218b. However, in other implementations, the gas distribution holes may be differently configured, e.g., to bias gas flow from the showerhead 200 so as to vary as a function of radius and/or azimuthal position. For example, the spacing of gas distribution holes along the spiral paths may be caused to vary through one or more portions of the spiral paths, resulting in the gas distribution holes 208 for a spiral passage being more closely spaced together (thus increasing the rate of gas flow in such regions) or more widely spaced apart in different annular regions of the showerhead 200. Alternatively, or additionally, the size of the gas distribution holes 208 for a spiral passage may be varied as a function of radial position from the center of the spiral passage to produce a similar effect, e.g., increasing the diameter of the gas distribution holes 208 to increase the amount of gas flow and decreasing the diameter of the gas distribution holes 208 to decrease the amount of gas flow.

It will also be understood that the inlet ports 210 that are shown located near the center of the showerhead 200 do not necessarily need to be located in such a position. For example, the inlet ports 210 may instead be located at the opposite ends of the spiral passages 214 so as to flow gas inward towards the center of the showerhead 200 through the spiral passages 214 instead of outward towards the outer perimeter of the showerhead 200. In some instances, the inlet ports 210 may instead be located so as to fluidically connect with the spiral passages 214 at locations other than at the ends thereof, e.g., at one or more locations that are at some point between, e.g., midway between, the end points of the spiral paths 218. It will also be understood that multiple inlet ports 210 may be provided for a given spiral passage 214, thereby allowing gas to be introduced at multiple locations along the length of the spiral passage 214.

The spiral passages are located within a main body of the showerhead and are interposed between a first side of the main body and a second side of the main body. The second side of the main body is on the opposite side of the main body from the first side.

As can be seen, each spiral passage has a corresponding plurality of gas distribution holes that extend from a first side of the main body to the corresponding spiral passage, thereby fluidically connecting that spiral passage with the ambient environment beneath the showerhead (or above the showerhead if the showerhead is oriented to direct the process gases vertically upward instead of downward, as may done in backside-deposition or etch chambers).

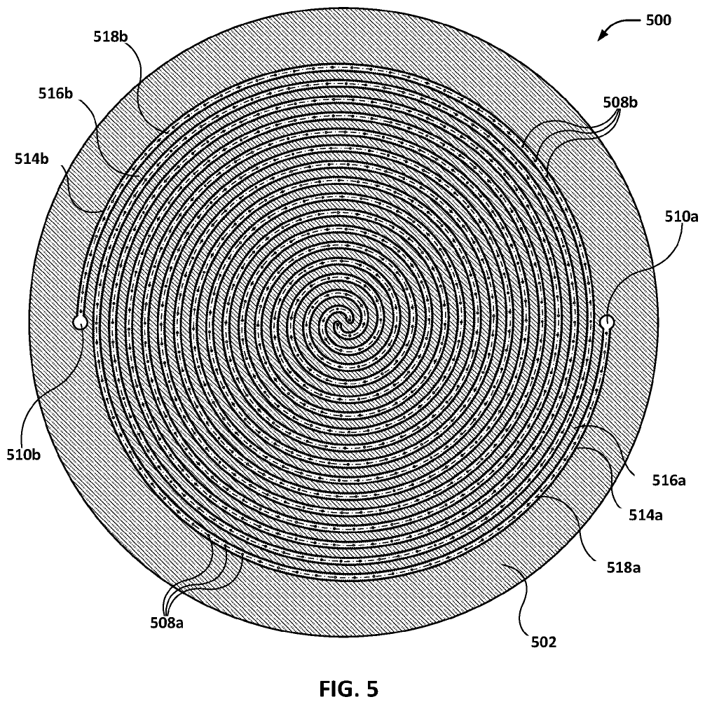

FIG. 5 depicts a cross-sectional view of a showerhead 500 having a main body 502 that has within it two spiral passages 514a and 514b that follow spiral paths 518a and 518b, respectively, that are 180° out of phase with the other relative to a center axis of the spiral paths 518a and 518b (e.g., similar to the showerhead 200 of FIG. 4). The spiral passages 518 may be, for example, 6 mm to 25.5 mm in width in some implementations. The spiral paths 518a and 518b are, in this example, spiral paths with the same pitch and number of revolutions, e.g., between 5 and 15 revolutions. Such dimensional ranges may provide a sufficient degree of uniformity in the distribution of gas across a portion of the underside of the showerhead that is approximately 330 mm to 360 mm in diameter. The spiral passages 514a and 514b may be separated from one another by intervening walls 516a and 516b. Each of the spiral passages 514a and 514b have, respectively, a plurality of first gas distribution holes 508a and a plurality of second gas distribution holes 508b distributed along its length; such gas distribution holes 508 may be used to flow gas from the spiral passages downward onto a wafer positioned beneath the showerhead 500.

Unlike the showerhead 200 of FIG. 4, however, the showerhead 500 has inlet ports 510a and 510b that are located at the outermost ends, respectively, of the spiral passages 514a and 514b. Thus, gas that is flowed into the showerhead 500 via the inlet ports 510a and 510b will flow along the spiral passages 514a and 514b in an inward-spiraling manner, towards the center of the showerhead 500.

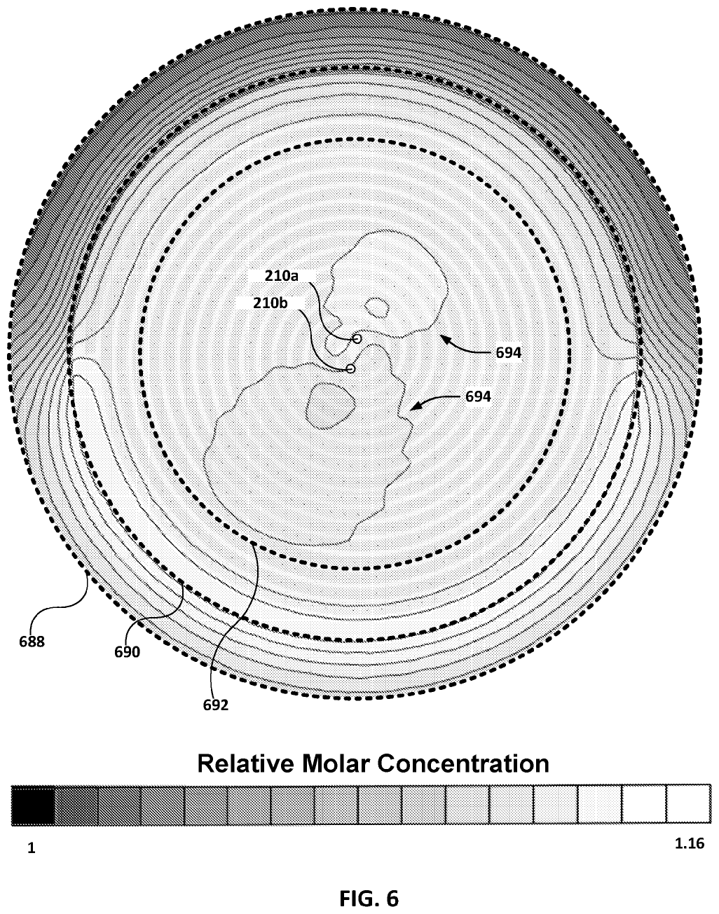

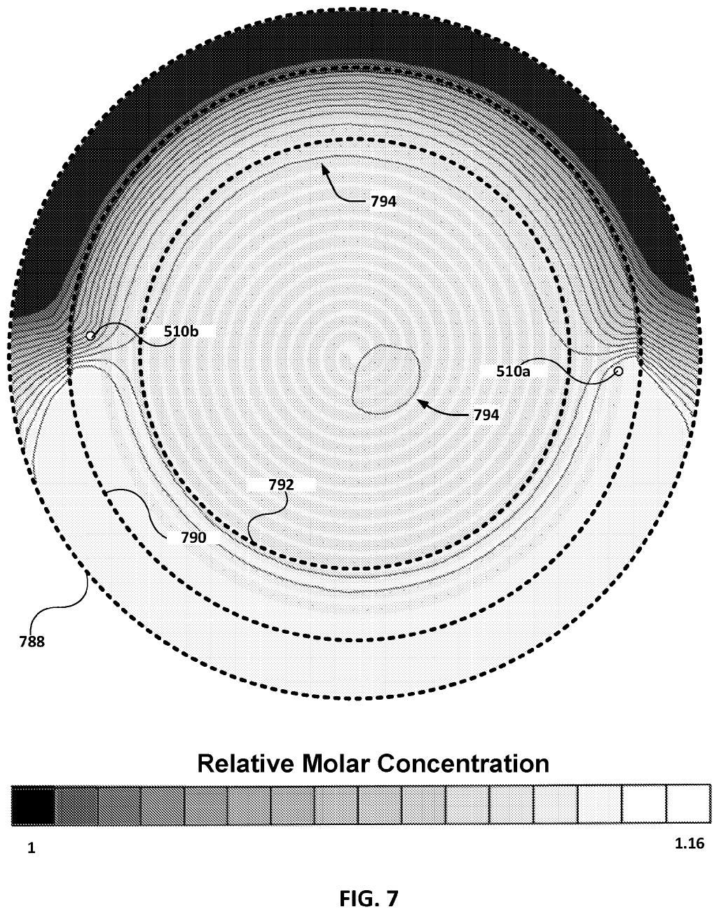

Such an approach provides a notable, and somewhat unexpected, benefit as compared with the showerhead 200 discussed earlier. This is illustrated in FIGS. 6 and 7. FIG. 6 depicts analysis results showing the relative molar concentration of a reactant flowed through a showerhead such as the showerhead 200, i.e., a showerhead with two spiral passages 214a and 214b having, respectively, inlet ports 210a and 210b located at the innermost ends of the spiral passages 214a and 214b, respectively. Thus, in FIG. 6, the showerhead has two inlet ports 210a and 210b that are located near the center of the showerhead, e.g., at the innermost ends of the spiral passages 214 located within the showerhead. The spiral passages in FIG. 6 are not specifically called out but are faintly visible within the showerhead. FIG. 6 also depicts three dotted circles indicating, respectively, the outer perimeter of a wafer 692, the outer perimeter of a pedestal 690 on which the wafer 692 rests, and an outer perimeter 688 of the showerhead. In FIG. 6, the relative molar concentration is shown for a reactant flowed through only one of the spiral passages 214, e.g., the spiral passage 214a.

Gradient shading is applied to FIG. 6 to indicate different relative molar concentrations of the above-referenced reactant. FIGS. 7, 9, 13, and 17 also depict analysis results for other implementations using similar gradient shading; to allow for the analysis results of all three Figures to be easily compared and contrasted, the number of gradient steps and the upper and lower bounds of the values represented by the gradient colors are the same between each of FIGS. 6, 7, 9, 13, and 17. For clarity, sixteen different shades of grey are used in the Figures to allow the contours (shown in black lines) between those sixteen (or however many are actually shown in each Figure) to be easily seen. However, it will be understood that the maximum and minimum values shown in each of these Figures in the gradient bar legend/scale along the bottom of each such Figure may not necessarily appear in each of these Figures (although each grey value will be shown in at least one such Figure).

As can be seen in FIG. 6, there are localized non-uniformity zones 694 on the wafer 692 where the relative molar concentration is up to 3 times larger than across the remainder of the wafer 692. These localized non-uniformity zones 694 extend across about 25% of the top surface of the wafer 692.

FIG. 7 depicts analysis results showing the relative molar concentration of the reactant flowed through a showerhead such as the showerhead 500, i.e., a showerhead with two spiral passages 514a and 514b having inlet ports 510a and 510b located at the outermost ends of the spiral passages 514a and 514b, respectively. Thus, in FIG. 7, the showerhead has two inlet ports 510a and 510b that are located near the periphery of the showerhead, e.g., at the outermost ends of the spiral passages located within the showerhead. The reactant for which the relative molar concentration is shown in FIG. 7 is, in this example, provided via the spiral passage 514a. As can be seen in FIG. 7, whereas the showerhead of FIG. 6 generated two localized non-uniformity zones 694 that were located near the center of the wafer 692 and that spanned across about 25% of the wafer 792, the showerhead of FIG. 7 generated non-uniformity zones 794 (the generally circular-shaped non-uniformity zone 794 near the center of the wafer 792 and the thin, C-shaped non-uniformity zone 794 along the upper edge, with respect to the Figure orientation, of the wafer 792) having a much smaller total area as compared with the total area of the non-uniformity zones 694. Additionally, the difference in relative molar concentration in the non-uniformity zones 794 and the relative molar concentration across the remainder of the wafer 792 is approximately 50% less than in the example of FIG. 6.

However, it will be noted that the relative molar concentration outside of the boundary of the wafer 792 now exhibits a marked asymmetry, e.g., the molar concentration on the right side of the pedestal 790 and the chamber 788 is about 15% higher than on the left side of the pedestal 790 and the chamber 788 (in both cases, this refers to the regions thereof outside of the outer perimeter of the wafer 792. This may result in the pedestal 790 and the chamber 788 experiencing non-uniform exposure to the reactants that are flowed through the showerhead. This, in turn, may result in uneven etching or deposition (depending on the reactants) of the pedestal 790 and/or the chamber 788 (or components associated with either). This may increase the frequency with which cleaning operations may need to be performed, e.g., to remove undesired deposition from the pedestal 790 and/or the chamber 788 (which may, for example, accumulate much faster in some areas than in others due to the uneven relative molar concentration of the reactants).

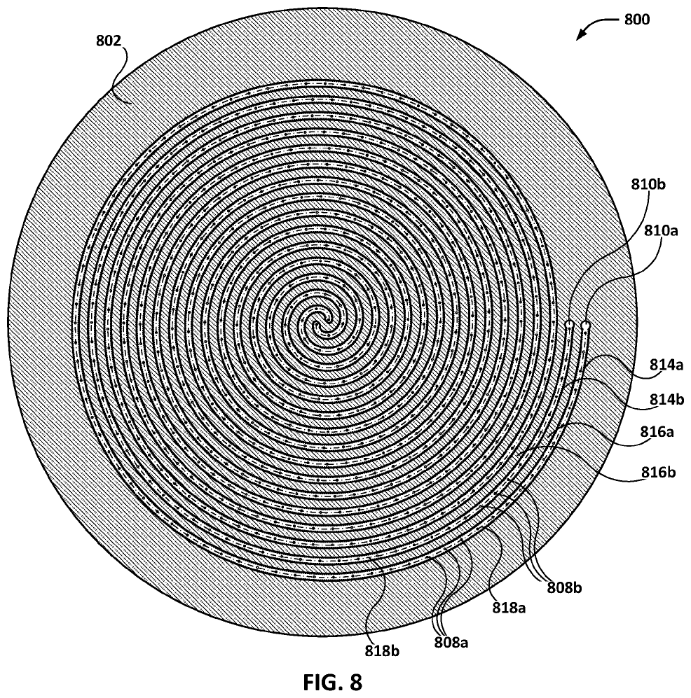

FIG. 8 depicts a cross-sectional view of a showerhead 800 having a main body 802 that has within it two spiral passages 814a and 814b that follow spiral paths 818a and 818b, respectively, that are 180° out of phase with the other relative to a center axis of the spiral paths 818a and 818b (e.g., similar to the showerhead 500 of FIG. 5). The spiral passages 818 may be, for example, 6 mm to 25.5 mm in width in some implementations. The spiral paths 818a and 818b are, in this example, spiral paths with the same pitch but differing numbers of revolutions, e.g., between 5 and 15 revolutions for one and half a revolution more or less for the other. This has the effect of locating the inlet ports 810a and 810b at the same azimuthal position. The spiral passages 814a and 814b may be separated from one another by intervening walls 816a and 816b. Each of the spiral passages 814a and 814b have, respectively, a plurality of first gas distribution holes 808a and a plurality of second gas distribution holes 808b distributed along its length.

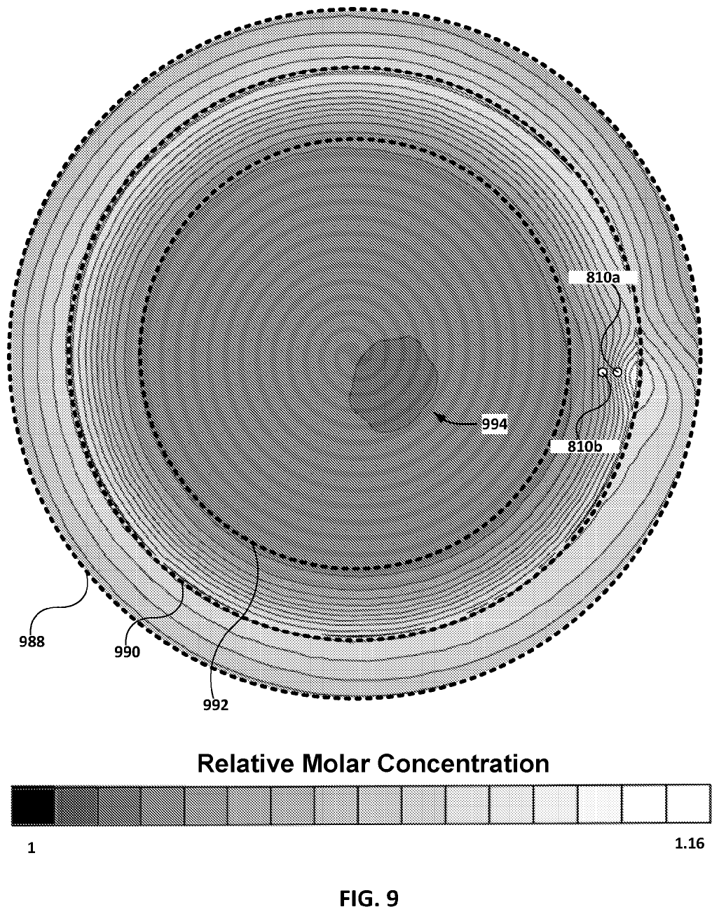

FIG. 9 depicts analysis results showing the relative molar concentration of the reactant flowed through a showerhead such as the showerhead 800, i.e., a showerhead with two spiral passages 814a and 814b having inlet ports 810a and 810b located at the outermost ends of the spiral passages 814a and 814b, respectively, and positioned at the same azimuthal location. Thus, in FIG. 9, the showerhead has two inlet ports 810a and 810b that are located near the periphery of the showerhead, e.g., at the outermost ends of the spiral passages located within the showerhead, and at the same azimuthal location. The relative molar concentration shown in FIG. 9 is for the reactant when flowed through the spiral passage 914a via the inlet port 810a As can be seen in FIG. 9, whereas the showerhead of FIG. 8 generated a relative molar concentration of the reactant flowed through the showerhead that demonstrated significant bilateral asymmetry in the region between the outer edge of the wafer 892 and the chamber 888, the showerhead of FIG. 9 demonstrates a much higher degree of azimuthal uniformity in the region between the outer edge of the wafer 992 and the chamber 988. Thus, showerheads such as those of FIG. 8 may not only significantly reduce the extent and magnitude of localized non-uniformity zones that may be present over the wafers processed with such showerheads, they may also significantly increase the azimuthal uniformity about the periphery of the wafer, e.g., between the wafer and the chamber walls. Such implementations may offer enhanced wafer processing uniformity on a wafer 992 as compared with some other implementations and may also cause more uniform incidental deposition or etching on surfaces of a chamber 988 and/or a pedestal 990.

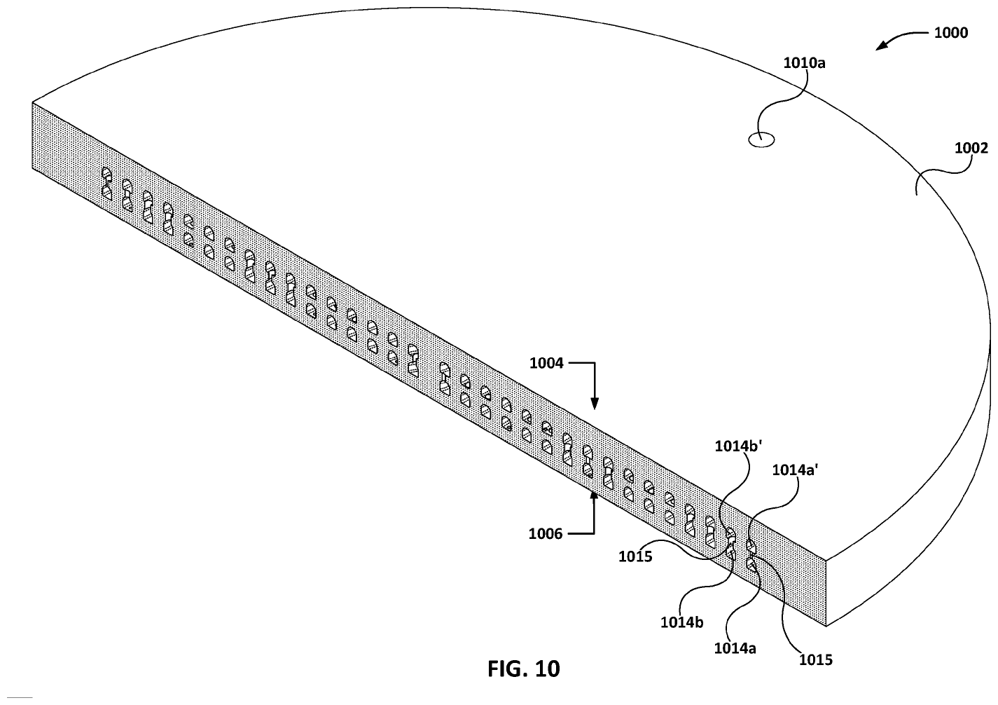

FIG. 10 depicts an isometric cutaway view of an example showerhead having dual-level spiral passages. In FIG. 10, showerhead 1000 is shown with a first inlet port 1010a visible in a first side 1004 of the showerhead 1000; a second inlet port is located on an opposite side of the showerhead 1000 (which is cut away in this view). The showerhead 1000 may include a main body 1002, which may include within it, similar to the spiral passages 214a/b in main body 202, a first spiral passage 1014a and a second spiral passage 1014b (see FIG. 11, which depicts, at bottom, an isometric top section view of the showerhead 1000 along the section line indicated in the side view of the showerhead 1000 at the top of FIG. 11). The first and second spiral passages 1014a and 1014b may be arranged in a similar manner, e.g., in a circular array about a common center axis and spaced 180° out of phase with each other about the common center axis. The first spiral passage 1014a may have first gas distribution holes 1008a distributed along its length. Each first gas distribution hole 1008a may connect between the second side 1006 of the main body 1002 and the first spiral passage 1014a. Similarly, the second spiral passage 1014b may have second gas distribution holes 1008b distributed along its length. Each second gas distribution hole 1008b may connect between the second side 1006 of the main body 1002 and the second spiral passage 1014b. In the above respects, the showerhead 1000 is very similar to the showerhead 200 or the showerhead 500, discussed earlier.

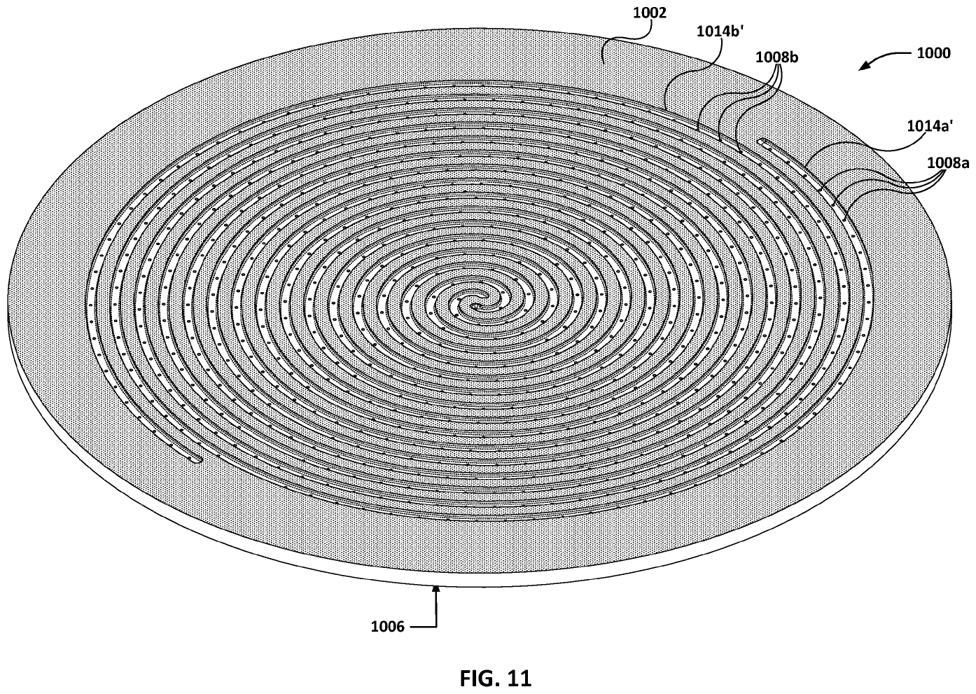

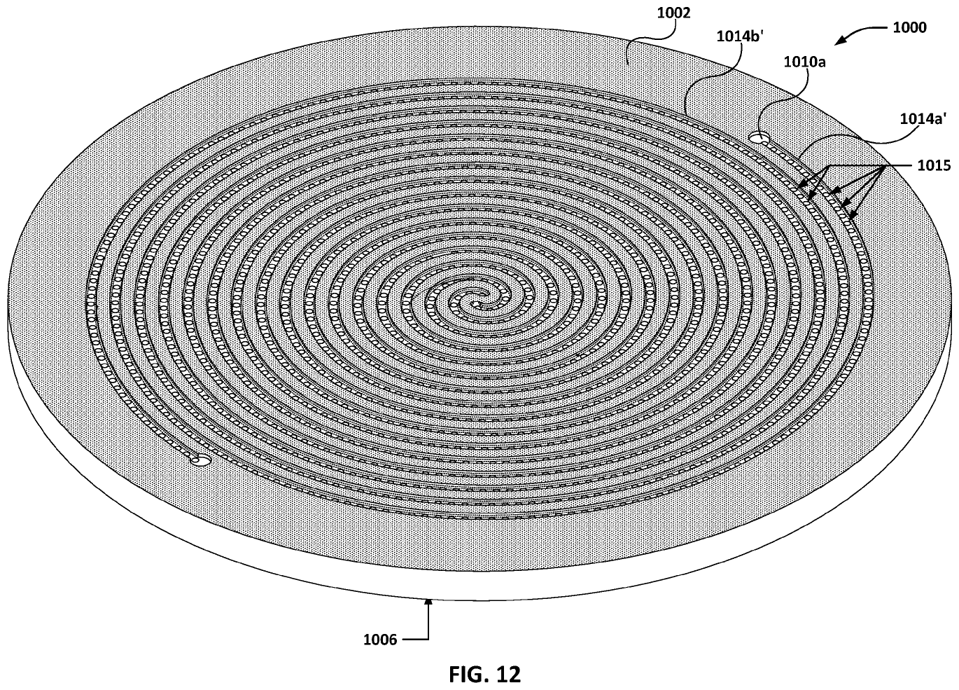

However, the main body 1002 differs from the main bodies 202 and 502 in that the main body 1002 also includes an additional first spiral passage 1014a′ and an additional second spiral passage 1014b′ (see FIG. 12, which depicts, at bottom, an isometric top section view of the showerhead 1000 along the section line indicated in the side view of the showerhead 1000 at the top of FIG. 12). The first spiral passage 1014a′ may generally follow the same spiral path followed by the first spiral passage 1014a but offset towards the first side 1004 of the main body 1002 such that the first spiral passage 1014a is at a lower elevation in the main body 1002 than the first spiral passage 1014a′. Thus, when viewed along a direction normal to the first side 1004, the first spiral passage 1014a and the first spiral passage 1014a′ may generally overlap each other in a generally continuous manner along their lengths. Similarly, the second spiral passage 1014b′ may generally follow the same spiral path followed by the second spiral passage 1014b, but also offset towards the first side 1004 of the main body 1002 such that the second spiral passage 1014b is at a lower elevation in the main body 1002 than the second spiral passage 1014b′. In FIG. 10, the first spiral passage 1014a′ and the second spiral passage 1014b′ have cross-sectional profiles that are, as shown, the same as those of the first spiral passage 1014a and the second spiral passage 1014b, respectively, but it will be understood that the first spiral passage 1014a′ and the second spiral passage 1014b′ in other implementations may have cross-sectional profiles that are different from those of the first spiral passage 1014a and the second spiral passage 1014b.

The first spiral passage 1014a and the first spiral passage 1014a′ may be fluidically connected with one another by a plurality of riser passages 1015 that span between the first spiral passage 1014a and the first spiral passage 1014a′. Such riser passages 1015 may, for example, be distributed along the lengths of the first spiral passages 1014a/1014a′, e.g., distributed in a spaced-apart manner. The riser passages 1015 may, for example, be spaced apart by a distance that is on the order of one, two, or three times the diameters of the riser passages 1015 The riser passages 1015 may be sized to have relatively large diameters, e.g., multiple times larger than the diameters of the gas distribution holes of the showerhead 1000, such that the flow resistance between the first spiral passage 1014a and the first spiral passage 1014a′ via the riser passages 1015 is much lower than the flow resistance from the first spiral passage 1014a to the second side 1006 via the first gas distribution holes 1008a. The riser passages 1015 may, in some instances, have diameters that are on the order of 75% to 100% of the widths of the first spiral passages 1014a and/or the first spiral passages 1014a′.

Such an arrangement may be particularly useful in laminated ceramic showerheads, which are discussed in more detail later in this disclosure. For example, in some laminated ceramic manufacturing techniques, there may be a height-to-width aspect ratio limit that may constrain the design of the spiral passages. For example, it may be difficult to manufacture laminated ceramic parts having spiral passage depths that are greater than twice the width of such spiral passages. As a result, if a given cross-sectional area in such spiral passages is needed in order to provide for a desired level of flow conductance along such spiral passages, there will be a certain minimum width that such spiral passages will need to be in order to provide that cross-sectional area and desired flow conductance while still staying within the maximum height-to-width ratio. That minimum width, in turn, will limit the spiral pitch that the spiral passages may have and thus the number of spiral turns of such spiral passages that will fit within the volume of the showerhead 1000 and how close such spiral passages can be to one another. This, in turn, limits how close the first gas distribution holes 1008a on adjacent spiral turns can be to one another and how densely the first gas distribution holes 1008a can be arranged on the second side 1006 of the main body 1002.

However, such spacing limitations may be overcome by using a showerhead design such as the showerhead 1000. For example, the first spiral passages 1014a, the riser passages 1015, and the first spiral passages 1014a′ may, in aggregate, function as a single, unified plenum volume due to the relatively large size of the riser passages 1015 as compared with the first gas distribution holes 1008a. Such a unified plenum volume may have an overall height-to-width ratio that exceeds the maximum height-to-width ratio that typically limits channel depths in such laminated ceramic showerheads 1000. At the same time, the individual first spiral passages that may be machined or formed in the layers of ceramic material used to make the main body 1002 in order to provide the first spiral passages 1014a and the first spiral passages 1014a′ have height-to-width aspect ratios that are less than the maximum height-to-width ratio discussed above.

The second spiral passage 1014b and the second spiral passage 1014b′ may be similarly connected together with corresponding riser passages 1015 and may be arranged in an analogous manner to provide similar benefits.

It will be understood that the implementation shown in FIGS. 10 through 12 features rounded or arched top surfaces to the spiral passages, as well as rounded bottom edges of the spiral passages. Such features, as discussed elsewhere herein, may be included to facilitate manufacturing such showerheads via additive manufacturing. In other implementations, such spiral passages may have flat bottoms and/or flat tops. For example, if such a showerhead is manufactured by laminating multiple machined or formed ceramic layers together, the spiral passages may be machined or otherwise formed in one or more of the layers, and then capped by another of the layers when the layers are bonded together. In such implementations, the top surfaces and/or the bottom surfaces of the spiral passages may, for example, exhibit sharp edges, e.g., 90° corners.

The gas that is flowed into the showerhead 200 via the first inlet port 1010a and the second inlet port 1010b (not shown, but symmetric to inlet port 1010a about the section plane of FIG. 10) may first flow into the first spiral passage 1014a′ and the second spiral passage 1014b′, respectively, and then flow into the first spiral passage 1014a and the second spiral passage 1014b, respectively, before flowing out of the first gas distribution holes 1008a and the second gas distribution holes 1008b, respectively.

Such an approach allows for such showerheads 1000 to have gas distribution holes that are densely distributed, thereby more evenly distributing gas across wafers being processed thereby, while still retaining sufficiently high flow conductances within the spiral passages to avoid undesirable pressure drops along the lengths of such spiral passages that may negatively affect radial uniformity of the gas distribution. It will be appreciated that while the showerhead 1000 has inlet ports 1010a and 1010b that are positioned on opposite sides of the showerhead, other such implementations may feature inlet ports 1010a and 1010b on the same side of the showerhead 1000, e.g., similar to the configuration of the showerhead 500.

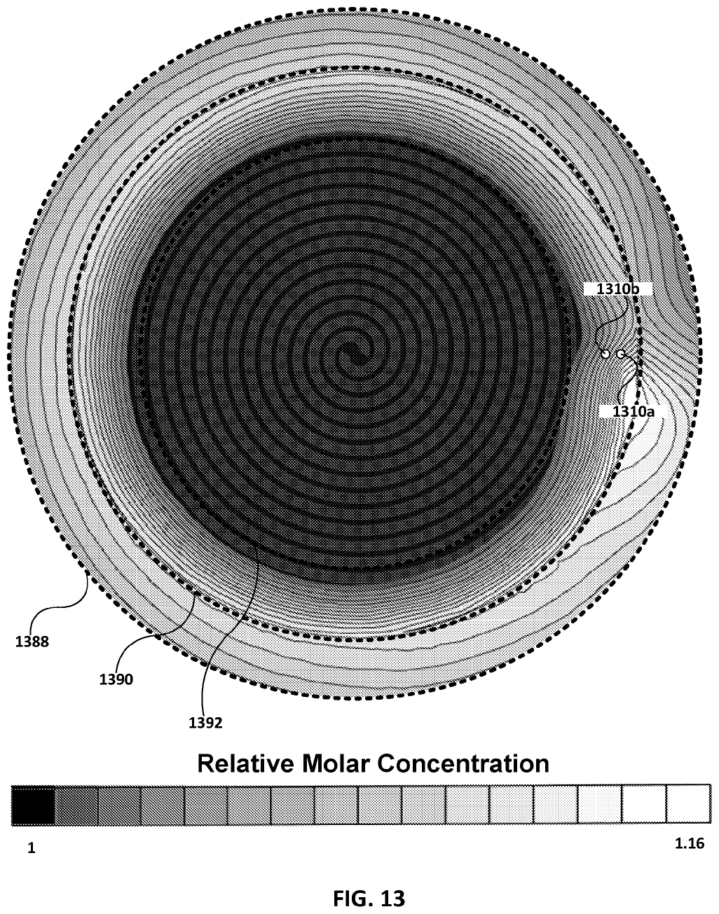

FIG. 13, for example, depicts analysis results showing the relative molar concentration of a reactant flowed through a showerhead similar to the showerhead 1000, i.e., a showerhead with stacked spiral passages that may be used to provide a combined plenum that has height-to-width aspect ratio that is higher than either of the spiral passages on their own could have, but having inlet ports positioned as in the showerhead 500. For example, the showerhead in this example has two inlet ports 1310a and 1310b that are both located near the periphery of the showerhead, e.g., at the outermost ends of the spiral passages located within the showerhead, and both located in close proximity to one another azimuthally, e.g., at the same azimuthal position. Thus, the spiral path followed by the spiral passage supplied gas via the inlet port 1310a may have an extra half-turn as compared with the spiral path followed by the spiral passage supplied gas via the inlet port 1310b. The reactant for which the relative molar concentration is shown in FIG. 13 is, in this example, provided via the spiral passage supplied by inlet port 1310a. As can be seen, the gas distribution across the area of the wafer 1392 is highly uniform, both azimuthally and radially, e.g., within about a single percent of variance in relative molar concentration.

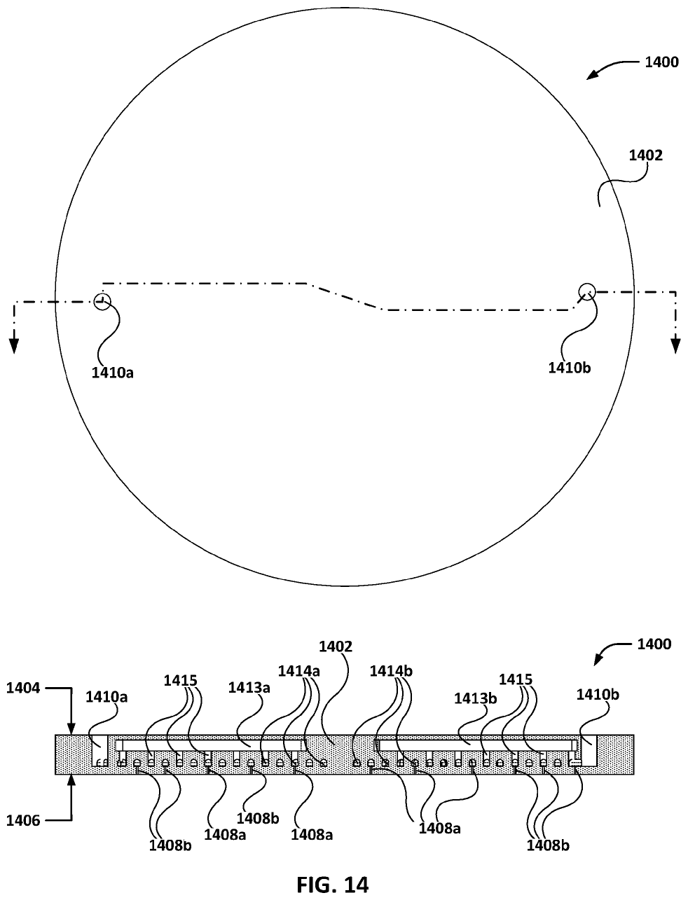

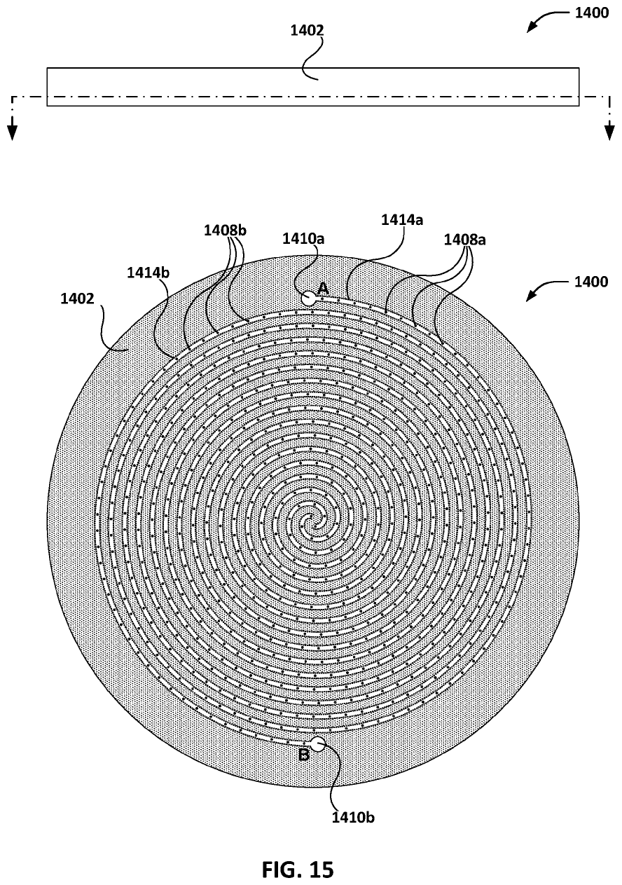

FIG. 14 depicts a top view (at top) and side section view (at bottom) of an example showerhead that includes spiral passages and spoke passages. The showerhead 1400 that is depicted in FIG. 14 provides an alternate approach for providing for more uniform gas delivery in a spiral-passage showerhead. As with other showerheads discussed above, showerhead 1400 has a main body 1402 that has a first side 1404 and a second side 1406. A first spiral passage 1414a and a second spiral passage 1414b are located within the main body 1402, as shown in FIG. 15, which depicts a side view (at top) of the showerhead 1400 and a top section view (at bottom) of the showerhead 1400 taken along the section line shown in the side view. The first and second spiral passages 1414a and 1414b may be arranged in a similar manner to the spiral passages 214 or 514, e.g., in a circular array about a common center axis and spaced 180° out of phase with each other about the common center axis. The first spiral passage 1414a may have first gas distribution holes 1408a distributed along its length. Each first gas distribution hole 1408a may connect between the second side 1406 of the main body 1402 and the first spiral passage 1414a. Similarly, the second spiral passage 1414b may have second gas distribution holes 1408b distributed along its length. Each second gas distribution hole 1408b may connect between the second side 1406 of the main body 1402 and the second spiral passage 1414b. In the above respects, the showerhead 1400 is very similar to the showerheads 200, 500, and 1000 discussed earlier.

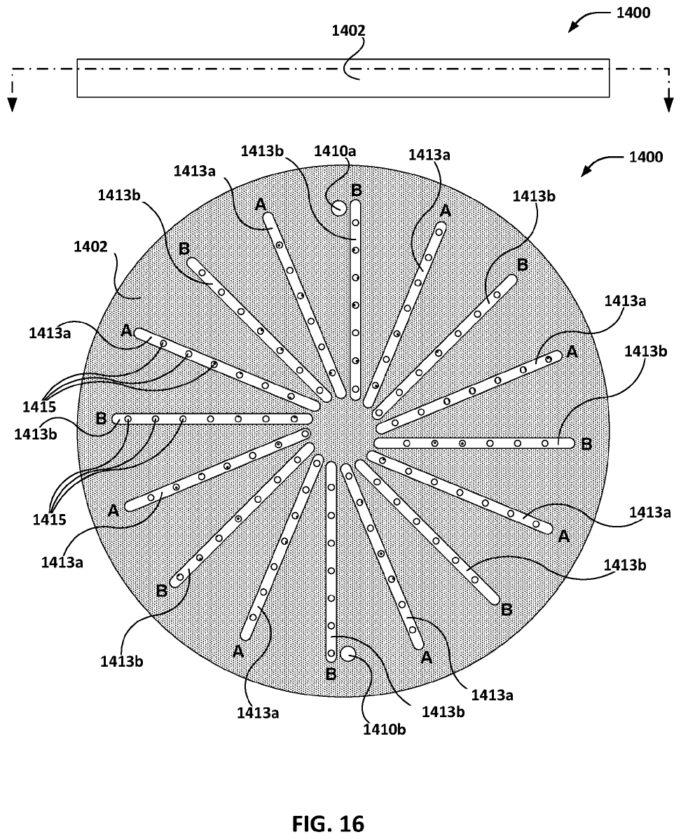

The showerhead 1400 differs from such previously discussed showerheads in that the showerhead 1400 main body 1402 includes within it a plurality of spoke passages, e.g., first spoke passages 1413a and second spoke passages 1413b, that extend outward from a center region of the main body 1402, as shown in FIG. 16, which depicts a side view (at top) of the showerhead 1400 and a top section view (at bottom) of the showerhead 1400 taken along the section line shown in the side view. The first spoke passages 1413a and the second spoke passages 1413b may be positioned in between the first side 1404 of the main body 1402 and the first and second spiral passages 1414a and 1414b.

Each first spoke passage 1413a may have a corresponding plurality of riser passages 1415 that fluidically connect that first spoke passage 1413a with the first spiral passage 1414a. More specifically, each riser passage 1415 may, for example, connect with the first spiral passage 1414a at a different location along the spiral path followed by the first spiral passage 1414a. Similarly, each second spoke passage 1413b may have a corresponding plurality of riser passages 1415 that fluidically connect that second spoke passage 1413b with the second spiral passage 1414b, e.g., each riser passage 1415 may connect with the second spiral passage 1414b at a different location along the spiral path followed by the second spiral passage 1414b. Thus, the first spoke passages 1413a may serve, in effect, as radial (or somewhat radial) “bridges” that connect adjacent turns of the first spiral passage 1414a together, thereby providing a fluidic shortcut between adjacent turns of the first spiral passage 1414a. The second spoke passages 1413b may serve similarly with respect to the second spiral passage 1414b. It will be understood that the first and second radial spoke passages 1413a and 1413b are fluidically isolated from one another within the showerhead.

The first and second spoke passages 1413a and 1413b may be arranged, as shown in FIG. 16, in an alternating circular pattern, e.g., A-B-A-B-A-B . . . . , such that the gases flowed through each spiral passage 1414a and 1414b are provided with generally radially symmetric flow paths about the circumference of the showerhead 1400.

The spoke passages for such showerheads may allow such showerheads to exhibit enhanced radial uniformity in gas distribution as compared with showerhead designs without such spoke passages. For example, in a showerhead having spiral passages but no spoke passages, the gas that is flowed through the spiral passages to the gas distribution hole that is furthest from the inlet port through which that gas was introduced into the showerhead would need to flow along the entire length of that spiral passage before reaching the gas distribution hole at the opposite end of the spiral passage from the inlet port. However, in a showerhead with spiral passages linked by spoke passages, such as the showerhead 1400, the spoke passages for a given spiral passage may allow gas introduced via the inlet port for that spiral passage to reach any of the gas distribution holes for that spiral passage that are more distant from the inlet port via a much shorter flow path than would be possible absent the spoke passages. This serves to more evenly distribute the gas flow in the radial direction.

It will be appreciated that while the showerhead 1400 has inlet ports 1410a and 1410b that are positioned on opposite sides of the showerhead, other such implementations may feature inlet ports 1410a and 1410b on the same side of the showerhead 1400, e.g., similar to the configuration of the showerhead 500.

As with the implementation shown in FIGS. 10 through 12, the implementation of FIGS. 14 through 16 features rounded or arched top surfaces to the spiral passages, as well as rounded bottom edges of the spiral passages. The spoke passages, however, have flat bottom and top surfaces. The rounded features of the spiral passages, as discussed earlier, may be included to facilitate manufacturing such showerheads via additive manufacturing. In such a showerhead, the spoke passages, may similarly have rounded or arched top surfaces and, in some cases, rounded edges bounding the bottom surfaces. This is not shown in FIGS. 14 through 16 but will be understood to nonetheless be within the scope of this disclosure. In other implementations, such spiral passages may have flat bottoms and/or flat tops, e.g., similar to how the spoke passages are depicted in FIGS. 14 through 16. For example, if such a showerhead is manufactured by laminating multiple machined or formed ceramic layers together, the spiral passages may be machined or otherwise formed in one or more of the layers, and then capped by another of the layers when the layers are bonded together. In such implementations, the top surfaces and/or the bottom surfaces of the spiral passages may, for example, exhibit sharp edges, e.g., 90° corners.

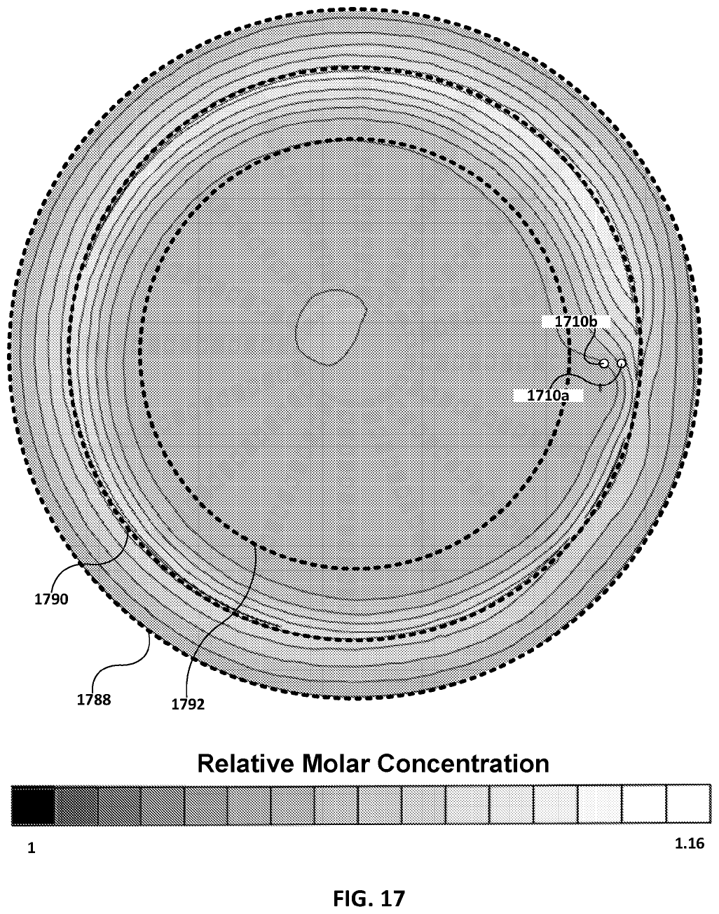

FIG. 17, for example, depicts analysis results showing the relative molar concentration of a reactant flowed through a showerhead similar to the showerhead 1400, i.e., a showerhead with spiral passages linked by spoke passages, but having inlet ports both located at the outer ends of the spiral passages and both located in close proximity to one another azimuthally, e.g., at the same azimuthal position. Thus, the spiral path followed by the spiral passage supplied gas via the inlet port 1710a may have an extra half-turn as compared with the spiral path followed by the spiral passage supplied gas via the inlet port 1710b. The reactant for which the relative molar concentration is shown in FIG. 17 is, in this example, provided via the spiral passage supplied by inlet port 1710a. As can be seen, the gas distribution across the area of the wafer 1792 is highly uniform, both azimuthally and radially, e.g., within about two percent of variance in relative molar concentration.

It will be understood that showerheads such as the showerheads 1000 and 1400 may be implemented with inlet ports that are located at the outer ends of the spiral passages, as shown, or at the inner ends of the spiral passages, e.g., similar to in the showerhead 200.

It will be understood that while the examples and analysis results discussed above are provided for showerheads having two spiral passages, similar benefits may arise in showerheads having more than two spiral passages, e.g., three or four spiral passages, when similar conventions are followed in such showerheads, e.g., locating the inlet ports at outermost ends of the spiral passages, optionally locating the inlet ports at the same azimuthal position in the showerhead, using doubled-up spiral passages, and/or using spoke passages. For the doubled-up variants, it will also be understood that there may be more than just two spiral passages that are stacked atop one another—there may be three, four, five, etc. spiral passages that are stacked atop one another, thereby allowing for very high height-to-width aspect ratios. These variants are all considered to be within the scope of this disclosure.

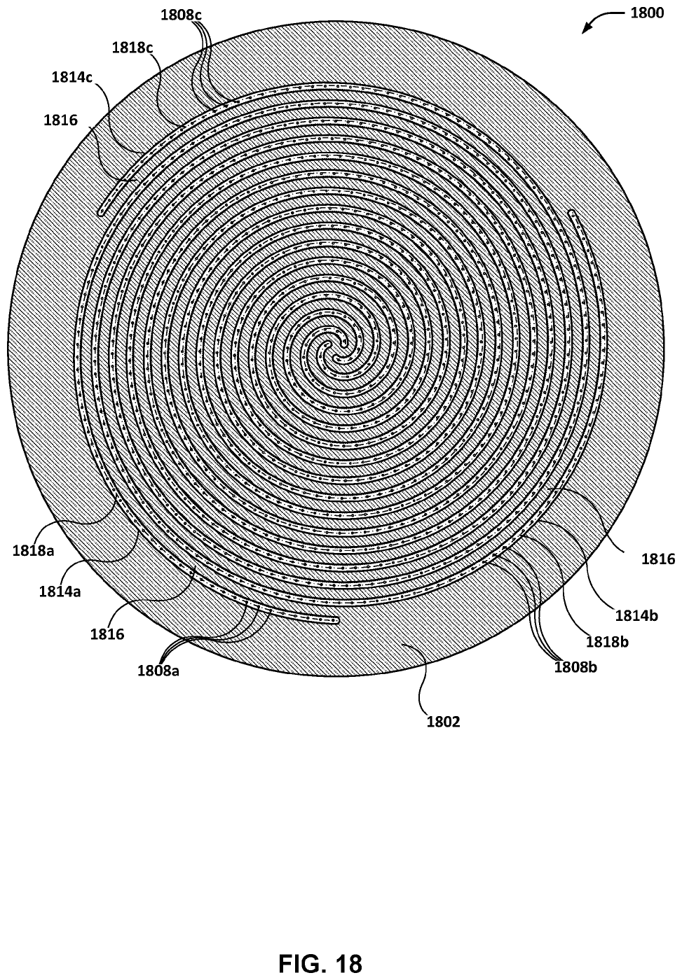

FIG. 18 is a section view of an example showerhead similar to the example showerhead of FIG. 2, but configured to separately deliver three process gases using internal spiral passages. As can be seen, the structure is similar to the example showerhead of FIG. 2, but with three spiral passages 1814a/b/c instead of two spiral passages 214 disposed within the main body 1802 of the showerhead 1800. The three spiral passages 1814a/b/c follow spiral paths 1818a/b/c that are each 120° out of phase with each other and are separated by spiral walls 1816. Each spiral passage 1814a/b/c has gas distribution holes 1808a/b/c that are distributed therealong. It will be apparent that such arrangements may also be pursued for showerheads having even greater numbers of spiral passages, e.g., 4, 5, 6, or more spiral passages. In such cases, the angular offset between adjacent spiral paths followed by the spiral passages may be selected to be equal to 360°/N, where N is the number of spiral passages.

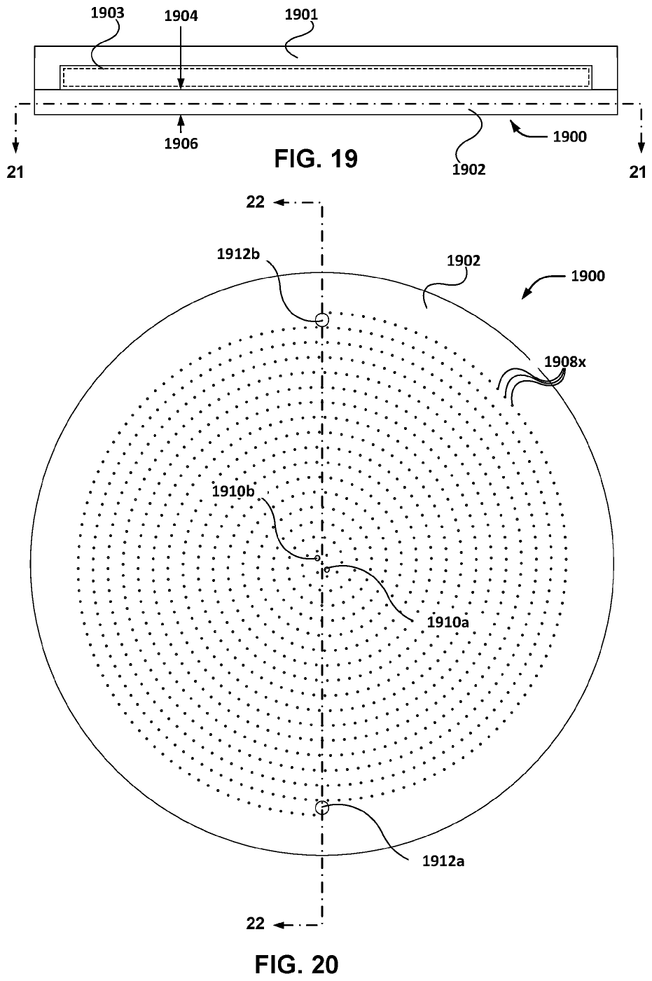

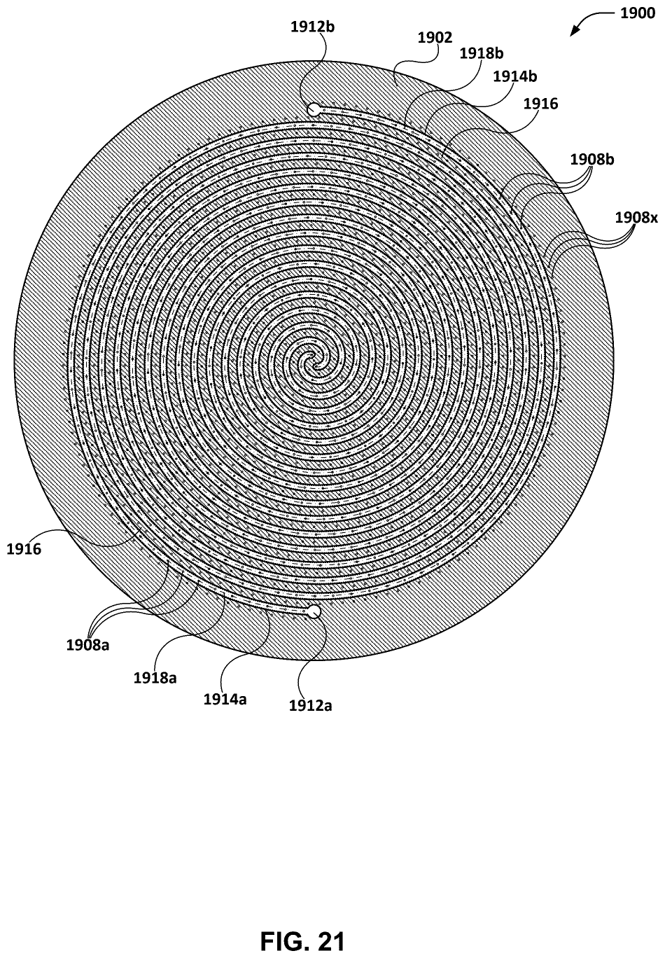

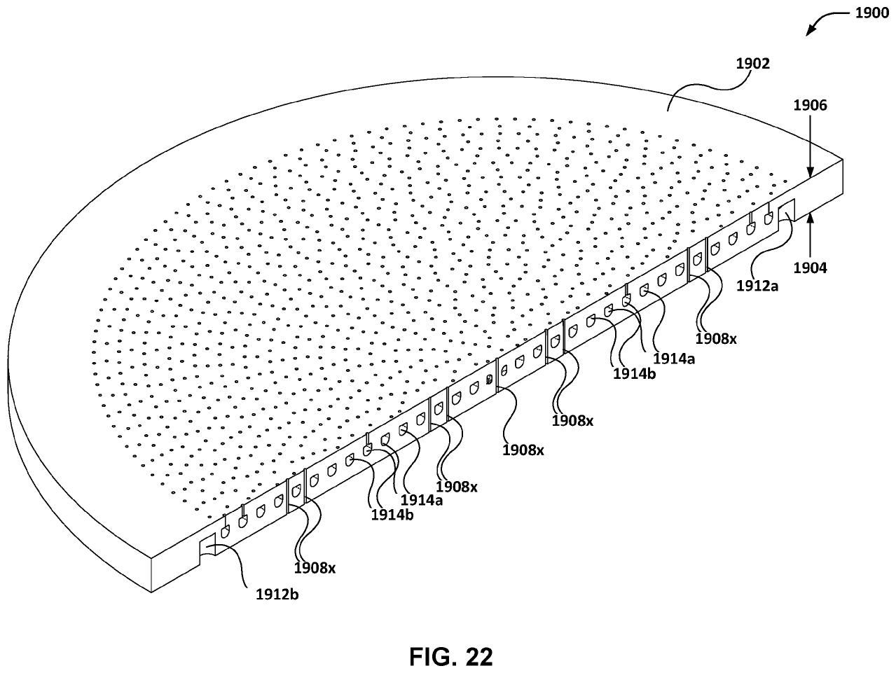

FIG. 19 is a side view of another example showerhead similar to that of FIG. 2 but having the capability of separately delivering three process gases—two via internal spiral passages and one via gas distribution holes that extend from one side of the showerhead to the other. The showerhead of FIG. 19 may, for example, be considered to be a showerhead faceplate, as discussed earlier. FIG. 20 is a top view of the example showerhead of FIG. 19. FIG. 21 is a section view of the example showerhead of FIG. 19 taken along the section line of FIG. 19. FIG. 22 is an isometric section view of the example showerhead of FIG. 19 taken along the section line in FIG. 20.

As can be seen from FIG. 20, the showerhead 1900 of FIG. 19 features a plurality of gas distribution holes 1908x that are visible on the top side (a first side 1904) of a main body 1902 of the showerhead 1900. Such a showerhead may be mated to (or have as part of) a backplate 1901 (see FIG. 19), which may, in concert with the showerhead 1900, define a plenum volume 1903 of which the showerhead 1900 forms the floor. Thus, gas or plasma that is introduced into such a plenum volume 1903 may exit the plenum volume 1903 by flowing through the showerhead 1900 from the first side 1904 to the second side 1906 thereof via the gas distribution holes 1908x. The inlet ports 1910a and 1910b that are visible in FIG. 20 may lead to spiral passages 1914a and 1914b, respectively, that are located within the main body 1902, e.g., as shown in FIG. 21. The spiral passages 1914a and 1914b are, in this example identical to the spiral passages 214a and 214b of the showerhead 200. The various features in FIGS. 19 through 22 that have callouts sharing the last two digits in common with similar features in the showerhead 200 are to be understood to be analogous to the corresponding features of FIGS. 2 through 4′, and the descriptions provided earlier with respect to those analogous features are equally applicable to those same features in FIGS. 19 through 22 unless indicated otherwise.

As noted earlier, the showerhead 1900 differs from the showerhead 200 in that it includes a third set of gas distribution holes 1908x that extend through the main body 1902 of the showerhead 1900. As can be seen in FIG. 21, the gas distribution holes 1908x are also arranged along a spiral path, much as the first gas distribution holes 1908a and the second gas distribution holes 1908b. The spiral path that the gas distribution holes 1908x are positioned along coincides with the spiral path followed by a spiral wall 1916 that separates the spiral passages 1914a and 1914b from one another. The spiral wall 1916 may, in some implementations, be as little as 0.15 mm in width. In some other implementations, the width may be on the order of 0.5 mm or greater or 1 mm or greater. For example, if the spiral wall has gas distribution holes passing through it, the wall thickness of the spiral wall (at least in the regions around the gas distribution holes if not the entire length of the spiral wall) may have a wall thickness on the order of the diameter of the gas distribution holes plus an amount such as 0.3 mm, 1 mm, 2 mm, or more. Thus, the gas distribution holes 1908x may be positioned in between the two spiral passages 1914, effectively forming a third and fourth spiral patterns of gas distribution holes 1908x in addition to the first and second spiral patterns of gas distribution holes 1908a and 1908b, respectively.

The inlet ports 1910a and 1910b that are visible near the center of the showerhead 1900 would, of course, be sealed off from the plenum volume 1903 such that gas introduced into the plenum volume 1903 would not be able to mix with the gases introduced into the spiral passages 1914a and 1914b by way of the inlet ports 1910a and 1910b, respectively—at least until after the gases have flowed through their respective gas distribution holes 1908 and exited the showerhead 1900.

The gas distribution holes passing entirely through the showerhead may be placed along a corresponding spiral path that defines the path followed by a spiral wall (or walls) that separate the spiral passages from one another within the showerhead. Thus, each such gas distribution hole passes through a portion of the showerhead that is free of any gaps, e.g., that does not overlap with any of the spiral passages when viewed along a direction perpendicular to a plane defined by the first side of the main body.

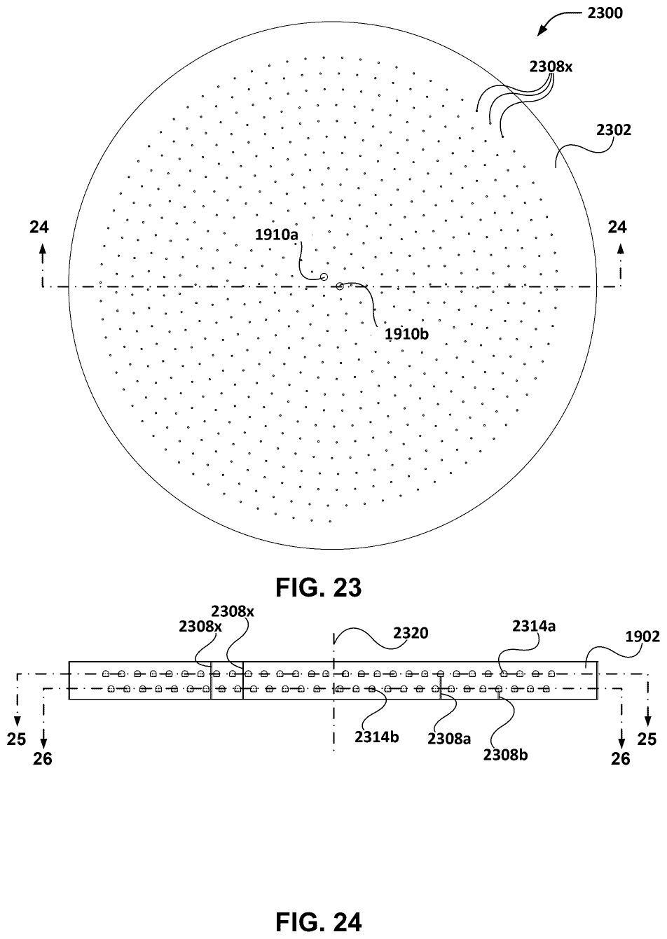

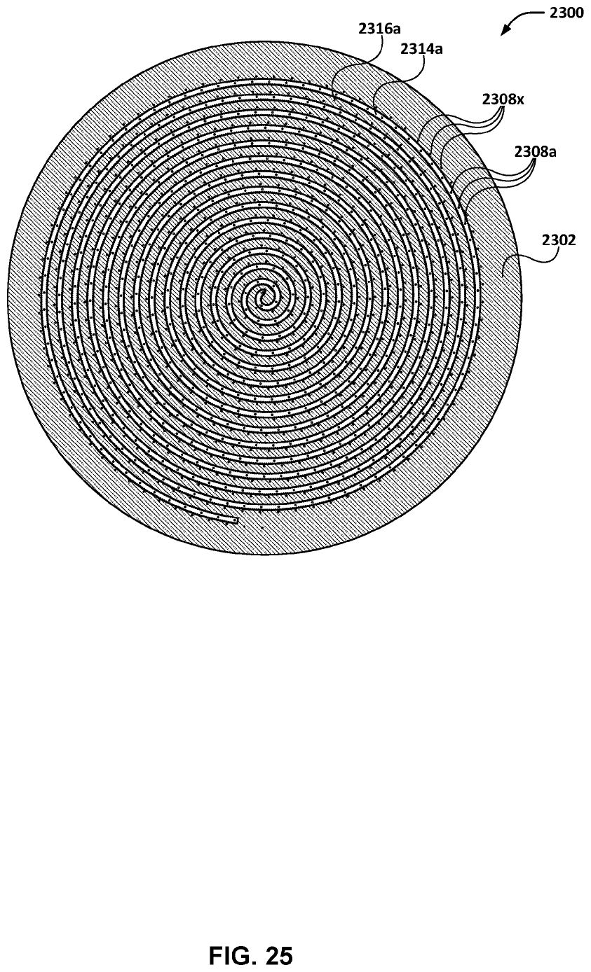

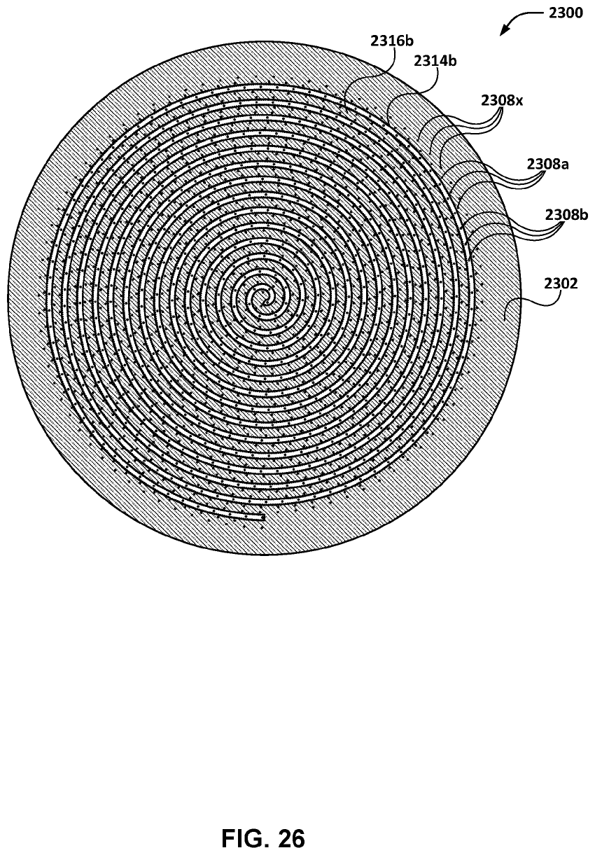

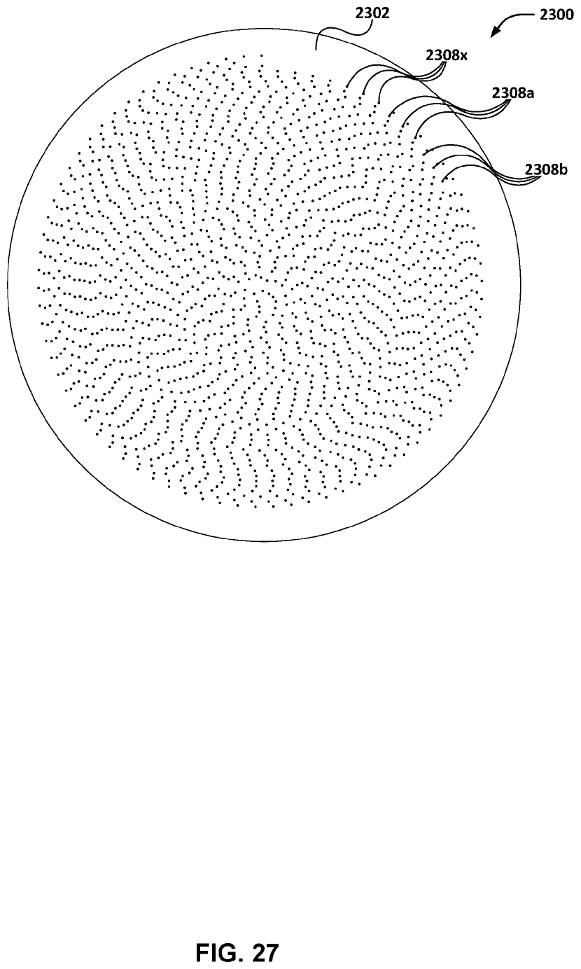

FIG. 23 is a top view of another example showerhead that is configured to separately deliver three different process gases in a manner similar to how the example showerhead of FIG. 19 delivers process gases. FIG. 24 is a side section view of the example showerhead of FIG. 23 taken along the section line of FIG. 23. FIGS. 25 and 26 are section views of the example showerhead of FIG. 23 taken along the corresponding section lines at different elevations in FIG. 24. FIG. 27 is a bottom view of the example showerhead of FIG. 23.

As can be seen in this example, particularly in FIG. 24, the showerhead 2300 includes a main body 2302 that houses within it a first spiral passage 2314a and a second spiral passage 2314b that are arranged so as to be at different elevations or distances from a first side 2304 or a second side 2306 of the main body 1902, thereby allowing the spiral passages 2314 to be clocked at generally the same angular orientation (see FIGS. 25 and 26, with one spiral passage 2314 of the spiral passages 2314a generally offset radially inward or outward of the other spiral passage 2314 of the spiral passages, e.g., such that a portion of the first spiral passage 2314a along the length of the first spiral passage 2314a that is radially inward of the centerline of the first spiral passage 2314a overlaps with a portion of the second spiral passage 2314b along the length of the second spiral passage 2314b that is radially outward of the centerline of the second spiral passage 2314b, and, optionally, such that a portion of the first spiral passage 2314a along the length of the first spiral passage 2314a that is radially outward of the centerline of the first spiral passage 2314a does not overlap with a portion of the second spiral passage 2314b along the length of the second spiral passage 2314b that is radially inward of the centerline of the second spiral passage 2314b. This allows gas distribution holes 2308a and 2308b for the spiral passages 2314a and 2314b, respectively, to extend vertically downward (or upward if the showerhead is used in backside deposition) so as to span between the second side 2306 of the main body 2302 and the corresponding spiral passage 2314a or 2314b, but without intersecting the other spiral passage 2314a or 2314b. There may also be a spiral region, when viewed along the center axes 2320 of the spiral paths followed by the spiral passages, that neither spiral passage 2314a or 2314b overlaps with-this spiral region, in effect, is a region that in which spiral walls 2316a (which may be interposed between adjacent portions of the first spiral passage 2314a) and spiral walls 2316b (which may be interposed between adjacent portions of the second spiral passage 2314b) overlap when viewed along the center axis 2320 of the spiral passages 2314a and 2314b. Similar to the gas distribution holes 1908x, a plurality of gas distribution holes 2308x that span from the first side 2304 to the second side 2306 of the main body 2302 may be distributed along/throughout this spiral region. As with the showerhead 1900, the showerhead 2300 may be connected with a backplate (not shown, but see the example of FIG. 19 for a similar arrangement) in order to form a plenum volume that is partially bounded by the first side 2304 of the showerhead 2300. Gas that is delivered to this plenum volume may then flow through the gas distribution holes 2308x and out of the second side 2306 of the showerhead 2300. Similarly, other gases may be introduced into the first spiral passage 2314a and the second spiral passage 2314b through separate inlet ports 23

It will be understood that while the depicted showerhead 2300 in this example has two internal spiral passages at two different elevations, other variants may feature additional such spiral passages at even further different elevations, allowing for the separate delivery of additional gases beyond the three gases able to be delivered by the depicted showerhead. Regardless of the number of such spiral passages, such showerheads may provide for a more radially compact spacing between gas distribution holes for radially adjacent spiral passages, allowing for a higher radial density of gas distribution holes and a correspondingly more uniform gas distribution to be achieved.

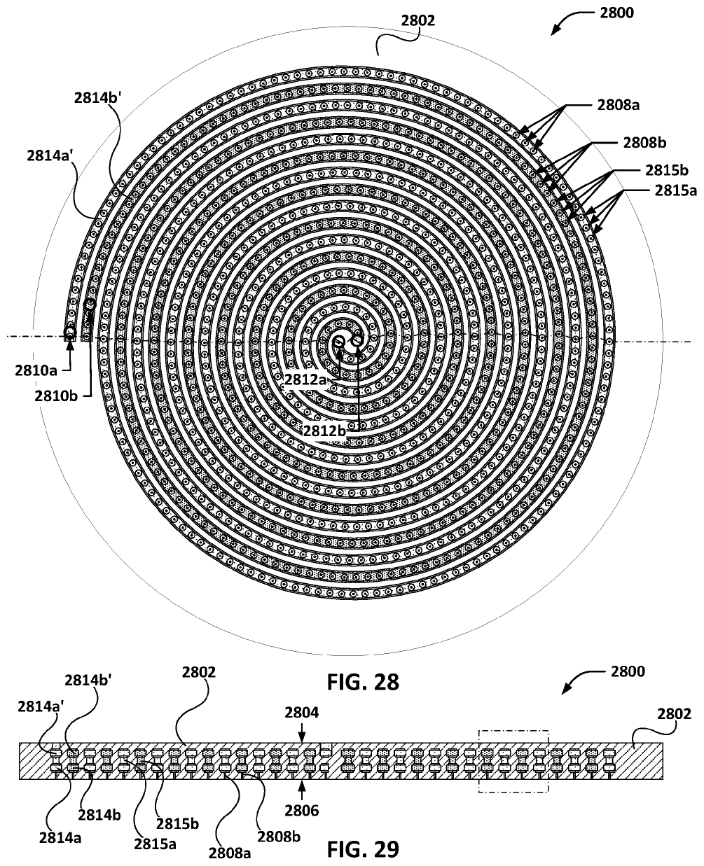

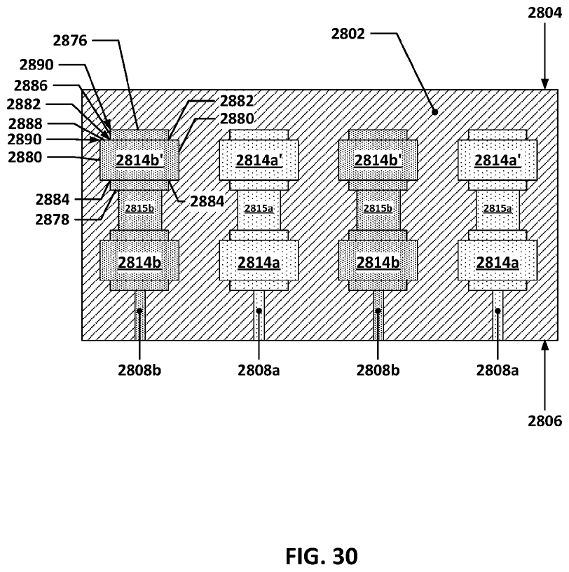

FIG. 28 is a top cutaway view of an example showerhead featuring two nested dual-level spiral passages. FIG. 29 is a section view of the example showerhead of FIG. 28 along the dash-dot-dash line in FIG. 28. FIG. 30 is a detail view of the portion of the section view of the example showerhead of FIG. 28 within the rectangular dash-dot-dash rectangle.

The implementation of FIGS. 28 through 30 is somewhat similar to the showerhead 1000 of FIG. 10. To avoid undue repetition, elements in the implementation of FIGS. 28 through 30 that are analogous to elements shown in FIG. 10 are called out with numbers that share the same last two digits as those analogous elements in FIG. 10. Thus, the discussion provided above with respect to the elements of the implementation of FIG. 10 will be understood to be equally applicable to the analogous elements in FIGS. 28 through 30 unless indicated otherwise. In the interest of conciseness, discussion of these elements that would be redundant of earlier discussion herein of similar elements is not provided, with the understanding that the earlier discussion of such elements is applicable to these similar elements in FIGS. 28 through 30.

As shown most clearly in FIG. 30, the spiral passages 2814a, 2814a′, 2814b, 2814b′ may differ from those of FIG. 10 in that one or more of the spiral passages 2814a, 2814a′, 2814b, 2814b′ (e.g., all of the spiral passages 2814a, 2814a′, 2814b, 2814b′) may have top surfaces 2876, bottom surfaces 2878, and opposing sidewalls 2880 generally extending between the top surfaces 2876 and the bottom surfaces 2878. The showerhead 2800 may be manufactured by laminating multiple machined or formed ceramic layers together, the spiral passages 2814a, 2814a′, 2814b, 2814b′ may be machined or otherwise formed in one or more of the layers, and then capped by another of the layers when the layers are bonded together.

Furthermore, as shown in FIG. 30, one or more of the spiral passages 2814a, 2814a′, 2814b, 2814b′ (e.g., each one of the spiral passages 2814a, 2814a′, 2814b, 2814b′) may further include a plurality of upper junctions 2882 configured to join a top end of each sidewall 2880 to the top surface 2876 adjacent thereto and a plurality of lower junctions 2884 configured to join a bottom end of each sidewall 2880 to the bottom surface 2878 adjacent thereto. Each junction 2882, 2884 may be an internal corner reinforcement element configured to distribute a load received from the top surface 2876, the bottom surface 2878, and/or the sidewalls 2880 across a length or surface area of that reinforcement element. The force per unit length or unit surface area of the junction 2882, 2884 may be less than a resultant force at a sharp 90-degree inner corner edge without the reinforcement element. For example, a single interior corner formed by the intersection of the top end of a sidewall 2880 and the top surface 2876 may act as a stress riser that results in a maximum stress X when a given load is transmitted from the top surface 2876 to the sidewall 2880. If such a single interior corner is replaced with two interior corners formed by a junction 2882 (or more interior corners formed by multiple junctions 2882, for example), the load may be divided across the multiple interior corners, thereby reducing the peak stress at each interior corner to, for example, ˜X/2 (or ˜X/(the number of interior corners between the two adjacent surfaces)). Thus, each junction 2882, 2884 acts to reduce the stress risers that may occur between the sidewall 2880 and the top surface 2876 and/or the bottom surface 2878 (e.g., at a sharp 90-degree inner corner edge). Such geometries may be particularly useful in showerheads that are made of a ceramic material. Such materials may be more vulnerable to fracture failure when subjected to high stress risers.

In one implementation, one or more of the junctions (e.g., each one of the junctions 2882, 2884) may include a single step having a rise surface 2886 (e.g., a vertical surface), a run surface 2888 (e.g., a horizontal surface), and two corners 2890, such that the corresponding junction 2882, 2884 distributes a load across the rise surface 2886, the run surface 2888, and the two corners 2890. In other implementations, each junction 2882 may include two or more steps (and may thus include multiple rise surfaces 2886 and run surfaces 2888). In still other implementations, one or more of the junctions 2882, 2884 may include a concave surface (e.g., a fillet), a chamfer, a notch, or other features having a predetermined length or surface area across which a load may be distributed (in contrast to an inner corner edge). Thus, for example, one or more of the interior corners 2890 of a junction 2882 and/or 2884 may be a rounded or chamfered interior corner. In laminated ceramic implementations, small-thickness, e.g., 1 mm thick, sheets of ceramic material may be machined with two-dimensional patterns and then stacked and bonded or fused together to form the main body. In some such cases, the rise and run surfaces may terminate at sharp corners, e.g., without rounded or chamfered corners.

Also visible in FIG. 28 are inlet ports 2810a and 2810b, as well as outlet ports 2812a and 2812b. It will be understood that while the inlet ports 2810a and 2810b are located at the outermost ends of the spiral passages 2814a′ and 2814b′ and the outlet ports 2812a and 2812b at the innermost ends of the spiral passages 2814a′ and 2814b′, the locations of the inlet ports 2810 and the outlet ports 2812 may also be reversed in some implementations. It will also be understood that the outlet ports 2812 may also be omitted entirely in some implementations and may, if present, be capped or plugged, as discussed earlier with respect to other implementations.

In FIGS. 28 through 30, the showerhead 2800 is a two-plenum showerhead capable of delivering two different process gases to the interior of a processing chamber simultaneously, with each process gas kept in fluidic isolation from the other within the showerhead 2800. However, such a showerhead may also be modified to deliver more than two such process gases, or to have multiple sets of separate spiral passages within the showerhead, with each set of spiral passages being configured to deliver a separate process gas.

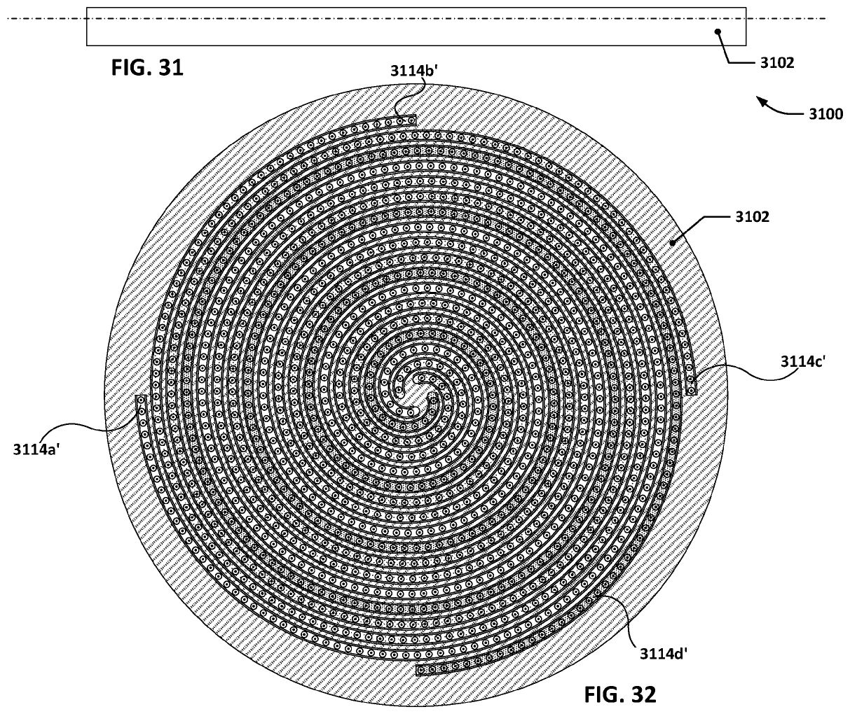

For example, FIG. 31 depicts a side view of an example showerhead featuring four nested, dual-level spiral passages. FIG. 32 depicts a top cutaway view of the example showerhead of FIG. 31 along the dash-dot-dash line in FIG. 31. As can be seen, a showerhead 3100 is shown in FIG. 31 that includes a main body 3102 that has within it a set of four spiral passages 3114a′, 3114b′, 3114c′, and 3114d′. The four spiral passages 3114a′, 3114b′, 3114c′, and 3114d′ are arranged in a circular array, with the spiral passages 3114 being nested within one another. It will be understood that each of the four spiral passages 3114a′, 3114b′, 3114c′, and 3114d′ may have a corresponding spiral passage 3114a, 3114b, 3114c, or 3114d (not shown, but replicating spiral passages 3114a′, 3114b′, 3114c′, and 3114d′) directly below it, with riser passages connecting the four spiral passages 3114a′, 3114b′, 3114c′, and 3114d′ to the four spiral passages 3114a, 3114b, 3114c, and 3114d, respectively, and with gas distribution holes leading from each of the four spiral passages 3114a, 3114b, 3114c, and 3114d to the underside of the showerhead 3100.

Such a showerhead 3100 may, for example, be used to distribute two different process gases, e.g., a first process gas via the spiral passages 3114a and 3114c and a second process gas via the spiral passages 3114b and 3114d (e.g., a separate process gas via each set of opposing spiral passages 3114). Alternatively, four separate process gases may be distributed via the four spiral passages 3114, with each separate process gas being flowed through a corresponding one of the four spiral passages 3114a, 3114b, 3114c, and 3114d. In yet another alternative, three different process gases may be flowed through the four spiral passages, with one of the three separate process gases being flowed through two of the four spiral passages. For example, a first process gas may be flowed through the first and third spiral passages (which may be diametrically opposed to one another), while a second process gas is flowed through the second spiral passage and a third process gas is flowed through the fourth spiral passage.

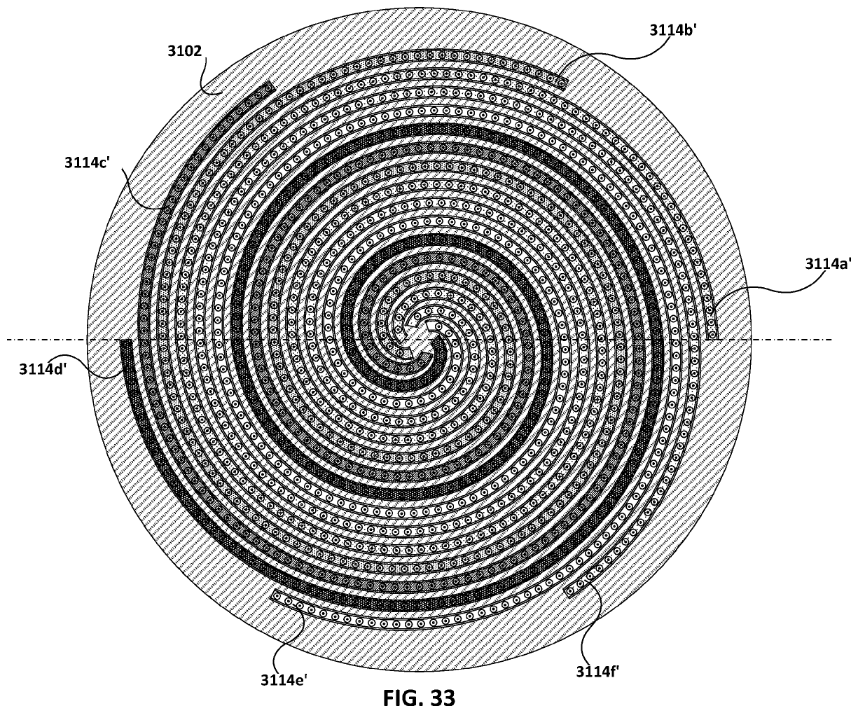

FIG. 33 depicts a top cutaway section view of another example showerhead similar to that of FIG. 31 but having six nested, dual-level spiral passages. Such a showerhead may, for example, be used to deliver up to six different process gases while keeping such process gases fluidically isolated from one another within the showerhead. However, such showerheads are more likely to be used to deliver two or three different process gases while keeping such process gases fluidically isolated from one another within the showerhead. For example, a first process gas may be flowed through spiral passages 3114a′ and 3114d′, a second process gas may be flowed through spiral passages 3114b′ and 3114e′, and a third process gas may be flowed through spiral passages 3114c′ and 3114f. In another example, a first process gas may be flowed through spiral passages 3114a′, 3114c′, and 3114e′, while a second process gas may be flowed through spiral passages 3114b′, 3114d′, and 3114f.

In the above-discussed dual-level spiral passage showerhead implementations, the upper and lower spiral passages in each showerhead have spiraled in the same directions and each pair of upper and lower spiral passages has had the same pitch, clocking, and number of revolutions. Each pair of upper and lower spiral passages in such implementations may serve as a flow path for a single corresponding process gas within the showerhead. However, other dual-level spiral passage showerhead implementations may feature a different configuration of spiral passages. For example, in some implementations, the upper spiral passages may spiral in a first direction, e.g., with a first chirality, while the lower spiral passages may spiral in a second direction, e.g., with a second chirality opposite the first chirality. In some such implementations, the number of upper spiral passages may be different from the number of lower spiral passages.

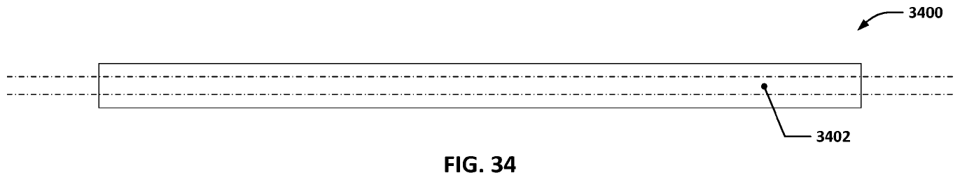

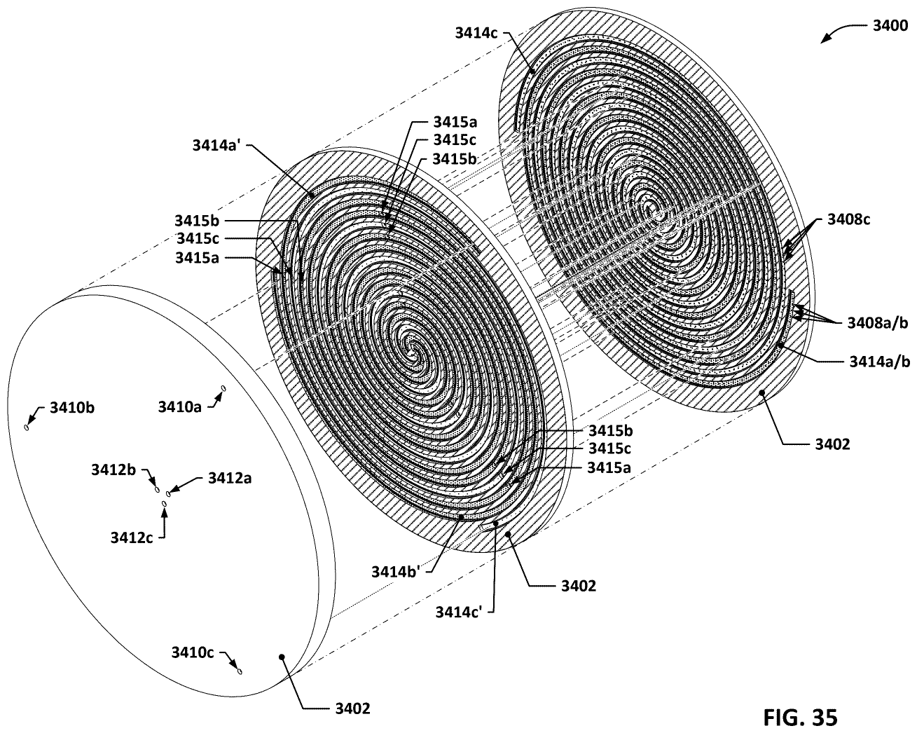

FIG. 34 depicts a side view of an example showerhead having nested dual-level, reversed spiral passages. FIG. 35 depicts an exploded view of the showerhead of FIG. 34. The showerhead 3400 may have a main body 3402, similar to earlier showerheads discussed herein, with the cuts between the exploded sections taken along the two dash-dot-dash lines shown in FIG. 34.

As can be seen, the showerhead 3400 has three upper spiral passages 3414a′, 3414b′, and 3414c′ that are each provided respective process gases via inlet ports 3410a, 3410b, or 3410c. Outlet ports 3412a, 3412b, and 3412c are also shown, but may be blocked off or plugged during process gas delivery (or may be omitted entirely, as discussed earlier with respect to other implementations). The upper spiral passages 3414a′, 3414b′, and 3414c′ spiral outward in a clockwise direction in FIG. 35.

The showerhead 3400 also has a plurality of lower spiral passages 3414a/b and 3414c that spiral in a counterclockwise direction in FIG. 35. The lower spiral passages 3414a/b and 3414c have a smaller pitch and undergo more revolutions than the upper spiral passages 3414a′, 3414b′, and 3414c′. As a result of the reversed chirality of the upper spiral passages 3414a′, 3414b′, and 3414c′ and the lower spiral passages 3414a/b and 3414c, there are a plurality of discrete points where the centerlines of the upper spiral passages 3414a′, 3414b′, and 3414c′ and the lower spiral passages 3414a/b and 3414c cross over one another. Riser passages 3415a, 3415b, and 3415c may be provided at such locations in order to fluidically connect each of the upper spiral passages 3414a′, 3414b′, and 3414c′ with one of the lower spiral passages 3414a/b and 3414c. The lower spiral passage 3414a/b may have a corresponding plurality of gas distribution holes 3408a/b distributed along its length, while the lower spiral passage 3414c may similarly have a corresponding plurality of gas distribution holes 3408c distributed along its length (e.g., in spiral hole patterns).

In the depicted implementation, there are only two lower spiral passages—the lower spiral passage 3414a/b and the lower spiral passage 3414c-while there are three upper spiral passages—the upper spiral passage 3414a′, the upper spiral passage 3414b′, and the upper spiral passage 3414c′. In this particular showerhead design, the lower spiral passage 3414a/b is provided process gases via both the upper spiral passage 3414a′ and the upper spiral passage 3414b′ (the a/b callout for the lower spiral passage 3414a/b is to indicate that the lower spiral passage 3414a/b receives process gases from both of the upper spiral passages 3414a′ and 3414b′), while the lower spiral passage 3414c is provided process gas only via the upper spiral passage 3414c′.

Such an implementation may allow for two or more process gases to be pre-mixed within one of the lower spiral passages, e.g., the lower spiral passage 3414a/b, in the showerhead 3400 before being delivered into the processing chamber and flowed onto a semiconductor wafer via the gas distribution holes, e.g., via the gas distribution holes 3408a/b, while a third process gas may be delivered to the processing chamber via the other lower spiral passage, e.g., the spiral passage 3414c and the gas distribution holes 3408c, without mixing within the showerhead 3400 prior to being introduced into the process chamber.

FIG. 36 depicts a diagram showing crossover points between nested spiral passages in a dual-level reversed spiral passage showerhead. This diagram may more clearly communicate the nature of how the upper spiral passages 3614a′, 3614b′, and 3614c′ and the lower spiral passages 3614a and 3614b may cross over one another, and how the riser passages 3615a and 3615b may be placed at the locations where the upper spiral passages 3614a′ and 3614b′ cross over the lower spiral passage 3614a/b and the upper riser passages 3615c may be placed at the locations where the upper spiral passage 3614c′ crosses over the lower spiral passage 3614c (FIG. 36 is not to scale, and is schematic in nature).

It will be understood that the dual-level, reversed direction (or reversed chirality) spiral passage showerhead discussed above with respect to FIGS. 34 and 35 may be implemented in a number of ways. For example, in some implementations, there may be equal numbers of upper and lower spiral passages, while in other implementations, such as the example discussed above, there may be different numbers of upper and lower spiral passages, e.g., 3, 4, 5, or 6 upper spiral passages and 2 or 3 lower spiral passages, or 4 upper spiral passages and 3 lower spiral passages. It will be understood that when there are different numbers of upper and lower spiral passages, at least one of the spiral passages of which there are fewer in number (as with respect to the upper spiral passages and the lower spiral passages) may be fluidically connected via corresponding riser passages with two or more of the spiral passages of which there is a greater number (as with respect to the upper spiral passages and the lower spiral passages).

The above examples have all focused on showerheads with internal spiral passages in which the “upper” surfaces of the passages are generally parabolic or arcuate in cross-sectional profile, thereby avoiding flat spots that may prove problematic during additive manufacturing of such showerheads. As mentioned earlier, another type of showerhead that may be suitable for being manufactured using additive manufacturing techniques is one in which the showerhead has a main body with a large internal plenum volume bounded on one side by a first surface and on another, opposite side, by a second surface. Such a showerhead may also include a plurality of pillars that span between the first surface and the second surface. The pillars may have an exterior side wall or side walls that transition to the first surface via a rounded transition region. A plurality of first gas distribution holes may span between a first side of the main body and a second side of the main body on an opposite side of the main body from the first side. Each of the first gas distribution holes may be located within a corresponding one of the pillars. Such a showerhead may generally be suitable for providing two separate process gases to a semiconductor wafer during semiconductor processing operations, and may be considered to be a showerhead that is also a showerhead faceplate.

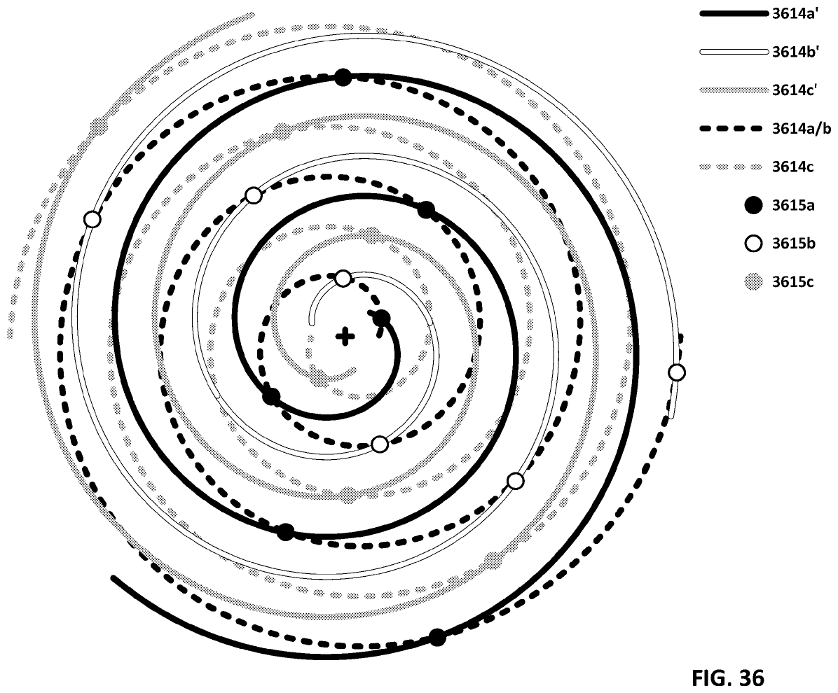

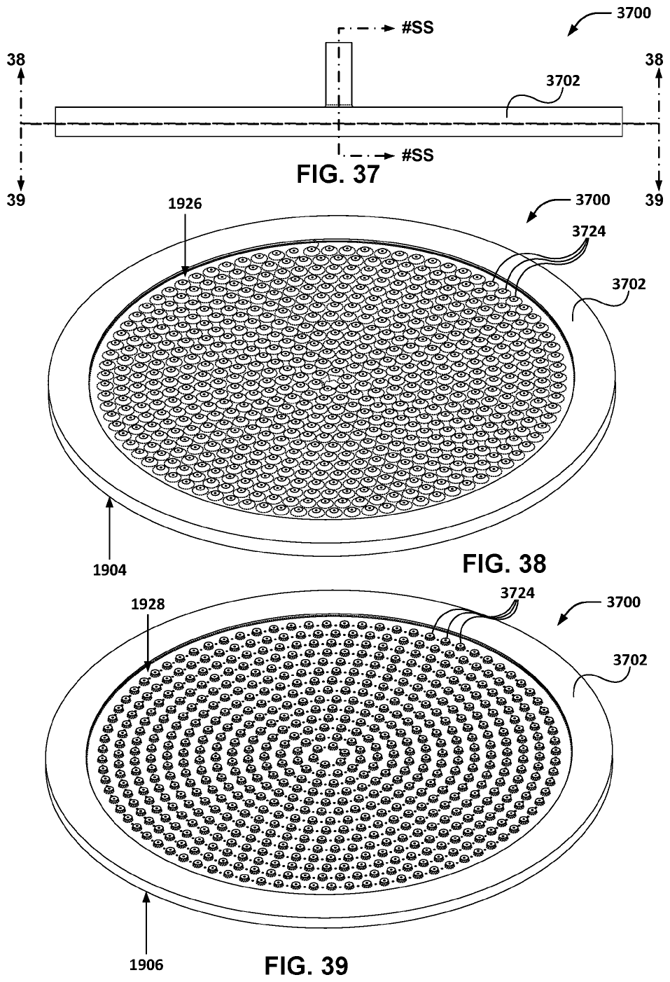

FIG. 37 is a side view of an example showerhead featuring an internal plenum volume having a plurality of pillars extending between upper and lower surfaces thereof. FIGS. 38 and 39 are isometric section views of the example showerhead of FIG. 37 taken along the corresponding section lines of FIG. 37.

As can be seen, the interior of a main body 3702 in the example showerhead 3700 of FIG. 37 is equipped with an internal plenum volume 3703 that is bounded on the top by a first surface 3726 and on the bottom by a second surface 3728. A large number of pillars 3724 that span between the first and second surfaces 3726 and 3728, respectively, of the internal plenum volume 3703 are distributed throughout the internal plenum volume 3703 in a relatively tightly packed manner.

A plurality of first gas distribution holes 3708a may fluidically connect the first side 3704 of the main body 3702 with the second side 3706 of the main body 3702 by passing through the main body 3702; each such first gas distribution hole 3708a may pass through a corresponding one of the pillars 3724, thereby allowing the first gas distribution holes 3708a to travel through the main body 3702 without coming into fluidic contact with the internal plenum volume 3703. A plurality of second gas distribution holes 3708b may extend from the second surface 3728 to the second side 3706, thereby fluidically connecting the internal plenum volume 3703 with the ambient environment adjacent to the second side 3706.

Each pillar 3724 may have an exterior surface or surfaces 3730 that span between the first and second surfaces of the internal plenum volume; the exterior surface or surfaces may transition to the first or second surfaces of the internal plenum volume via a corresponding rounded transition region. As with the rounded transition regions of the spiral-passage showerheads discussed above, the curvature of the rounded transition regions closer to the side of the main body on which the gas distribution holes are located that fluidically connect to the internal plenum volume may be smaller than the curvature of the rounded transition regions closer to the other side of the main body.

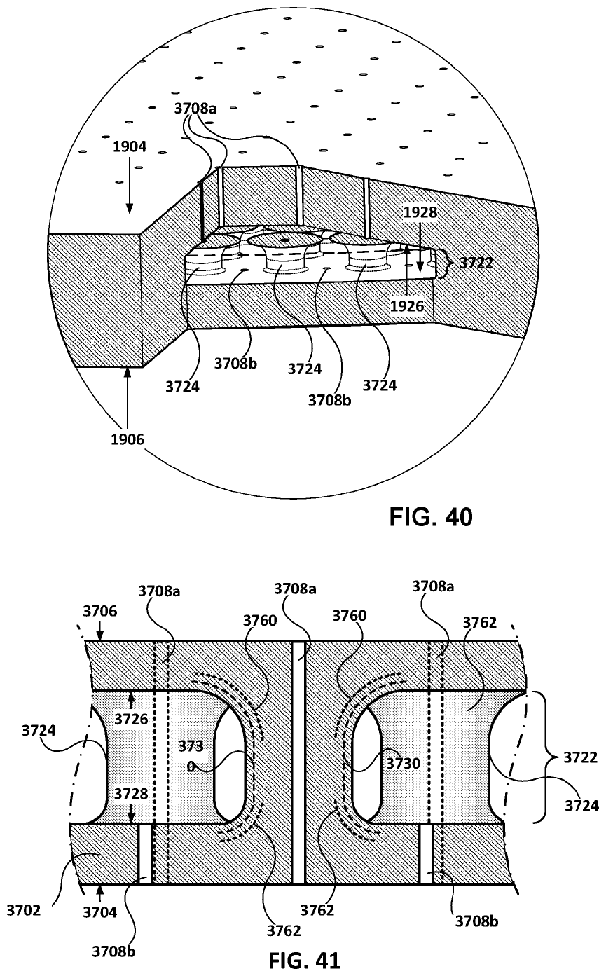

FIG. 40 depicts a partial cutaway view of a portion of the showerhead 3700 in which several pillars 3724 are visible. FIG. 41 depicts a side section view of a representative pillar 3724 highlighting various features thereof.

As can be seen, each pillar 3724 extends between first and second surfaces 3726 and 3728, respectively, that bound an interior plenum volume 3722 of the main body 3702 of the showerhead 3700. Each pillar 3724 has one or more exterior surfaces 3730; in the depicted example, each pillar 3724 is axially symmetric and thus has a single exterior surface 3730 that has circular cross-sections in planes perpendicular to the center axes of the first gas distribution holes 3708a that extend therethrough. However, in other implementations, the pillars 3724 may have non-axially symmetric exterior surfaces, e.g., surfaces that define cross-sectional shapes in planes perpendicular to the center axes of the first gas distribution holes that have radial symmetry (such as exterior surfaces that define a regular polygon such as a triangle, square, pentagon, hexagon, heptagon, octagon, nonagon, decagon, etc.) or that may even be other shapes, e.g., trapezoidal shapes).

As can be seen in the representative pillar 3724 of FIG. 41, the exterior surfaces 3730 of the pillars 4124 may have a first rounded transition region 3760 and a second rounded transition region 3762. While the second rounded transition region 3762 is shown as being smaller in size compared to the first rounded transition region 3760. In other implementations, however, the second rounded transition region 3762 may be larger than as shown in FIG. 41, potentially even being the same size as the first rounded transition region 3760. For example, even if a) the second rounded transition region 3762 is the same size as the first rounded transition region 3760 and b) the first rounded transition regions of two or more neighboring pillars 3724 meet each other, there may still be a location on the second surface 3728 in between the pillars 3724, e.g., a generally triangular region in the case of three pillars 3724 that are positioned such that the first rounded transition region 3760 of each such pillar 3724 meets with the first rounded transition regions 3760 of the other two pillars 3724, where the second surface 3728 is still flat. If the second gas distribution holes 3708b are positioned so as to be located within these regions (and the hole placement tolerance is sufficiently precise), then there may be little risk of such second gas distribution holes 3708b being located in locations where they may intersect with the second rounded transition regions 3762 and thus experience variance in their lengths.

In some implementations, the pillars 3724 may be spaced close enough together that the first rounded transition region 3760 of each pillar meets with the first rounded transition region 3760 of one or more other pillars. In some instances, the pillars 3724 may be arranged in a triangular lattice pattern, e.g., with each pillar 3724 (aside from the pillars 3724 at the edges or center of the pattern) being surrounded by six other pillars 3724 positioned in a circle around that pillar 3724 such that the six pillars 3724 surrounding that pillar 3724 are all equidistantly spaced from that pillar 3724 and such that each of the six pillars 3724 surrounding that pillar 3724 is equidistantly spaced from the neighboring pillars of six pillars 3724 by the same amount. In some implementations, the pillars 1424 may be arranged in a square lattice pattern subject to similar spacing constraints as are discussed below.

In some implementations, the first surface 3726 and the second surface 3728 may be spaced apart from one another by a first amount that is less than or equal to 120% of a radius of the first rounded transition regions. In some additional or alternative such implementations, each pillar may have a centerline that is within 240%, e.g., within 200% to 240%, of a radius of the first rounded transition regions 3760 of the centerlines of any immediately neighboring pillars 3724 of that pillar 3724. The pillars 3724 may, in some cases, generally be distributed across a circular region that is the diameter of a semiconductor wafer, e.g., 300 mm, or larger. In some implementations, regions on the “ceiling” of the internal plenum volumes between adjacent rounded transition regions that are flat and horizontal may be present but may have a maximum dimension of 10 mm or less.

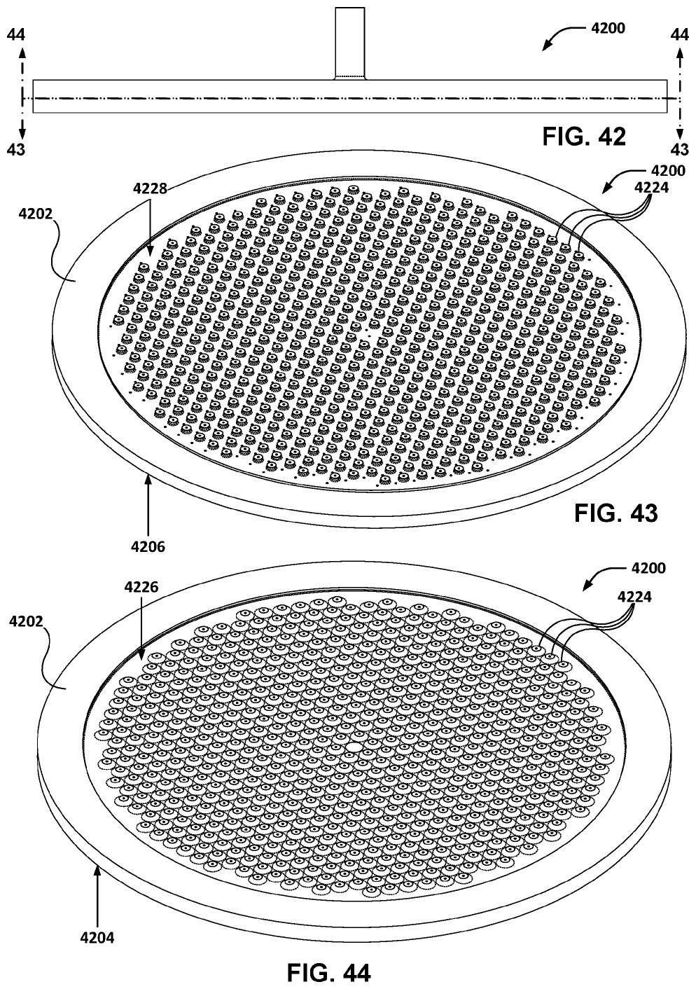

In the showerhead 3700, the first gas distribution holes 3708a are arranged in multiple concentric circular arrays. The second gas distribution holes 3708b are arranged in identical circular arrays (having the same circumferential spacing and same radii) such that each second gas distribution hole 3708b is circumferentially interposed between two circumferentially adjacent first gas distribution holes 3708a, and such that each first gas distribution hole 3708a is circumferentially interposed between two circumferentially adjacent second gas distribution holes 3708b. However, other implementations of similar showerheads may feature other arrangements of gas distribution holes, as shown in FIGS. 42 through 45.

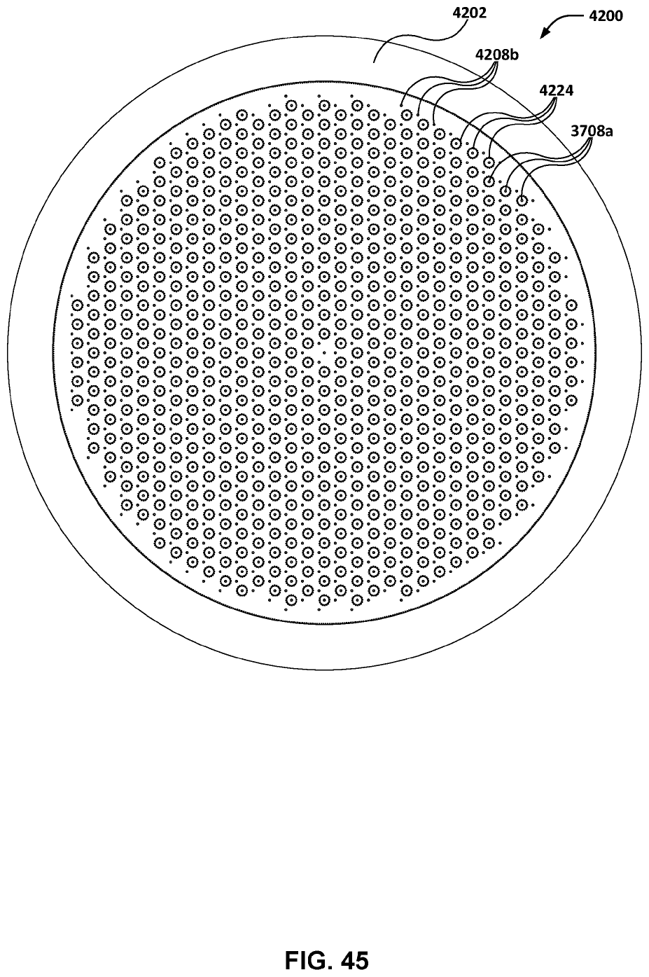

FIG. 42 is a side view of another example showerhead featuring an internal plenum volume having a plurality of pillars extending between upper and lower surfaces thereof. FIGS. 43 and 44 are isometric section views of the example showerhead of FIG. 42 taken along the corresponding section lines of FIG. 42. FIG. 45 is an isometric section view of the example showerhead of FIG. 42 taken along the corresponding section line of FIG. 42.

The example showerhead 4200 of FIGS. 42 through 45 is identical to that of the showerhead 3700 of FIG. 37 except that the pillars 4224 are arranged in a triangular lattice pattern, with a first rounded transition region 4260 of each pillar 4224 meeting with the first rounded transition region 4260 of three or more adjacent pillars 4224. Another difference is that second gas distribution holes 4208b are generally located at locations that are equidistantly spaced by a first distance from the center axis of three adjacent first gas distribution holes 4208a (or, for those second gas distribution holes 4208b not adjacent to three first gas distribution holes 208a, spaced by the same first distance from the center or centers of whatever first gas distribution holes 4208a are adjacent thereto).

In some implementations, additively manufactured showerheads with pillar structures in them may be configured to provide more than two different gases. For example, some showerheads with pillar structures may be configured to provide three different gases. Two different examples of such showerheads are discussed below, although it will be apparent that the principles underlying them may be applied to also provide showerheads capable of providing more than three different gases, e.g., by adding additional internal plenum volumes and pillars.

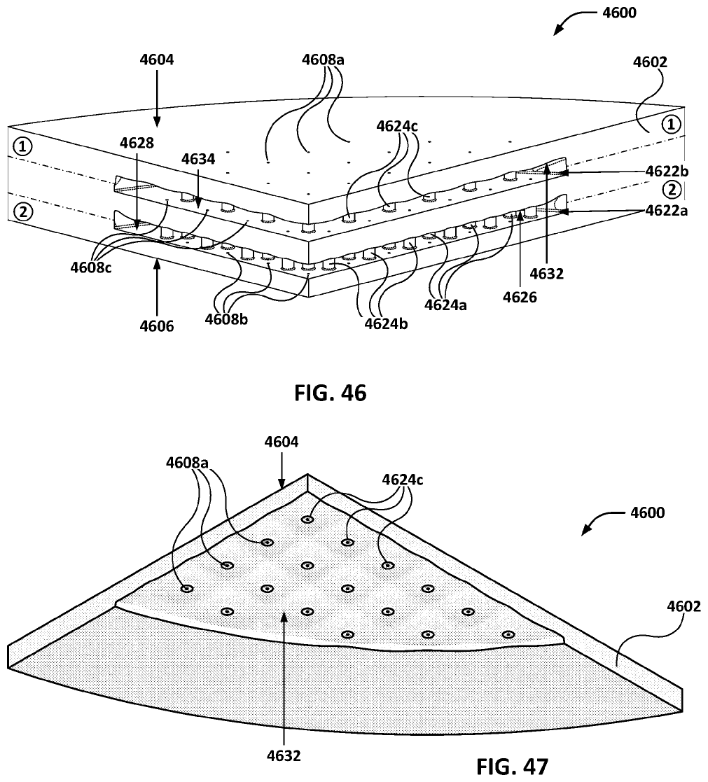

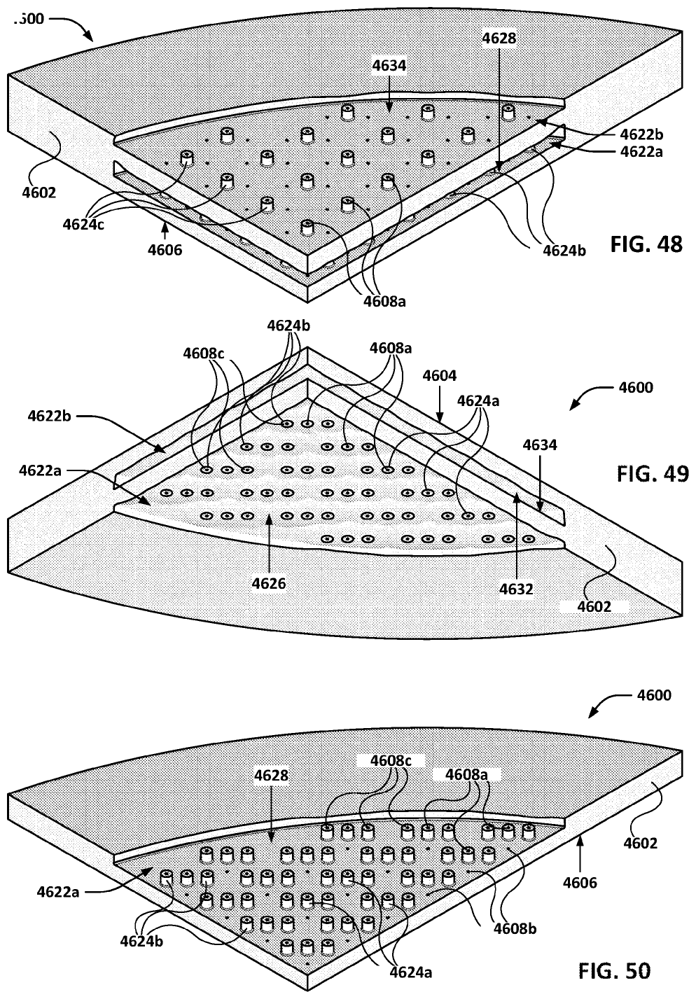

FIG. 46 depicts a perspective view of a removed portion of such a showerhead. FIGS. 47 through 50 depict cutaway perspective views of the removed portion of FIG. 46. FIG. 47, for example, shows the removed portion of the showerhead with the material below the dot-dash-dot line \textcircled{1} removed, while FIG. 48 shows the removed portion of the showerhead with the material above the dot-dash-dot line \textcircled{1} removed. Similarly, FIG. 49, for example, shows the removed portion of the showerhead with the material below the dot-dash-dot line \textcircled{2} removed, and FIG. 50, for example, shows the removed portion of the showerhead with the material above the dot-dash-dot line \textcircled{2} removed.

As can be seen in FIG. 46, the showerhead 4600 has a main body 4602 that has located within it a first internal plenum volume 4622a and a second internal plenum volume 4622b. The main body 4602 has a first side 4604 and a second side 4606 opposite the first side 4604. The first internal plenum volume 4622a may be bounded on the top by a first surface 4626 and on the bottom by a second surface 4628. Similarly, the second internal plenum volume 4622b may be bounded on the top by a third surface 4632 and on the bottom by a fourth surface 4634.

The showerhead 4600 may have within it a plurality of pillars 4624 that are each located within one of the internal plenum volumes 4622. For example, the first internal plenum volume 4622a may have first pillars 4624a and second pillars 4624b within it, while the second internal plenum volume 4622b may have third pillars 4624c within it. The third pillars 4624c may each generally correspond in location with one of the first pillars 4624a such that first gas distribution holes 4608a that each pass through one of the first pillars 4624a also pass through a corresponding one of the third pillars 4624c. Thus, the first gas distribution holes 4608a may span between the first side 4604 and the second side 4606 of the main body 4602, with each such first gas distribution hole 4608a passing through both a corresponding first pillar 4624a and a corresponding third pillar 4624c to fluidically isolate that first gas distribution hole 4608a from the first internal plenum volume 4622a and the second internal plenum volume 4622b.

The showerhead 4600 may also include second gas distribution holes 4608b that each span between the second surface 4628 and the second side 4606 and third gas distribution holes 4608c that each span between the fourth surface 4634 and the second side 4606. The third gas distribution holes 4608c may each pass through a corresponding one of the second pillars 4624b, which may act to fluidically isolate the corresponding third gas distribution hole or port 4608c from the first internal plenum volume 4622a.

Such an arrangement allows a first gas that is flowed into an external plenum volume (not shown, but see example of FIG. 19) to be distributed from the second side 4606 of the showerhead 4600 via the first gas distribution holes 4608a, a second gas that is flowed into the first internal plenum volume 4622a to be distributed from the second side 4606 of the showerhead 4600 via the second gas distribution holes 4608b, and a third gas that is flowed into the second internal plenum volume 4622b to be distributed from the second side 4606 of the showerhead 4600 via the third gas distribution holes 4608c. Each such gas flow may be kept fluidically isolated from the other gas flows within the showerhead 4600 and may only potentially mix once such gases have exited the showerhead 4600.

As can be seen in FIGS. 47 and 49, the first surface 4626 and the third surface 4632, which form the “ceilings” of the first internal plenum volume 4622a and the second internal plenum volume 4622b, may be non-planar surfaces, exhibiting a somewhat subtle contouring. The first pillars 4624a and the second pillars 4624b may each span between the first surface 4626 and the second surface 4628, while the third pillars 4624c may each span between the third surface 4632 and the fourth surface 4634.

As can be seen in FIGS. 47 and 48, the third pillars 4624c (and the corresponding first pillars 4624a) and the third gas distribution holes 4608c may be arranged in corresponding square grid patterns, with the square grid pattern for the third gas distribution holes 4608c being oriented at a 45° angle relative to the square grid pattern for the third pillars 4624c. Similarly, and as can be seen in FIG. 50, the second pillars 4624b and the corresponding third gas distribution holes 4608c may also be arranged in a square grid pattern that is the same size as, and oriented in the same direction as, the square grid pattern for the third gas distribution holes 4608c (although offset laterally from that other square grid pattern).

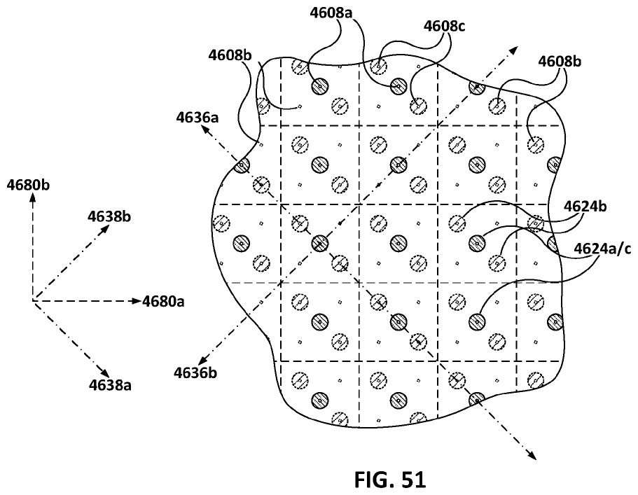

FIG. 51 is a plan view of a portion of the showerhead 4600 with the first side 4604 removed and the interior of the second internal plenum volume 4622b visible. The third pillars 4624c and first gas distribution holes 4608a are also visible within the exposed portion of the second internal plenum volume 4622b. Also shown are the second pillars 4624b, the second gas distribution holes 4608b, and the third gas distribution holes 4608c, although these are shown with dotted outlines since they are located in the first internal plenum volume 4622a and would thus normally not be visible in this view. The first pillars 4624a are not visible here, but are each located directly beneath one of the third pillars 4624c. As can be seen, each first pillar 4624a in the depicted portion of the showerhead 4600 is located at the center of a unit cell of a square array (the square grid of dashed lines representing the square array), with two second pillars 4624b being positioned within that unit cell on opposite sides of the first pillar 4624a and along a first axis 4636a that is parallel to a first direction 4638a, e.g., such that the first pillar 4624a is interposed between the two second pillars 4624b. Each unit cell in the depicted portion of the showerhead 4600 also includes two second gas distribution holes 4608a that are positioned on opposite sides of the first pillar 4624a of that unit cell and along a second axis 4636b that is parallel to a second direction 4638b. The first direction 4638a and the second direction 4638b may, in some implementations, be perpendicular to one another, although in other implementations, the angle between the first direction 4638a and the second direction 4638b may be an oblique angle. Generally speaking, the second direction 4638b may be transverse to the first direction 4638a (or vice-versa). It will also be noted that the array axes 4680a and 4680b of the square array may be at 45° angles with respect to the first direction 4638a and/or the second direction 4638b.

It will be observed from FIG. 51 that in some implementations the second pillars 4624b within each unit cell of the square array are the two closest pillars 4624 in the first internal plenum volume 4622a to the first pillar 4624a in that unit cell. Similarly, the second gas distribution holes 4608b within each unit cell of the square array are, in some implementations, the two closest second gas distribution holes in the first internal plenum volume 4622a to the first pillar 4624a. In some implementations, the centers or center axes of the second pillars 4624b and the second gas distribution holes 4608b in each unit cell of the square array may be equidistantly spaced from a center or center axis of the first pillar 4624a of that unit cell.

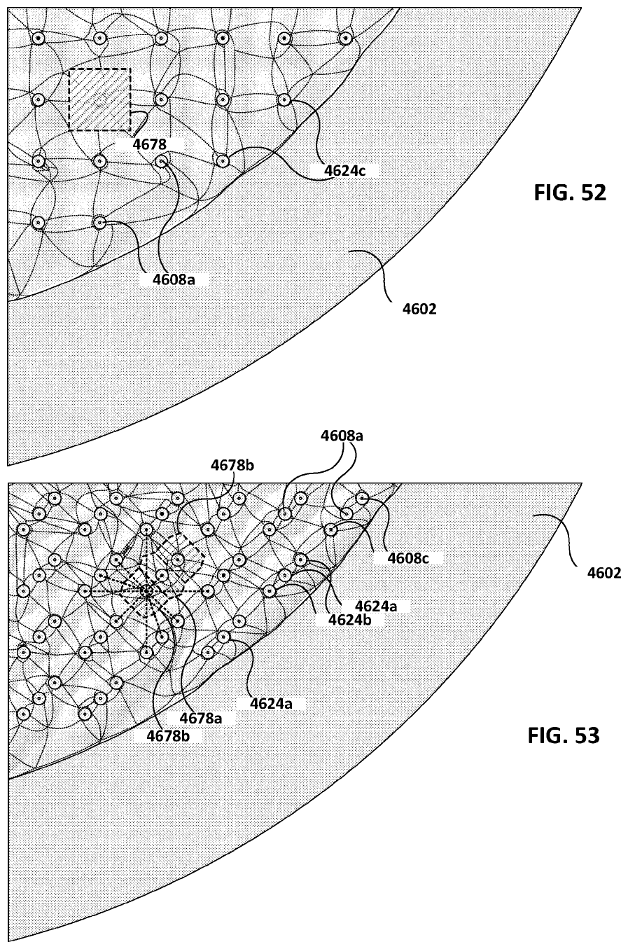

The showerhead 4600 that is illustrated in FIGS. 46 through 50 has, as mentioned earlier, a contoured first surface 4626 and a contoured third surface 4632. Portions of the third surface 4632 and the first surface 4626 are shown in plan view in FIGS. 52 and 53, respectively.

The contouring that is used on the first surface 4626 and the third surface 4632 may be optimized to facilitate modeling, manufacturing, and performance. For example, showerheads such as the depicted showerhead 4600 may feature a very large number of pillars 4624 that may connect with the upper surface bounding the internal plenum volume 4622 that such pillars 4624 are located within. If the interfaces between the pillars 4624 and such an upper surface are rounded to the point where there is little or no part of the upper surface that is flat and horizontal, the resulting shape may prove to be too complex to model in a conventional solid modeling program (or may, even if able to be modeled, be so computationally intensive that interacting with the model may consume undesirably large periods of time. However, if a voxel-based modeling program, e.g., such as nTopology, Inc.'s self-titled software (“nTopology”), is used, then the contouring where each pillar 4624 joins with the upper surface of the internal plenum volume 4622 in which it is located may be defined according to a scalar function that may be determined in a fraction of the time (and more reliably) than may be needed to determine similar contouring in a traditional solid modeling program. At the same time, the resulting surface contour avoids the presence of generally flat, horizontal overhanging surfaces in the component (thereby avoiding issues encountered in additive manufacturing with such geometries) and results in a generally smooth surface that is less likely to be subject to erosion and particulate generation during use.

For example, in nTopology, it is possible to apply a scalar field feature to a component model in which a particular model value is determined according to a scalar function relative to each point or feature in an array of points or features. That scalar function may be applied to all of the points or features in the same way, but the model value that is determined using the scalar function in association with a particular point or feature may only be determined within a contour region associated with that point or feature. Such a contour region may, for example, generally be bounded by boundary edges or planes that are perpendicular to, and that bisect, reference lines that extend from the center of that point or feature to the centers of pillars that are adjacent to that pillar. Generally speaking, only the potential boundary edges that are closest to the pillar of interest define the boundary of the contour region. Thus, the contour region may generally take the form of a polygon in which each side is equidistant from the particular pillar of interest and a pillar adjacent thereto. Each contour region generally fences in a corresponding portion of the first surface 4626 or the third surface 4632, with the portion of the relevant surface that is fenced in has a profile that is determined by applying the scalar function relative to the pillar that is within that contour region.

In FIG. 52, a single contour region 4678 is shown that has the shape of a square-it will be readily apparent that each side of the square contour region 4678 is equidistantly spaced between the third pillar 4624c in that contour region 4678 and the four closest surrounding third pillars 4624c. In FIG. 53, three contour regions 4678a and 4678b are shown (there are two contour regions 4678b that are mirror images of each other). Here, one can see that the contour regions 4678a and 4678b are more complicated than the contour region 4678, e.g., having uneven hexagonal shapes. In either case, it can be observed that the boundaries between contour regions 4678 and contour regions 4678a/b generally correspond with valleys in the contouring of the third surface 4632 and the first surface 4626, respectively. The boundaries of the contour regions 4678 and contour regions 4678a/b may generally define the limit of how far away from each pillar the scalar function is applied. Put another way, the scalar function would, with respect to each pillar, only be used to determine model values for points that lie within the contour region for that pillar. Model values for points located outside of that contour region would be determined by applying the scalar function to other pillars. The boundary between two contour regions would generally be equidistant from both pillars that lie within those contour regions, and so the model values determined using the scalar function in either contour region will generally match at the boundary since the input (distance from the pillar center axis) would be the same for both pillars at that boundary location.

In the case of a showerhead, the model value that is determined according to the scalar function may be a first distance between the upper surface of the internal plenum volume 4622 and a reference plane, e.g., a reference plane that is defined by the second side 4606. A scalar function may be defined that determines the value of the first dimension as a function of distance from the center axis of any given pillar in the population of pillars. For example, the scalar function may be configured to increase the first distance as a function of increasing second distance from the given pillar in a direction perpendicular to the center axis of that pillar (or in a horizontal direction). For example, the scalar function may be set to vary the first distance between X and Y millimeters, with the scalar function having a value of X at the center of the given pillar and a value of Y at the outermost edge or point of the contour region from the center of the given pillar. In some implementations, the scalar function may be defined to vary the first distance between X and Y such that the radial profile defined by the scalar function relative to the center axis of the given pillar is smooth (without sharp corners) and tangent to horizontal reference axes or lines at both the center axis (or a location within the given pillar) and at a value of the second distance equal to the largest value that the second distance can have for any of the pillars to which the scalar field is being applied before exiting the contour region for the relevant pillar. Put another way, the contour developed for any given pillar using the scalar function may curve upward as it travels away from the given pillar and may curve downward as it approaches the outer edge of the contour region for the given pillar. In some implementations, the scalar function may be axially symmetric about the center axis of the given pillar, e.g., producing the same value for the first distance at a given value of the second distance for a given pillar regardless of the bearing along which the point being defined lies.

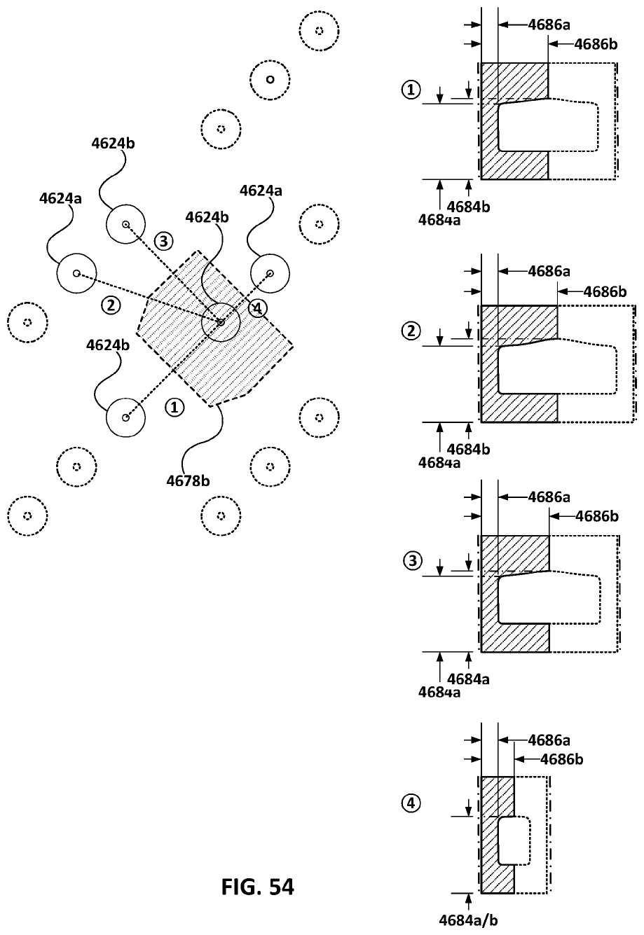

FIG. 54 helps illustrate this. In FIG. 54, an assortment of first pillars 4624a and second pillars 4624b are shown, as well as one of the contour regions 4678b. There are four cross-sectional profiles shown at right in FIG. 54, with each cross-sectional profile corresponding to the cross-section taken along one of the dotted lines with the corresponding circled number callout next to it that extend from the second pillar 4624b located within the contour region 4678b to one of the four solid-line first or second pillars 4624 surrounding that second pillar 4624b. The solid portion of each cross-section corresponds to the portion of the cross-section that lies within the contour region 4678b, and the dotted portion of each cross-section corresponds to the portion of the cross-section that lies outside of the contour region 4678b. The cross-sections, it will be understood, are simplified and do not include features relating to the second internal plenum volume.

Also visible in the cross-sections of FIG. 54 are first distances 4684 and second distances 4686. The first distances 4684 are measured from the second side of the showerhead to the cross-sectional profile defined by the scalar function. In each case, the first and second distances 4684 and 4686 are shown as two pairs of first and second distances 4684a and 4684b and 4686a and 4686b. The first and second distance 4684a and 4686a define the inner end of the cross-sectional profile, while the first and second distance 4684b and 4686b define the outer end of the cross-sectional profile. As may be apparent from FIG. 54, each of the cross-sectional profiles has, to the degree they overlap, the same contour as the other cross-sectional profiles.

In some implementations, the values of X and Y may be chosen such that the difference between X and Y is within 20% to 30% of the maximum distance between a center axis of any pillar to which the scalar function is being applied and the outermost edge or point of the contour region for that pillar. Surfaces defined according to such scalar functions may generally be suitable for being additively manufactured, e.g., using LBPF, while avoiding sharp internal edges and minimizing or reducing the increase in volume within each of the internal plenum volumes, thereby reducing the amount of dead space within each such plenum volume that may need to be evacuated.

It will be understood, of course, that there may be small deviations in the first distance near the boundaries of the contour regions and where the pillars that are within the contour regions meet the contoured surface. For example, there may be small fillets or rounds that are applied to any discontinuities, e.g., sharp edges, to smooth out the interior of the associated internal plenum volume and reduce the potential for particulates being generated or collecting within the showerhead. Thus, for example, the last 10% on either end of the contour described by the scalar function may not necessarily adhere to the first distances determined using the scalar function.

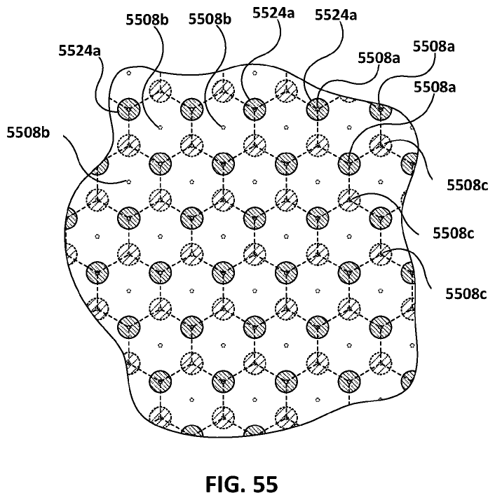

The contouring practice noted above may be applied to any of the pillar-based showerhead designs discussed herein, including those discussed above as well as the further example described below with respect to FIGS. 55 through 58.

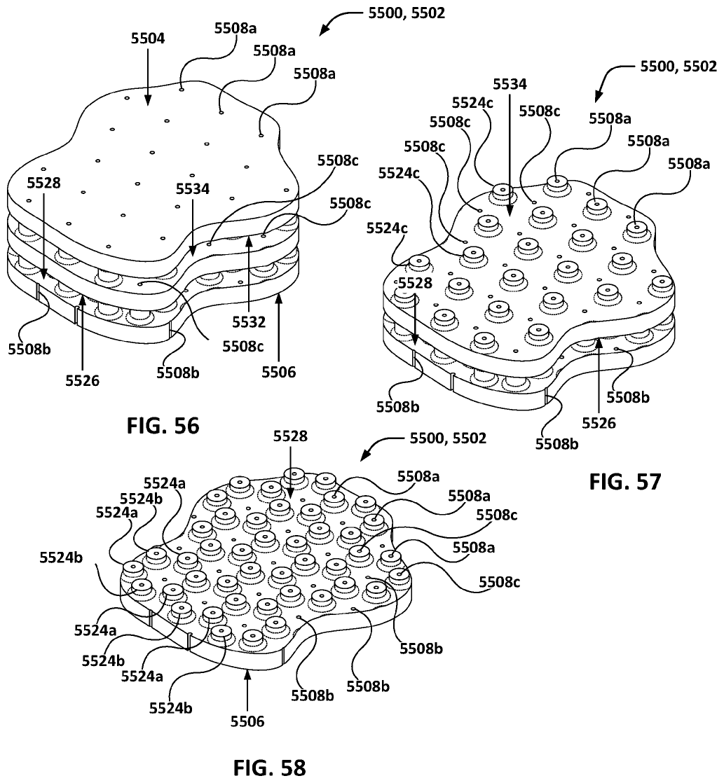

FIG. 55 is similar to FIG. 51, but showing a portion of an example showerhead 5500 in which pillars 5524 are arranged in a hexagonal lattice pattern as opposed to a square pattern. FIGS. 56 through 58 depict perspective views of a portion of the showerhead 5500, with FIGS. 57 and 58 being partial cutaway views showing the interior of each internal plenum volume.

As shown in FIG. 56, the showerhead 5500 may include a main body 5502 that has within it a first internal plenum volume 5522a and a second internal plenum volume 5522b that are both located between a first side 5504 and a second side 5506 of the main body 5502. The first internal plenum volume 5522a may be bounded by a first surface 5526 and a second surface 5528, while the second internal plenum volume 5522b may be bounded by a third surface 5532 and a fourth surface 5534.

As with the example showerhead 4600, the showerhead 5500 may also have within it a plurality of pillars 5524 that are each located within one of the internal plenum volumes 5522. For example, the first internal plenum volume 5522a may have first pillars 5524a and second pillars 5524b within it, while the second internal plenum volume 5522b may have third pillars 5524c within it. The third pillars 5524c may each generally correspond in location with one of the first pillars 5524a such that first gas distribution holes 5508a that each pass through one of the first pillars 5524a also pass through a corresponding one of the third pillars 5524c. Thus, the first gas distribution holes 5508a may span between the first side 5504 and the second side 5506 of the main body 5502, with each such first gas distribution hole 5508a passing through both a corresponding first pillar 5524a and a corresponding third pillar 5524c to fluidically isolate that first gas distribution hole 5508a from the first internal plenum volume 5522a and the second internal plenum volume 5522b.

The showerhead 5500 may also include second gas distribution holes 5508b that each span between the second surface 5528 and the second side 5506 and third gas distribution holes 5508c that each span between the fourth surface 5534 and the second side 5506. The third gas distribution holes 5508c may each pass through a corresponding one of the second pillars 5524b, which may act to fluidically isolate the corresponding third gas distribution hole or port 5508c from the first internal plenum volume 5522a.

As can be seen in FIGS. 55 through 58, the showerhead 5500 differs from the showerhead 4600 in that the first pillars 5524a and the second pillars 5524b are arranged in two staggered, triangular lattice patterns having opposite directionality such that adjacent triplets of first pillars 5524a and second pillars 5524b form a hexagonal pattern of pillars 5524 centered on a corresponding one of the second gas distribution holes 5508b. The third pillars 5524c, meanwhile, may form a triangular lattice pattern that is the same size and orientation as, and aligned with, the triangular lattice pattern of the first pillars 5524a.

In some implementations, the three pillars 5524 that are closest to each first pillar 5524a are all second pillars 5524b, equidistantly spaced from the center axis of that first pillar 5524a, and equidistantly spaced from one another. In some cases, the three second gas distribution holes 55 that are closest to each first pillar 5524a may also be equidistantly spaced from the center axis of that first pillar 5524a, equidistantly spaced from one another, and equidistantly spaced from the three second pillars 5524b that are closest to that first pillar 5524a.

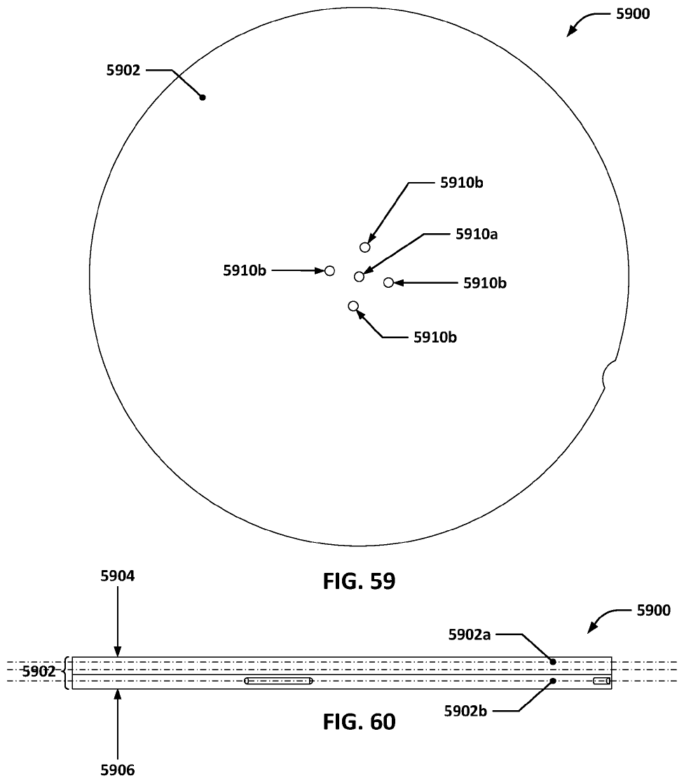

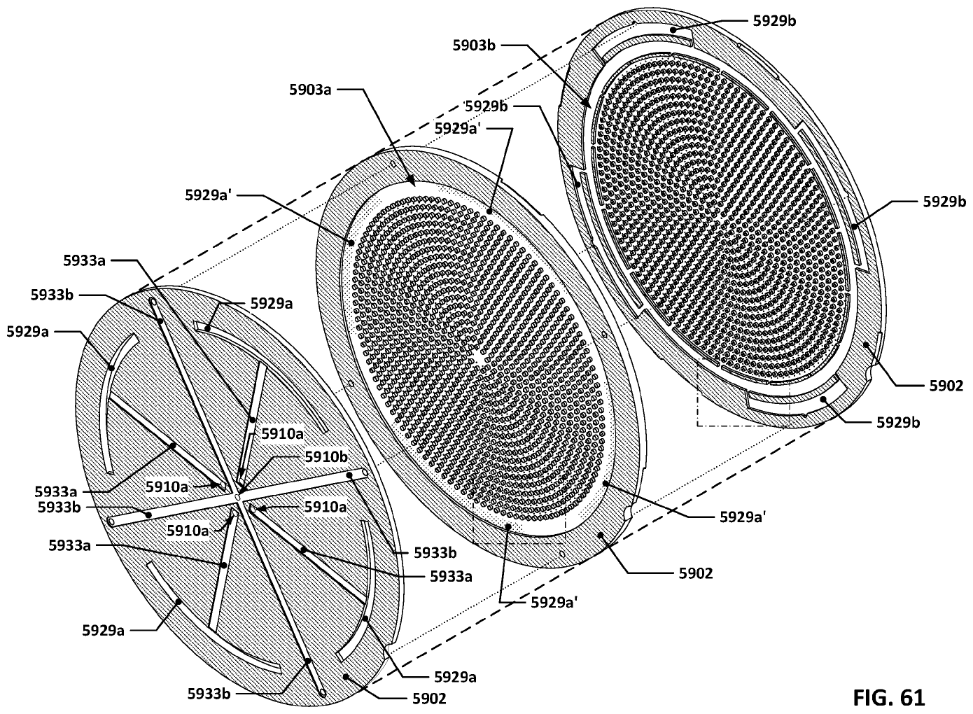

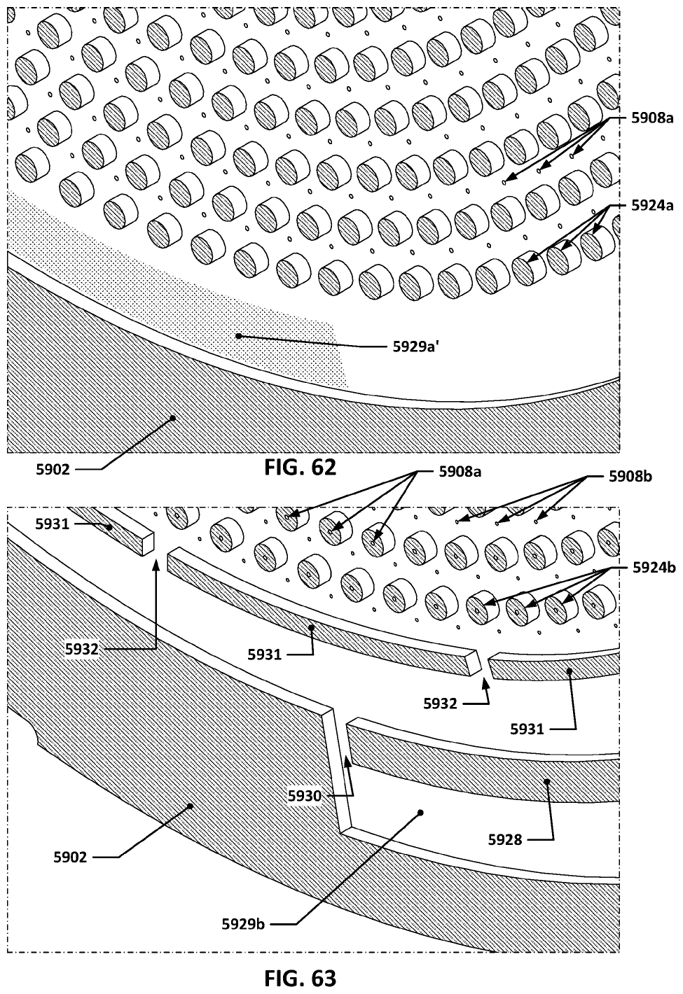

Further variants of showerheads having pillars spanning between upper and lower surfaces of one or more internal plenums are shown in FIGS. 59 through 63. FIG. 59 depicts a top view of an example showerhead having two edge-fed internal plenums with pillars spanning between upper and lower surfaces of each plenum. FIG. 60 depicts a side view of the example showerhead of FIG. 59. FIG. 61 depicts an isometric exploded section view of the example showerhead of FIG. 59 with the cut planes used to define the sections being positioned where the dash-dot-dash lines are in FIG. 60. FIG. 62 is a detail view of the portion of the example showerhead of FIG. 61 within the rectangular dash-dot-dash rectangle at left in FIG. 61. FIG. 63 is a detail view of the portion of the example showerhead of FIG. 61 within the rectangular dash-dot-dash rectangle at right in FIG. 61.

As can be seen from FIG. 59, the showerhead 5900 may feature a main body 5902 that includes a one or more first inlet ports 5910a (a single first inlet port 5910a is shown in FIG. 59) and one or more second inlet ports 5910b (four second inlet ports 5910b are shown in FIG. 59). The showerhead 5900, in this example, is a multi-piece showerhead having a first body 5902a and a second body 5902b that are assembled together, e.g., using threaded fasteners, so as to form an assembled showerhead. Such an approach allows the showerhead to be disassembled to allow for easier and/or more effective cleaning. Such an approach also allows for the first body 5902a and the second body 5902b to be made of different materials, e.g., the first body 5902a may be made of stainless steel and the second body 5902b may be made of a ceramic material, such as aluminum oxide. However, it will be understood that the showerhead 5900 may also be made as a single-piece component, e.g., via additive manufacturing or through laminated construction (in which multiple discrete layers of material are bonded together such that the assembled showerhead is not able to be non-destructively disassembled).

As can be seen in FIG. 61, the showerhead 5900 includes a plurality of first radial spoke passages 5933a. Each first radial spoke passage 5933a may have a first end that is collocated with one of the first inlet ports 5910a and a second end that is positioned radially outward from the first end and which terminates in a corresponding first arcuate plenum 5929a. The showerhead 5900 also includes a plurality of second radial spoke passages 5933b. Each second radial spoke passage 5933b may have a first end that is collocated with the second inlet port 5910b and a second end that is positioned radially outward from the first end thereof and which terminates in a riser passage that leads to a corresponding second arcuate plenum 5929b. The first radial spoke passages 5933a and the second radial spoke passages 5933b may be arranged in a circumferentially alternating pattern, e.g., in repeating instances of first/second/first/second radial passages.

A first process gas that is introduced into the showerhead 5900 via the first inlet ports 5910a will flow radially outward via the first radial spoke passages 5933a and into the first arcuate plenums 5929a and then into a first plenum volume 5903a via the shaded zones 5929a′. Put another way, the first plenum volume 5903a may be fluidically connected with the one or more first inlet ports 5910a within the main body 5902 by the first radial spoke passages 5933a.

The first process gas may then flow throughout the first plenum volume 5903a before exiting the first plenum volume 5903a via a plurality of first gas distribution holes 5908a (see FIG. 62). The first plenum volume 5903a, in this example, includes a plurality of first pillars 5924a that are distributed throughout the first plenum volume 5903, e.g., in multiple concentric circular patterns, and span or extend between upper and lower surfaces that bound, at least in part, the first plenum volume 5903a. Such first pillars 5924a may serve to provide structural rigidity to the showerhead 5900 and may also act to help more evenly distribute the flow of the first process gas throughout the first plenum volume 5903a and to conduct heat more efficiently between the bottom of the showerhead 5900 and the top of the showerhead 5900. In some implementations, the first pillars 5924a may be omitted, e.g., if increased heat conduction between the bottom of the showerhead 5900 and the top of the showerhead 5900 is not required and/or if there is sufficient structural rigidity in the first plenum volume 5903a of the showerhead 5900 such that the first pillars 5924a are unnecessary.

Similarly, a second process gas that is introduced into the showerhead 5900 via the second inlet port 5910b will flow radially outward via the second radial spoke passages 5933b and then through the riser passages and into the second arcuate plenums 5929b. The second arcuate plenums 5929b may, for example, be part of a second plenum volume 5903b. As can be seen in FIG. 63, the second arcuate plenums 5929b may be defined in part by first arcuate elements 5928. The first arcuate elements 5928 may, for example, be arcuate walls that separate the second arcuate plenums 5929b from the remainder of the second plenum volume 5903. Put another way, the second arcuate plenums 5929b may be considered to be sub-plenums of the second plenum volume 5903b. In some implementations, the second arcuate plenums 5929b may be replaced with non-arcuate plenums, e.g., rectangular or triangular plenums. The first plenum volume 5903a and the second plenum volume 5903b may both be interposed between a first side and a second side of the main body, with the first plenum 5903a interposed between the second plenum 5903b and the first side, and the second plenum 5903b interposed between the first plenum 5903a and the second side. The second plenum volume 5903b may be fluidically connected with the one or more second inlet ports 5910b within the main body 5902. The first gas distribution holes 5908a and the second gas distribution holes 5908b may, for example, extend from the first plenum volume 5903a and the second plenum volume 5903b, respectively, to the second side of the main body 5902, thereby allowing the process gases flowed through the first plenum volume 5903a and the second plenum volume 5903b to flow out of the underside of the showerhead 5900.

The depicted arrangement features the first inlet ports 5910a and the second inlet ports 5910b both located in a common center region of the main body 5902. The first arcuate plenums 5929a, as well as the first arcuate elements 5928 and the second arcuate plenums 5929b, may, as shown, be arranged in circular arrays about a center axis of the showerhead 5900, e.g., around the center region.

Each first arcuate element 5928 may have a plurality of first openings 5930 that extend radially inward through that first arcuate element 5928, thereby fluidically connecting the corresponding second arcuate plenum 5929b with the remainder of the second plenum volume 5903b. In this example, the first arcuate elements 5928 each have two openings 5930 located at opposing ends of the corresponding second arcuate plenum 5929b.

The second plenum volume 5903b in this example also includes second arcuate elements 5931 that are arranged in a circular array and are concentrically positioned, and located radially inward, with respect to the first arcuate elements 5928, thereby forming a radial gap between the first arcuate elements 5928 and the second arcuate elements 5931. Each second arcuate element 5931 may be separated from the adjacent second arcuate elements 5931 by second openings 5932. Thus, when a second process gas is flowed into the second plenum volume 5903b via the second arcuate plenums 5929b, the second process gas first flows into an annular sub-plenum region that is bounded (at least in part) between the first arcuate elements 5928 and the second arcuate elements 5931. The second process gas may then flow through the second openings 5932 to reach the interior region of the second plenum volume 5903b.

It will be observed that there are N first arcuate elements 5928 and second arcuate plenums 229a and 2N first openings 5930, and that there are 4N second arcuate elements 5931 and 4N second openings 5932 (N, in this example, is 4). Moreover, it can be seen that each second arcuate element 5931 is azimuthally positioned such that the center of that second arcuate element 5931 azimuthally aligns with or is azimuthally centered on one of the first openings 5930. “Azimuthally centered,” it will be understood, refers to a condition where elements that are arranged about a common center point are aligned such that element that is azimuthally centered on another element is positioned such that the center points of both elements lie along the same radius extending from the common center point.

It will also be observed that the first arcuate elements 5928 are all the same size, and that the second arcuate elements 5931 are also all the same size. Such an arrangement has the effect of providing multiple gas flow introduction points all around the circumference of the second plenum volume 5903b that generally all have equivalent flow resistance since the shortest flow path from any of the second openings 5932 to the second inlet port 5910b that is closest thereto (in terms of fluid path length) may generally have a flow path length (and fluidic resistance) that is equivalent to the shortest flow path from any of the other second openings 5932 to the second inlet port 5910b that is closest thereto. Such an arrangement acts to divide the gas flows introduced into each of the second arcuate plenums 5929b into two generally equal-sized gas flows, and to then further subdivide each of the generally equal-sized gas flows into two more generally equal-sized gas flows, thereby partitioning the second process gas flow into 4N generally equal gas flows that are equidistantly spaced about the perimeter of the second plenum volume 5903b. This may help ensure that the flow of second process gas from the second plenum volume 5903b and through the second gas distribution holes 5908b is more azimuthally uniform. It will be further understood that one or more additional concentric rings of arcuate elements may be included to further subdivide the second process gas flows, thereby further evening out the flow of the second process gas azimuthally. For example, each arcuate element in such an additional ring of arcuate elements may be azimuthally centered on one of the openings between the arcuate elements in the ring of arcuate elements that is immediately radially outward from that additional ring of arcuate elements.

As can be seen, the second plenum volume 5903b also features a plurality of second pillars 5924b that extend between the upper and lower surfaces of the second plenum volume 5903b. Each of the second pillars 5924b has one of the first gas distribution holes 5908a passing through it, thereby providing a flow path from the first plenum volume 5903a through the second plenum volume 5903b without allowing the first process gas in the first plenum volume 5903a to mix with the second process gas in the second plenum volume 5903b within the showerhead 5900.

It will be appreciated that the first plenum volume 5903a may also, in some implementations, feature a similar arrangement of arcuate elements as in the second plenum volume 5903b, e.g., forming one or more annular sub-plenum regions, each with a circular array of evenly spaced openings that allow the first process gas to flow radially inward in a more evenly distributed manner.

The showerhead 5900 features dual gas plenums that are each edge-fed, i.e., where the process gas that is introduced into each gas plenum is introduced into the respective plenum volume at multiple locations about the periphery of the plenum volume. However, such showerheads may also be implemented so as to have a center-fed plenum volume.

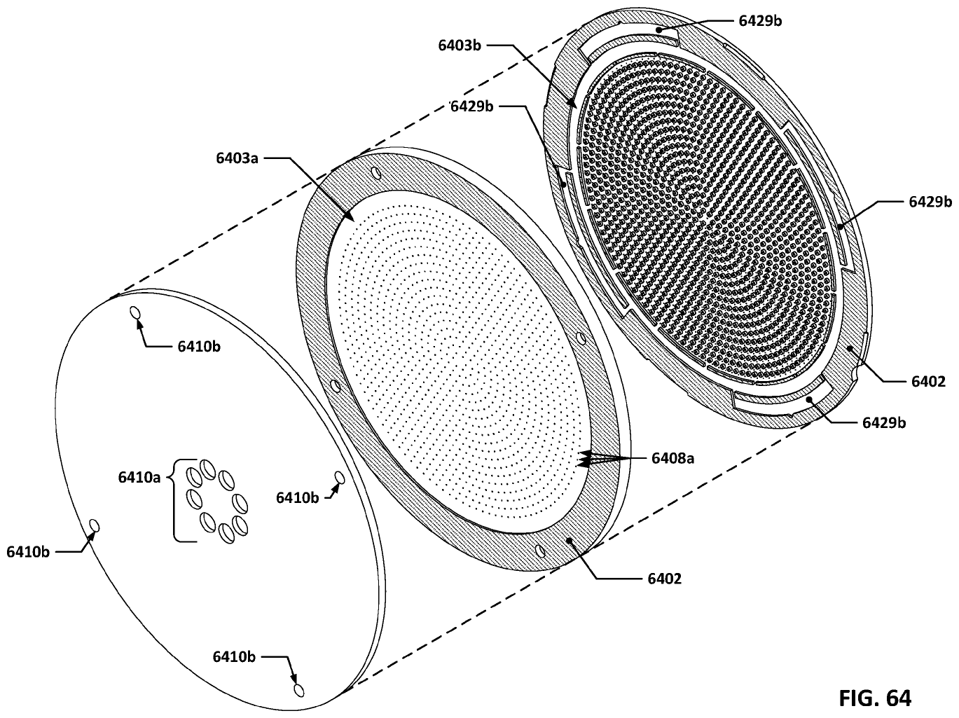

For example, FIG. 64 depicts an isometric exploded section view of an example showerhead similar to that shown in FIGS. 59 through 63, except that one of the internal plenums is center-fed and does not have pillars spanning between top and bottom surfaces thereof. As can be seen, the showerhead 6400 shown in FIG. 64 includes within it a first plenum volume 6403a and a second plenum volume 6403b. The second plenum volume 6403b may be similar to the second plenum volume 5903b of the example showerhead 5900 discussed above with respect to FIGS. 59 through 63. Elements of the implementation of FIG. 64 that are similar to those in the implementation of FIGS. 59 through 63 are called out in FIG. 64 using callouts with the same last two digits. The descriptions of such elements presented above with respect to FIGS. 59 through 63 will be understood to be equally applicable to the implementation of FIG. 64, and such elements are thus not re-described here unless necessary.

While the second plenum volume 6403b is generally identical to the second plenum volume 5903b, the first plenum volume 6403a of the showerhead 6400 is quite different from the first plenum volume 5903a. For example, whereas the first plenum volume 5903a included the plurality of first pillars 5924a, the first plenum volume 6403a does not have any first pillars 5924a. However, it will be understood that the first plenum volume 6403a may, in some implementations, still include a plurality of first pillars, similar to the implementation of FIGS. 59 through 63.

The first plenum volume 6403a also does not include or interface with any first arcuate plenums. Instead, the first process gas may be flowed into the center of the first plenum volume 6403a via one or more first inlet ports 6410a located near the center of, and on the top surface of, the showerhead. In the depicted implementation, there are multiple first inlet ports 6410a arranged in a circular array about a center axis of the showerhead 6400. However, other implementations thereof may feature only a single center-located inlet port 6410a. In some other implementations, there may be multiple inlet ports 6410a that are located closer to the edge of the first plenum volume 6403a.

The second process gas may be introduced into the second plenum volume 6403b via the second inlet ports 6410b, which are shown located near the periphery of the showerhead 6400. However, it will be understood that the showerhead 6400 may also feature an inlet port arrangement similar to that of the showerhead 5900. For example, the top of the showerhead 6400 may have the first inlet ports 6410a and the second inlet ports 6410b both located near the center axis of the showerhead 6400. In such an implementation, the second inlet ports 6410b may be joined by radial spoke passages, e.g., similar to the second radial spoke passages 5933b, to riser passages that are located outside of the first plenum volume 6403a and that lead to the second plenum volume 6403b.

As noted earlier, the flow conductance and/or the spacing of gas distribution holes along the spiral paths of showerheads with spiral passages may be modified so as to have varying spacing and/or size (e.g., diameter) so as to create radial zones in which gas flow may be increased or decreased relative to other radial zones. Showerheads featuring pillar features such as are discussed above may be similarly designed so as to have radially varying port size (e.g., diameter) and/or radially and/or circumferentially varying spacing so as to be able to provide increased or reduced gas flow at different radial distances from the center axis of the showerhead.

As alluded to earlier, the above-referenced showerheads include features that make them suitable for use in semiconductor processing contexts, e.g., having the ability to distribute process gas or gases in a generally uniform manner over a large area, e.g., an area similar in size to (or larger than) a semiconductor wafer. At the same time, such showerheads may also include features having reduced, minimal, or no horizontal surfaces that are unsupported from below, e.g., in the same orientation as the showerheads may be in when being used, so as to make such components more suitable to being made using additive manufacturing techniques such as selective laser melting (SLM) or direct metal laser melting (DMLM), or other LPBF techniques. Moreover, such components may be made from metallic materials that are compatible (or made compatible with the application of an appropriate coating material) with the processing gases that such components are configured to deliver. Example materials may include aluminum alloys that are then coated with an aluminum oxide coating, high-nickel alloys such as Hastelloy C22 (a nickel-chromium-molybdenum superalloy having, by percentage mass, <%0.015 C, 20%-22.5% Cr, 2%-6% Fe, ≤0.5% Mn, ≤0.08% Si, 12.5%-14.5% Mo, ≤2.5% Co, ≤0.02% P, ≤0.02% S, ≤0.35% V, 2.5%-3.5% W, and the balance Ni), or other suitable material. Other potentially suitable materials may include alloys such as Inconel 625 (a nickel-chromium alloy having, by percentage mass, <%0.1 C, 20%-30% Cr, ≤5% Fe, ≤0.5% Mn, ≤0.5% Si, 8%-10% Mo, ≤1% Co, ≤0.015% P, ≤0.015% S, ≤0.4% Al, ≤0.4% Ti, 3.15%-4.15% Nb (+Ta), and the balance Ni) or Inconel 718 (a nickel-chromium alloy having, by percentage mass, <%0.08 C, 17%-21% Cr, 17% Fe, ≤0.35% Mn, ≤0.35% Si, 2.8%-3.3% Mo, ≤1% Co, ≤0.015% P, ≤0.015% S, 0.2%-0.8% Al, 0.65%-1.15% Ti, 4.75%-5.5% Nb (+Cb), ≤0.006% B, ≤0.3% Cu, and the balance Ni). For showerheads that are to be used as electrodes in a semiconductor processing tool, such materials may generally encompass any metallic, electrically conductive material that is suitable for being used in additive manufacturing processes and that is also chemically resistant or inert with respect to the process gases used in the semiconductor processing chamber in which the showerhead is to be used.

As discussed earlier, due to the surface roughness that arises in additively manufactured components from the additive manufacturing process, it may be necessary or desirable to perform post-additive-manufacturing processing on additively manufactured showerheads to abrade, polish, or machine such surfaces to a finer surface finish. For example, it may be desirable to flow a polishing slurry or paste through the spiral passages (or internal plenum volume) of a showerhead to remove potential sharp discontinuities on the interior surfaces. Such flow may be introduced, for example, through an inlet port of the showerhead in much the same manner as process gas may be delivered to the showerhead. A separate outlet port may be provided at a location that is at the opposite end (or ends) of the internal cavity to be polished; once polishing is completed, the outlet port may be, in some cases, sealed to allow process gases introduced into the internal cavity to be prevented from leaking out of the internal cavity.

Surfaces of the showerhead that are externally accessible to tooling, such as the gas distribution holes and the exterior surfaces of the showerhead, may be subjected to machining and/or polishing operations in order to render such surfaces suitable for use in a semiconductor processing chamber. For example, external surfaces of such showerheads may, after additive manufacturing is complete, be machined using milling, lathing, or other suitable process to remove a thin layer of material and achieve a desired surface finish. Such surfaces may also be lapped or polished, as desired.

The gas distribution holes may be machined, for example, partially or entirely using post-additive manufacturing operations. For example in some implementations, the gas distribution holes may be created during the additive manufacturing process, either as full-depth holes or partial-depth holes of a smaller diameter than they will be in final form, and may act as pilot holes for guiding post-additive manufacturing hole-drilling operations. In other implementations, the additively manufactured showerhead may not have any gas distribution hole features after additive manufacturing is completed. In such cases, the gas distribution holes may instead be machined into the showerhead entirely using post-additive-manufacturing machining operations, such as mechanical drilling or electric discharge drilling. Such operations may ensure that the gas distribution holes are of a uniform (or desired) diameter or size along their center axes, thereby ensuring more predictable gas flow through the gas distribution holes than if the gas distribution holes were to be entirely additively manufactured. The gas distribution holes may, for example, be between 0.010 inches to 0.040 inches in diameter in some implementations, although potentially larger in some implementations.

The implementations discussed herein, while designed to be suitable for manufacture using additive manufacturing techniques, may also be manufactured using more traditional manufacturing techniques, such as machining the internal features of a showerhead into a plate and then brazing, welding, diffusion bonding, or otherwise joining the face of that plate having such features to another plate in order to cap those features off and turn them into internal features of the showerhead. In such implementations, features discussed above that are provided to facilitate or accommodate additive manufacturing processes may be omitted. For example, traditionally machined showerheads may include horizontal, flat surfaces that form the “ceilings” of the interior plenum volumes and/or gas passages within a showerhead that may present manufacturing issues if included in additively manufactured versions. Similarly, the gas passages in such showerheads may have sharp (or much smaller radius) internal corners.

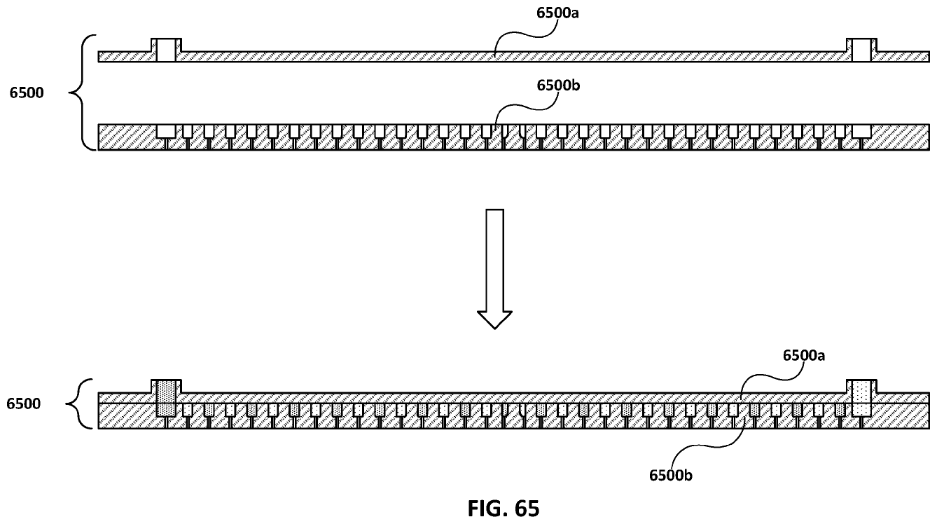

FIG. 65 depicts an example of a showerhead 6500 that is manufactured using such traditional machining techniques, e.g., subtractive manufacturing. For example, the showerhead 6500 may be made from two pieces—an upper piece 6500a and a lower piece 6500b, as shown in the upper half of FIG. 65. The lower piece 6500b may, for example, have spiral channels machined into it while the upper piece 6500a may generally be a flat plate (potentially with raised features on one side, e.g., such as for the inlet ports). The upper piece 6500a may then be bonded, brazed, welded, or otherwise joined to the lower piece 6500b in order to cap the spiral channels and turn them into internal spiral passages of the showerhead 6500, as shown in the lower half of FIG. 65. This, of course, is but one example of how traditional manufacturing techniques may be used to manufacture showerheads such as those discussed herein.

It will be further understood that such showerheads may be made as a laminated ceramic structure, e.g., with one or more ceramic plates that are machined or otherwise formed, e.g., by pressing, so as to have such features, e.g., open spiral channels (similar to the example discussed in FIG. 65) or open plenums with a plurality of pillars extending therethrough (similar to the examples of FIGS. 37 through 58). Such a ceramic plate or ceramic plates may then be bonded to another ceramic plate and/or to each other so as to cap such open channel features or pillar-containing plenum volumes to form enclosed passages or enclosed plenums. For example, such ceramic plates may be bonded together by sintering the ceramic plates together. Such approaches may also be used to provide multi-plenum structures in which there are multiple levels of such passages or plenum volumes at different elevations, with the plenum volume or passages of each elevation being provided by a machined or formed ceramic plate similar to the lower piece 6500b that is then bonded to either another such lower piece 6500b or to an upper piece 6500a. It will also be understood that the channel features that are shown in FIG. 65 as being machined or formed in the lower piece 6500b (or plenum/pillar features that may be machined or formed in such a lower piece for showerheads such as are shown in FIGS. 37 through 58) may alternatively or additionally be machined or formed in the upper piece 6500a.

It will be understood that characterizations of how the various pillars and/or gas distribution holes that are discussed herein are arranged in which statements are made regarding “each pillar” or “each gas distribution hole or port” or the like may be general characterizations that apply only to a set of such pillars and/or gas distribution holes, e.g., pillars and/or gas distribution holes that are located within the interior of an internal plenum volume as opposed to near the outer perimeter (for example, at some point, whatever repeating pattern there may be of pillars and/or gas distribution holes will need to end, at which point the characteristics of the repeating pattern that hold true for pattern instances in the interior of the pattern will cease to hold true at the outer edges of the pattern).

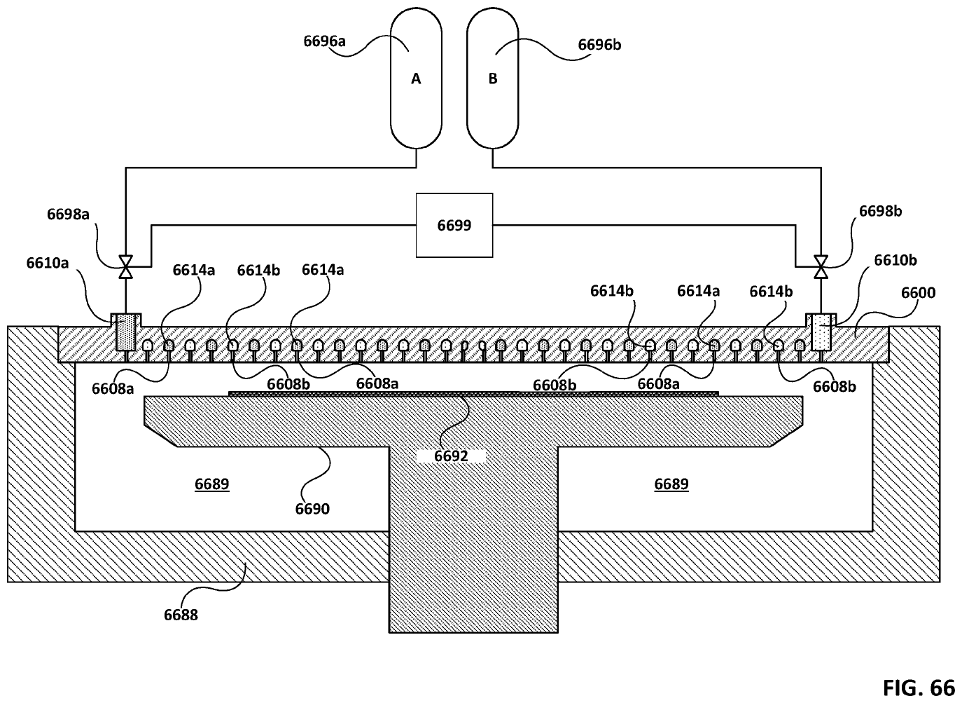

The showerheads discussed herein may be used in a semiconductor processing chamber to deliver various reactants to a processing space above a semiconductor wafer that is being processed. FIG. 66 depicts a schematic of such a chamber. As seen in FIG. 66, a semiconductor processing tool may include a processing chamber 6688 that may enclose an interior volume 6689. The processing chamber 6688 may include, for example, a showerhead 6600 that may be any of the showerheads discussed herein (the depicted example is a showerhead similar to the showerhead 500, but it will be understood that other showerheads disclosed herein may be used in place of this specific design). In this example, the showerhead 6600 is a flush-mount showerhead, e.g., a showerhead that mounts acts as a lid to the chamber and seals off a large opening, e.g., an opening that is sized larger than the diameter of a semiconductor wafer 6692, and that acts as the “ceiling” or part of the ceiling of the processing chamber 6688. In other implementations, the showerhead may be supported within the interior volume 6689 by a vertical column or stem that extends into the interior volume 6689 through an aperture in the ceiling of the processing chamber 6688; such showerheads are typically referred to as “chandelier showerheads.”

The showerhead 6600 is a two-plenum showerhead that has a first spiral passage 6614a and a second spiral passage 6614b. The first spiral passage 6614a may be provided one or more first processing gases via a first inlet port 6610a that is fluidically connected with a first gas supply 6696a via a first valve 6698a. Similarly, the second spiral passage 6614b may be provided one or more second processing gases via a second inlet port 6610b that is fluidically connected with a second gas supply 6696b via a second valve 6698b. A controller 6699 may be provided that may be configured to communicate with the first valve 6698a and the second valve 6698b and to control the valves 6698 so as to selectively enable or disable gas flow to either or both of the first spiral passage 6614a and the second spiral passage 6614b. Gas that is flowed into the first spiral passage 6614a or the second spiral passage 6614b may be flowed out of the first spiral passage 6614a or the second spiral passage 6614b via first gas distribution holes 6608a or second gas distribution holes 6608b, respectively. The semiconductor wafer 6692 may be supported within the processing chamber 6688 by a pedestal 6690. The pedestal 6690 may, for example, include a wafer support surface that is configured to support the semiconductor wafer 6692 from below.

It will also be understood that the “junction” features discussed earlier herein may be employed in any of the implementations discussed above, including those with pillars or spiral passages, in order to reduce stress risers. Thus, for example, pillars in some of the implementations may be equipped with stepped junctions at the interfaces between the pillars and the upper and lower surfaces of the pillars.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electrical connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.” There may also be reference to a “zeroth” item herein, which is to be understood as simply being a reference to another ordinal indicator, e.g., on that comes before a “first” item (of course, as noted above, there is no particular order indicated by the use of ordinal indicators unless the context indicates otherwise. It will also be understood that reference to “first,” “second,” etc. with respect to various elements herein may not be carried through to the claims. For example, elements that are referred to as “first” and “second” in the discussion above may instead be referred to in the claims as, respectively, the “second” and “first” elements. Such recharacterization of such ordinal indicators may be resorted to in order to avoid instances in which a “second” element might be introduced in a claim before a corresponding “first”element.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

Terms such as “about,” “approximately,” “substantially,” “nominal,” or the like, when used in reference to quantities or similar quantifiable properties, are to be understood to be inclusive of values within ±10% of the values or relationship specified (as well as inclusive of the actual values or relationship specified), unless otherwise indicated.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure. At the very least, the present disclosure is directed to at least the following numbered implementations.
Implementation 1: An apparatus including: a main body having a first side and a second side on an opposite side of the main body from the first side; N spiral passages located within the main body, each spiral passage following a corresponding spiral path, the N spiral passages including at least: a first spiral passage located within the main body, in which at least a portion of the first spiral passage follows a first spiral path and has a first cross-sectional profile along at least a portion of the first spiral path, and a second spiral passage located within the main body, in which at least a portion of the second spiral passage follows a second spiral path and has a second cross-sectional profile along at least a portion of the second spiral path; a plurality of first gas distribution holes extending from the second side to the first spiral passage; a plurality of second gas distribution holes extending from the second side to the second spiral passage; one or more first inlet ports, each first inlet port extending from a corresponding location on the exterior of the main body to the first spiral passage; and one or more second inlet ports, each second inlet port extending from a corresponding location on the exterior of the main body to the second spiral passage, in which: the first gas distribution holes are arranged along the first spiral path, and the second gas distribution holes are arranged along the second spiral path.
Implementation 2: The apparatus of implementation 1, in which: the first cross-sectional profile has a first segment proximate to the first side, a second segment positioned such that the first segment is between the second segment and the first side, and opposing first side segments, each first side segment spanning between the first segment and the second segment, the second cross-sectional profile has a third segment proximate to the first side, a fourth segment positioned such that the third segment is between the fourth segment and the first side, and opposing second side segments, each second side segment spanning between the third segment and the fourth segment, the first segment includes corresponding first rounded transition regions, the third segment includes corresponding second rounded transition regions each first rounded transition region connects with a corresponding one of the first side segments, and each second rounded transition region connects with a corresponding one of the second side segments.
Implementation 3: The apparatus of implementation 2, in which: each first rounded transition region is tangent to the first side segment to which it connects, and each second rounded transition region is tangent to the second side segment to which it connects.
Implementation 4: The apparatus of implementation 2, in which: the first rounded transition regions connected with the first side segments connect with each other such that the first segment has a circular or parabolic profile in cross-section.
Implementation 5: The apparatus of implementation 2, in which: the second rounded transition regions connected with the second side segments connect with each other such that the third segment has a circular or parabolic profile in cross-section.
Implementation 6: The apparatus of implementation 2, in which: the first rounded transition regions connected with the first side segments connect with each other such that the first segment has a circular or parabolic profile in cross-section, and the second rounded transition regions connected with the second side segments connect with each other such that the third segment has a circular or parabolic profile in cross-section.
Implementation 7: The apparatus of any one of implementations 2 through 6, in which: the second segment includes corresponding third rounded transition regions, the fourth segment includes corresponding fourth rounded transition regions, each third rounded transition region connects with a corresponding one of the first side segments, and each fourth rounded transition region connects with a corresponding one of the second side segments.
Implementation 8: The apparatus of implementation 7, in which: the third rounded transition regions are smaller in cross-sectional profile than the first rounded transition regions, and the fourth rounded transition regions are smaller in cross-sectional profile than the second rounded transition regions.
Implementation 9: The apparatus of implementation 7 or implementation 8, in which:
   the third segment includes a first linear portion located between the third rounded transition regions, the fourth segment includes a second linear portion located between the fourth rounded transition regions, and the first linear portion and the second linear portion are parallel to a first plane defined by the first side.
Implementation 10: The apparatus of implementation 9, in which: the first gas distribution holes connect with the first spiral passage at cross-sectional locations within the first linear portion, and the second gas distribution holes connect with the second spiral passage at cross-sectional locations within the second linear portion.
Implementation 11: The apparatus of any one of implementations 1 through 9, in which: the spiral paths followed by the N spiral passages are all coaxial with one another, the spiral paths are all at different angular orientations with respect to a center axis of the spiral paths, and each spiral path is 360°/N out of phase with each neighboring spiral path.
Implementation 12: The apparatus of implementation 11, in which N=2.
Implementation 13: The apparatus of implementation 11, in which N=3.
Implementation 14: The apparatus of any one of implementations 1 through 13, further including: N spiral walls, each spiral wall separating one spiral passage from an adjacent spiral passage and following a corresponding spiral wall path; and a plurality of zeroth gas distribution holes, each zeroth gas distribution hole extending from the first side of the main body to the second side of the main body, in which the zeroth gas distribution holes are distributed along the corresponding spiral wall path for at least one of the spiral walls.
Implementation 15: The apparatus of implementation 14, in which the zeroth gas distribution holes are distributed along the corresponding spiral wall paths of the spiral walls.
Implementation 16: The apparatus of any one of implementations 1 through 9, further including a plurality of zeroth gas distribution holes arranged along a zeroth spiral path, in which: each zeroth gas distribution hole extends from the first side of the main body to the second side of the main body, and the spiral paths, including the spiral paths followed by the N spiral passages and the zeroth spiral path, are: coaxial with one another, at different angular orientations with respect to a center axis of the spiral paths, and each 360°/(N+1) out of phase with each neighboring spiral path.
Implementation 17: The apparatus of implementation 16, in which the first cross-sectional profile is at a different distance from the second side in a direction perpendicular to a plane defined by the second side than the second cross-sectional profile.
Implementation 18: The apparatus of any one of implementations 1 through 17, in which the first spiral path and the second spiral path have the same pitch and the same number of revolutions.
Implementation 19: The apparatus of any one of implementations 1 through 17, in which the first spiral path has between 5 and 15 revolutions.
Implementation 20: The apparatus of any one of implementations 1 through 19, in which: the one or more first inlet ports connect with the first spiral passage at a location or locations that are proximate to an end of the first spiral passage that is furthest from a center of the first spiral path, and the one or more second inlet ports connect with the second spiral passage at a location or locations that are proximate to an end of the second spiral passage that is furthest from a center of the second spiral path.
Implementation 21: The apparatus of implementation 20, in which the one or more first inlet ports and the one or more second inlet ports are positioned at a common azimuthal location relative to the first spiral path and the second spiral path.
Implementation 22: The apparatus of any one of implementations 1 through 21, in which the first spiral path has an outer diameter of at least 300 mm.
Implementation 23: The apparatus of any one of implementations 1 through 22, in which the main body and spiral passages are formed through additive manufacturing.
Implementation 24: The apparatus of implementation 23, in which the main body and spiral passages are formed from a material exhibiting an anisotropic micrograin structure.
Implementation 25: The apparatus of implementation 24, in which the material is a metal.
Implementation 26: The apparatus of implementation 25, in which the metal is Hastelloy C-22 alloy
Implementation 27: The apparatus of any one of implementations 23 through 26, in which the first gas distribution holes and the second gas distribution holes are drilled or electrical discharge machined holes.
Implementation 28: The apparatus of any one of implementations 23 through 27, further including a plurality of outlet ports, in which: each spiral passage is fluidically interposed between two of the outlet ports, and at least one of the outlet ports between which each spiral passage is fluidically interposed is sealed off to prevent fluid flow therethrough.
Implementation 29: The apparatus of implementation 28, in which at least one of the inlet ports also serves as one of the outlet ports.
Implementation 30: The apparatus of either implementation 28 or implementation 29, in which the outlet ports are used to flow a polishing compound through the spiral passages.
Implementation 31: A method for manufacturing the apparatus of any one of implementations 1 through 30, including: manufacturing the main body and, concurrently with manufacturing the main body, the spiral passages using additive manufacturing, and drilling the first gas distribution holes and the second gas distribution holes after manufacturing the main body.
Implementation 32: The method of implementation 31, in which the drilling is performed using a mechanical drill or using electric discharge drilling.
Implementation 33: The method of either implementation 31 or implementation 32, further including flowing a polishing compound through the spiral passages.
Implementation 34: An apparatus including: a main body having a first side and a second side on an opposite side of the main body from the first side; a first internal plenum volume located within the main body, the first internal plenum volume located between a first surface and a second surface, the first surface between the first side and the second surface, and the second surface between the first surface and the second side; a plurality of pillars, the plurality of pillars including first pillars distributed throughout a first region of the first internal plenum volume, in which: each first pillar in a set of the first pillars spans between the first surface and the second surface, each first pillar in the set of first pillars includes a corresponding first gas distribution hole that extends between the first side and the second side, each first pillar in the set of first pillars has one or more exterior side walls, and the one or more exterior side walls of each first pillar in the set of first pillars connect with the first surface via a corresponding first rounded transition region; and a plurality of second gas distribution holes distributed throughout the first region of the first internal plenum volume, each second gas distribution hole spanning between the second side and the second surface.
Implementation 35: The apparatus of implementation 34, further including: a second internal plenum volume located within the main body, the second internal plenum volume located between a third surface and a fourth surface, the third surface between the first side and the fourth surface, the fourth surface between the third surface and the second side, and the third and fourth surfaces between the first side and the first surface, in which: each first pillar in the set of first pillars is interposed between two corresponding second pillars of the plurality of pillars, the two corresponding second pillars for each first pillar in the set of first pillars are the two closest pillars in the first internal plenum volume to that first pillar, each first pillar in the set of first pillars and the corresponding second pillars for that first pillar are arranged along a corresponding first axis parallel to a first direction, the plurality of pillars further includes third pillars located within the second internal plenum volume, each third pillar corresponding in location to one of the first pillars in the set of first pillars and having the corresponding first gas distribution hole for that first pillar extending therethrough, and the corresponding second pillars for each first pillar in the set of first pillars each include a corresponding third gas distribution hole that spans between the second side and the fourth surface.
Implementation 36: The apparatus of implementation 35, in which: each first pillar in the set of first pillars is interposed between two of the second gas distribution holes that are closest to that first pillar, each first pillar in the set of first pillars and the two second gas distribution holes closest thereto are arranged along a corresponding second axis parallel to a second direction, and the second direction is transverse to the first direction.
Implementation 37: The apparatus of implementation 36, in which a center of each first pillar in the set of first pillars is equidistantly spaced from centers of the two second pillars that are closest to that first pillar and from centers of the two second gas distribution holes that are closest to that first pillar.
Implementation 38: The apparatus of implementation 36 or implementation 37, in which the first direction is perpendicular to the second direction.
Implementation 39: The apparatus of any one of implementations 36 through 38, in which the first pillars in the set of first pillars are arranged in a square array.
Implementation 40: The apparatus of implementation 39, in which the square array has array axes that are at 45° to the first direction.
Implementation 41: The apparatus of implementation 34, further including a second internal plenum volume located within the main body, the second internal plenum volume located between a third surface and a fourth surface, the third surface between the first side and the fourth surface, the fourth surface between the third surface and the second side, and the third and fourth surfaces between the first side and the first surface, in which: the plurality of pillars also includes second pillars located within the first internal plenum volume and third pillars located within the second internal plenum volume, for each first pillar in the set of first pillars, the three pillars closest thereto within the first internal plenum volume are each second pillars, equidistantly spaced from that first pillar, and equidistantly spaced from one another, each third pillar corresponds in location to one of the first pillars in the set of first pillars and has the corresponding first gas distribution hole for that first pillar extending therethrough, and the second pillars each include a corresponding third gas distribution hole that spans between the second side and the fourth surface.
Implementation 42: The apparatus of implementation 41, in which, for each first pillar in the set of first pillars, the three second gas distribution holes closest thereto are each equidistantly spaced from that first pillar and equidistantly spaced from one another.
Implementation 43: The apparatus of either implementation 41 or implementation 42, in which each second gas distribution hole in a set of the second gas distribution holes is at the center of a hexagonal pattern of three first pillars and three second pillars.
Implementation 44: The apparatus of any one of implementations 34 through 43, in which: the second surface defines a first reference plane, each of the pillars in a set of the pillars in the first internal plenum volume is associated with a corresponding contour region of the first surface, a corresponding portion of the first surface is bounded by the corresponding contour region for each pillar in the set of pillars, and a first distance between the first reference plane and the corresponding portion of the first surface for each pillar in the set of pillars in the first internal plenum volume increases as a function of a second distance from a center axis of that pillar.
Implementation 45: The apparatus of any one of implementations 34 through 44, in which, for each pillar in a set of pillars in the first internal plenum volume, the first distances for that pillar are determined according to a scalar function having axial symmetry about a center axis of that pillar.
Implementation 46: The apparatus of implementation 44, in which: cross-sectional profiles of the corresponding portion of the first surface for each pillar in a set of pillars in the first internal plenum volume are, at a boundary of the corresponding contour region for that pillar, tangent to a second reference plane that is parallel to the first reference plane and are, at that pillar, tangent to a third reference plane that is parallel to the second reference plane.
Implementation 47: The apparatus of implementation 44, in which, for each pillar in the set of pillars in the first internal plenum volume, a difference between minimum and maximum values of the first distance within the corresponding contour region for that pillar is between 20% and 30% of a maximum distance between the center axis of that pillar and a boundary of the corresponding contour region.
Implementation 48: The apparatus of implementation 44, in which the corresponding contour region for each pillar in a set of pillars in the first internal plenum volume has boundary edges that are perpendicular to, and bisect, reference lines extending between that pillar and adjacent pillars within the first internal plenum volume.
Implementation 49: The apparatus of implementation 44, in which: the corresponding contour region for each pillar in a set of pillars in the first internal plenum volume is bounded by a corresponding plurality of bounding reference planes, and for each of the pillars in the set of pillars in the first internal plenum volume, each reference plane in the corresponding plurality of bounding reference planes for that pillar is positioned midway between that pillar and another pillar in the first internal plenum volume and is perpendicular to a corresponding reference axis that is parallel to the first reference plane and that passes through the center of that pillar and the other pillar.
Implementation 50: The apparatus of any one of implementations 34 through 49, in which: the one or more exterior side walls of each first pillar in the set of first pillars connect with the second surface via a corresponding second rounded transition region, and the second rounded transition regions are smaller than the first rounded transition regions.
Implementation 51: The apparatus of any one of implementations 34 through 50, in which the first rounded transition region of each first pillar in the set of first pillars meets the first rounded transition region of at least one other first pillar of the first pillars.
Implementation 52: The apparatus of any one of implementations 34 through 51, in which: the first surface is offset from the second surface in a direction perpendicular to the first surface and by a first amount, and the first amount is less than or equal to 120% of a radius of the first rounded transition regions.
Implementation 53: The apparatus any one of implementations 34 through 52, in which each first pillar in the set of first pillars may have a centerline that is within 240% of a radius of the first rounded transition regions of the centerlines of any immediately neighboring first pillars of that first pillar.
Implementation 54: The apparatus of any one of implementations 1 through 53, in which the first region is a circular region of at least 300 mm in diameter.
Implementation 55: The apparatus of any one of implementations 34 through 54, in which the main body and the first pillars are formed through additive manufacturing.
Implementation 56: The apparatus of implementation 55, in which the main body and first pillars are formed from a material exhibiting an anisotropic micrograin structure.
Implementation 57: The apparatus of implementation 56, in which the material is a metal.
Implementation 58: The apparatus of implementation 57, in which the metal is Hastelloy C-22 alloy Implementation 59: The apparatus of any one of implementations 55 through 58, in which the first gas distribution holes and the second gas distribution holes are drilled or electrical discharge machined holes.
Implementation 60: An apparatus including: a main body having a first side and a second side on an opposite side of the main body from the first side, the main body having within it a first plenum volume and a second plenum volume, in which the first plenum volume is interposed between the first side and the second plenum volume and the second plenum volume is interposed between the second side and the first plenum volume; one or more first inlet ports fluidically connected with the first plenum volume within the main body; one or more second inlet ports fluidically connected with the second plenum volume within the main body; a plurality of first pillars distributed throughout the second plenum volume, each first pillar extending between an upper surface bounding the second plenum volume and a lower surface of the second plenum volume; a plurality of first gas distribution holes, each first gas distribution hole extending between the second side and the first plenum volume and passing through one of the first pillars, and a plurality of second gas distribution holes, each second gas distribution hole extending between the second side and the second plenum volume.
Implementation 61: The apparatus of implementation 60, further including a plurality of second pillars, each second pillar extending between an upper surface bounding the first plenum volume and a lower surface bounding the first plenum volume.
Implementation 62: The apparatus of implementation 60, further including a plurality of first arcuate elements positioned within the second plenum volume, the first arcuate elements each generally co-radial and concentric with one another and each defining, in part, a corresponding sub-plenum of the second plenum volume, in which each sub-plenum is fluidically connected with at least one of the one or more second inlet ports within the main body.
Implementation 63: The apparatus of implementation 62, in which the second plenum volume includes a plurality of first openings that extend radially inward, each first opening located at a different end of one of the first arcuate elements.
Implementation 64: The apparatus of implementation 62, in which the plurality of first pillars is located within a perimeter defined by the first arcuate elements.
Implementation 65: The apparatus of implementation 63, further including a plurality of second arcuate elements positioned within the second plenum volume, the second arcuate elements each generally co-radial and concentric with one another.
Implementation 66: The apparatus of implementation 65, in which the second plenum volume includes a plurality of second openings that extend radially inward, each second opening located at a different end of one of the second arcuate elements.
Implementation 67: The apparatus of implementation 66, in which each second arcuate element is azimuthally centered on one of the first openings, and each second opening is azimuthally centered on one of the first arcuate elements.
Implementation 68: The apparatus of implementation 66, in which a radial gap exists between the first arcuate elements and the second arcuate elements.
Implementation 69: The apparatus of implementation 66, in which the plurality of first pillars is located within a perimeter defined by the second arcuate elements.
Implementation 70: The apparatus of any one of implementations 60 through 69, in which: the one or more first inlet ports are located in a center region of the main body and on the first side, the one or more second inlet ports are located in the center region of the main body and on the first side and include a plurality of second inlet ports, a plurality of first radial spoke passages and a plurality of second radial spoke passages are interposed between the first plenum volume and the first side, each first radial spoke passage extends from a first inlet port of the one or more first inlet ports to a location proximate an outer periphery of the first plenum volume, and each second radial spoke passage extends from a second inlet port of the one or more second inlet ports to a location proximate an outer periphery of the second plenum volume.
Implementation 71: The apparatus of implementation 70, in which the first radial spoke passages and the second radial spoke passages are arranged in a circumferentially alternating circular pattern.
Implementation 72: The apparatus of implementation 71, in which each first radial spoke passage terminates in the middle of a corresponding arcuate plenum that leads to the first plenum volume.
Implementation 73: The apparatus of implementation 70, in which the first plenum volume has no pillars extending through it.
Implementation 74: The apparatus of implementation 70, in which the first plenum volume has a plurality of second pillars that are distributed throughout the first plenum volume, each second pillar extending between an upper surface bounding the first plenum volume and a lower surface of the first plenum volume.
Implementation 75: The apparatus of any one of implementations 60 through 74, in which the one or more first inlet ports are located in a center region of the main body and on the first side and fluidically connect with the first plenum volume in a center region of the first plenum volume.
Implementation 76: The apparatus of implementation 75, further including a plurality of radial spoke passages interposed between the first side and the first plenum volume, in which each radial spoke passage extends from one of the second inlet ports to a corresponding riser passage located outside of an outer periphery of the first plenum volume and fluidically connecting that radial spoke passage with the second plenum volume within the main body.
Implementation 77: The apparatus of any one of implementations 60 through 76, in which: at least one of the first pillars has a side surface that meets the upper and lower surfaces bounding the second plenum volume at corresponding junctions; each junction includes a rise surface and a run surface; the run surfaces of the corresponding junctions face each other, the rise surfaces of the corresponding junctions faces radially outward relative to a center axis of the side surface, the rise surface of the junction between the upper surface and the side surface forms an interior corner with the upper surface bounding the second plenum volume, the rise surface of the junction between the lower surface and the side surface forms an interior corner with the lower surface bounding the second plenum volume, and the run surface of each of the junctions forms an interior corner with the side surface.
Implementation 78: The apparatus of implementation 77, in which the rise surface and the run surface of each junction meet at an exterior corner.
Implementation 79: The apparatus of any one of implementations 60 through 78, in which the main body is additively manufactured and the first pillars meet the upper surface bounding the second plenum volume via rounded transitions.
Implementation 80: An apparatus including: a main body having a first side and a second side on an opposite side of the main body from the first side; N inlet port sets, each inlet port set including one or more corresponding inlet ports; N gas distribution hole sets, each gas distribution hole set including a plurality of corresponding gas distribution holes; and N spiral passages located within the main body, in which: each spiral passage follows a corresponding spiral path, each spiral passage has a corresponding cross-sectional profile along at least a portion of the corresponding spiral path, the gas-distribution holes of a corresponding one of the gas distribution hole sets extend between that spiral passage and the second side of the main body and are distributed along a length of the corresponding spiral path for that spiral passage, each spiral passage is fluidically connected within the main body with at least one inlet port of a corresponding one of the inlet port sets, the N inlet port sets include at least a first inlet port set and a second inlet port set, the N gas distribution hole sets include at least a first gas distribution hole set and a second gas distribution hole set, the N spiral passages include at least: a first spiral passage, in which the gas distribution holes of the first gas distribution hole set extend between the first spiral passage and the second side of the main body and the first spiral passage is fluidically connected within the main body with at least one inlet port in the first inlet port set, and a second spiral passage, in which the gas distribution holes of the second gas distribution hole set extend between the second spiral passage and the second side of the main body and the second spiral passage is fluidically connected within the main body with at least one inlet port in the second inlet port set, the gas distribution holes in the first gas distribution hole set are arranged along the first spiral path, and the gas distribution holes in the second gas distribution hole set are arranged along the second spiral path.
Implementation 81: The apparatus of implementation 80, further including M upper spiral passages, in which: each upper spiral passage is associated with a corresponding one of the spiral passages, there are M riser passage sets, each riser passage set corresponding to one of the upper spiral passages and including one or more riser passages that each fluidically connect the corresponding upper spiral passage with the corresponding spiral passage within the main body, and at least a portion of each upper spiral passage is fluidically interposed within the main body between the corresponding spiral passage and at least one inlet port in the inlet port set with which the corresponding spiral passage is fluidically connected within the main body.
Implementation 82: The apparatus of implementation 81, in which upper spiral passages are interposed between the spiral passages and the first side of the main body, and the spiral passages are interposed between the upper spiral passages and the second side of the main body.
Implementation 83: The apparatus of implementation 81, in which the gas distribution holes are smaller in size than the riser passages.
Implementation 84: The apparatus of implementation 81, in which the spiral passages and the upper spiral passages are arranged in circular arrays about a common axis and have the same chirality.
Implementation 85: The apparatus of implementation 84, in which M=N.
Implementation 86: The apparatus of implementation 85, in which M=2.
Implementation 87: The apparatus of implementation 85, in which M=3.
Implementation 88: The apparatus of implementation 85, in which M=4.
Implementation 89: The apparatus of implementation 85, in which M=6.
Implementation 90: The apparatus of implementation 81, in which: the spiral passages and the upper spiral passages are arranged in circular arrays about a common axis, the spiral passages have a first chirality and the upper spiral passages have a second chirality, and the first chirality is opposite the second chirality.
Implementation 91: The apparatus of implementation 90, in which each riser passage in each riser passage set is located in a location that corresponds with a crossover point between the corresponding upper spiral passage and the corresponding spiral passage associated with the corresponding upper spiral passage.
Implementation 92: The apparatus of implementation 91, in which M is greater than N and at least one of the spiral passages is associated, and fluidically connected, with two or more of the upper spiral passages via the riser passages in the riser passage sets corresponding with those upper spiral passages.
Implementation 93: The apparatus of implementation 92, in which N=2 and M=3.
Implementation 94: The apparatus of implementation 92, in which N=3 and M=4.
Implementation 95: The apparatus of implementation 92, in which N=2 and M=4.
Implementation 96: The apparatus of any one of implementations 80 through 95, in which at least one of the cross-sectional profiles defines a corresponding top surface, a corresponding bottom surface, and two corresponding sidewalls, in which: the corresponding top surface meets the two corresponding sidewalls at two corresponding junctions, the corresponding bottom surface meets the two corresponding sidewalls also at two corresponding junctions, each junction includes a rise surface and a run surface, each run surface of the corresponding junctions between the corresponding sidewalls and the corresponding bottom surface faces towards the corresponding top surface, each run surface of the corresponding junctions between the corresponding sidewalls and the corresponding top surface faces towards the corresponding bottom surface, each rise surface of the corresponding junctions faces towards one of the corresponding sidewalls, the rise surfaces of the corresponding junctions between the corresponding sidewalls and the corresponding top surface form interior corners with the corresponding top surface, the rise surfaces of the corresponding junctions between the corresponding sidewalls and the corresponding bottom surface form interior corners with the corresponding bottom surface, and the run surface of each of the junctions forms an interior corner with one of the corresponding sidewalls.
Implementation 97: The apparatus of implementation 96, in which the rise surface and the run surface of each junction meet at an exterior corner.
Implementation 98: The apparatus of implementation 96, in which at least one of the junctions includes multiple rise surfaces and multiple run surfaces, and in which: each rise surface thereof is separated from each other rise surface thereof by one of the run surfaces thereof, each run surface thereof is separated from each other run surface thereof by one of the rise surfaces thereof, the rise surfaces thereof and the run surfaces thereof form alternating interior and exterior corners.
Implementation 99: The apparatus of any one of implementations 80 through 98, in which: the main body is additively manufactured and the first cross-sectional profile has a first segment, a second segment positioned such that the first segment is between the second segment and the first side and that the second segment is between the first segment and the second side, and opposing first side segments, each first side segment spanning between the first segment and the second segment, the second cross-sectional profile has a third segment, a fourth segment positioned such that the third segment is between the fourth segment and the first side and that the fourth segment is between the third segment and the second side, and opposing second side segments, each second side segment spanning between the third segment and the fourth segment, the first segment includes corresponding first rounded transition regions, the third segment includes corresponding second rounded transition regions each first rounded transition region connects with a corresponding one of the first side segments, and each second rounded transition region connects with a corresponding one of the second side segments.

1. An apparatus comprising:
a main body having a first side and a second side on an opposite side of the main body from the first side;
N inlet port sets, each inlet port set including one or more corresponding inlet ports;
N gas distribution hole sets, each gas distribution hole set including a plurality of corresponding gas distribution holes; and
N spiral passages located within the main body, wherein:
each spiral passage follows a corresponding spiral path,
each spiral passage has a corresponding cross-sectional profile along at least a portion of the corresponding spiral path,
the gas-distribution holes of a corresponding one of the gas distribution hole sets extend between that spiral passage and the second side of the main body and are distributed along a length of the corresponding spiral path for that spiral passage,
each spiral passage is fluidically connected within the main body with at least one inlet port of a corresponding one of the inlet port sets,
the N inlet port sets include at least a first inlet port set and a second inlet port set,
the N gas distribution hole sets include at least a first gas distribution hole set and a second gas distribution hole set,
the N spiral passages include at least:
a first spiral passage that follows a first spiral path, wherein the gas distribution holes of the first gas distribution hole set extend between the first spiral passage and the second side of the main body and the first spiral passage is fluidically connected within the main body with at least one inlet port in the first inlet port set, and
a second spiral passage that follows a second spiral path, wherein the gas distribution holes of the second gas distribution hole set extend between the second spiral passage and the second side of the main body and the second spiral passage is fluidically connected within the main body with at least one inlet port in the second inlet port set,
the gas distribution holes in the first gas distribution hole set are arranged along the first spiral path, and
the gas distribution holes in the second gas distribution hole set are arranged along the second spiral path.

2. The apparatus of claim 1, further comprising M upper spiral passages, wherein:
each upper spiral passage is associated with a corresponding one of the spiral passages,
there are M riser passage sets, each riser passage set corresponding to one of the upper spiral passages and including one or more riser passages that each fluidically connect the corresponding upper spiral passage with the corresponding spiral passage within the main body, and
at least a portion of each upper spiral passage is fluidically interposed within the main body between the corresponding spiral passage and at least one inlet port in the inlet port set with which the corresponding spiral passage is fluidically connected within the main body.

3. The apparatus of claim 2, wherein upper spiral passages are interposed between the spiral passages and the first side of the main body, and the spiral passages are interposed between the upper spiral passages and the second side of the main body.

4. The apparatus of claim 2, wherein the gas distribution holes are smaller in size than the riser passages.

5. The apparatus of claim 2, wherein the spiral passages and the upper spiral passages are arranged in circular arrays about a common axis and have the same chirality.

6. The apparatus of claim 5, wherein M=N.

7. The apparatus of claim 6, wherein M=2.

8. The apparatus of claim 6, wherein M=3.

9. The apparatus of claim 6, wherein M=4.

10. The apparatus of claim 6, wherein M=6.

11. The apparatus of claim 2, wherein:
the spiral passages and the upper spiral passages are arranged in circular arrays about a common axis,
the spiral passages have a first chirality and the upper spiral passages have a second chirality, and
the first chirality is opposite the second chirality.

12. The apparatus of claim 11, wherein each riser passage in each riser passage set is located in a location that corresponds with a crossover point between the corresponding upper spiral passage and the corresponding spiral passage associated with the corresponding upper spiral passage.

13. The apparatus of claim 12, wherein M is greater than N and at least one of the spiral passages is associated, and fluidically connected, with two or more of the upper spiral passages via the riser passages in the riser passage sets corresponding with those upper spiral passages.

14. The apparatus of claim 13, wherein N=2 and M=3.

15. The apparatus of claim 13, wherein N=3 and M=4 or M=6.

16. The apparatus of claim 13, wherein N=2 and M=4 or M=6.

17. The apparatus of claim 1, wherein at least one of the cross-sectional profiles defines a corresponding top surface, a corresponding bottom surface, and two corresponding sidewalls, wherein:
the corresponding top surface meets the two corresponding sidewalls at two corresponding junctions,
the corresponding bottom surface meets the two corresponding sidewalls also at two corresponding junctions,
each junction includes a rise surface and a run surface,
each run surface of the corresponding junctions between the corresponding sidewalls and the corresponding bottom surface faces towards the corresponding top surface,
each run surface of the corresponding junctions between the corresponding sidewalls and the corresponding top surface faces towards the corresponding bottom surface,
each rise surface of the corresponding junctions faces towards one of the corresponding sidewalls,
the rise surfaces of the corresponding junctions between the corresponding sidewalls and the corresponding top surface form interior corners with the corresponding top surface,
the rise surfaces of the corresponding junctions between the corresponding sidewalls and the corresponding bottom surface form interior corners with the corresponding bottom surface, and
the run surface of each of the junctions forms an interior corner with one of the corresponding sidewalls.

18. The apparatus of claim 17, wherein the rise surface and the run surface of each junction meet at an exterior corner.

19. The apparatus of claim 17, wherein at least one of the junctions includes multiple rise surfaces and multiple run surfaces, and wherein:
each rise surface thereof is separated from each other rise surface thereof by one of the run surfaces thereof,
each run surface thereof is separated from each other run surface thereof by one of the rise surfaces thereof, and
the rise surfaces thereof and the run surfaces thereof form alternating interior and exterior corners.

20. The apparatus of claim 1, wherein:
the main body is additively manufactured and the corresponding cross-sectional profile of the first spiral passage has a first segment, a second segment positioned such that the first segment is between the second segment and the first side and that the second segment is between the first segment and the second side, and opposing first side segments, each first side segment spanning between the first segment and the second segment,
the corresponding cross-sectional profile of the second spiral passage has a third segment, a fourth segment positioned such that the third segment is between the fourth segment and the first side and that the fourth segment is between the third segment and the second side, and opposing second side segments, each second side segment spanning between the third segment and the fourth segment,
the first segment includes corresponding first rounded transition regions,
the third segment includes corresponding second rounded transition regions,
each first rounded transition region connects with a corresponding one of the first side segments, and
each second rounded transition region connects with a corresponding one of the second side segments.
